(19) United States
(12) Patent Application Publication
(10) Pub. No.: US 2023/0309375 A1
(43) Pub. Date: Sep. 28, 2023

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Wei Cai, Beijing (CN); Zheng Wang, Beijing (CN); Hongbo Li, Beijing (CN); Ming Sang, Beijing (CN); Zhen Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/124,217

(22) Filed: Mar. 21, 2023

(30) Foreign Application Priority Data
Mar. 25, 2022 (CN) 202210287785.X

(51) Int. Cl. H10K 85/30; C07F 15/00; C09K 11/06

(52) U.S. Cl. CPC H10K 85/342; C07F 15/0033; C09K 11/06; H10K 50/12

(57) ABSTRACT

Provided are an organic electroluminescent material and device thereof. The organic electroluminescent material is a metal complex comprising a ligand Lₐ having a structure of Formula 1. These novel metal complexes are applied in organic electroluminescent devices, and are capable of providing better device performance such as improved device efficiency and an improved device lifetime, especially a greatly improved device lifetime, and can significantly improve the overall device performance. Further provided are an organic electroluminescent device comprising the metal complex and a compound composition comprising the metal complex.

### CROSS-REFERENCE TO RELATED APPLICATION(S)

This application claims priority to Chinese Patent Application No. 202210287785.X filed on Mar. 25, 2022, the disclosure of which is incorporated herein by reference in its entirety.

### TECHNICAL FIELD

The present disclosure relates to compounds for organic electronic devices such as organic electroluminescent devices. More particularly, the present disclosure relates to a metal complex comprising a ligand Lₐ having a structure of Formula 1 and an organic electroluminescent device and compound composition comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US20210054010A1 discloses a metal complex comprising a ligand structure represented by

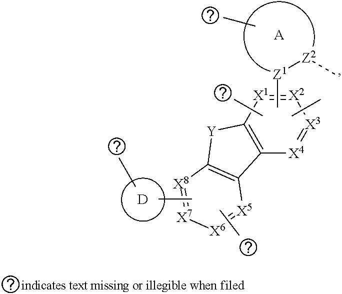

wherein the ring D is selected from a 5- or 6-membered carbocyclic ring or heterocyclic ring and at least one R_{D} is a carbocyclic ring or a heterocyclic group, and further discloses an iridium complex having the following structure

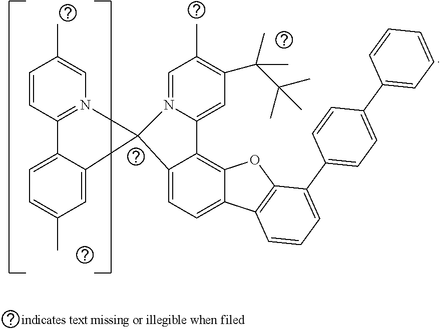

However, this application has neither disclosed nor taught metal complexes comprising ligands having specific fused polycyclic substituents and the effects of such metal complexes on device performance.

US20200251666A1 discloses a metal complex comprising a ligand structure represented by

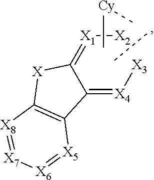

wherein at least one of X₁ to X₈ is selected from C—CN, and further discloses that the metal complex has the following structure

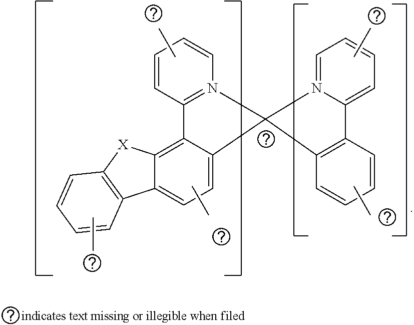

Such a metal complex is applied in organic electroluminescent devices, can improve device performance and color saturation and has reached a high level in the industry, but there is still room for improvement. This application has neither disclosed nor taught metal complexes comprising ligands having specific fused polycyclic substituents and the effects of such metal complexes on device performance.

US20200091442A1 discloses a metal complex comprising a ligand structure represented by

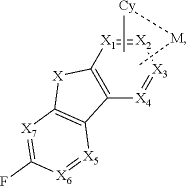

and further discloses that the metal complex has the following structure

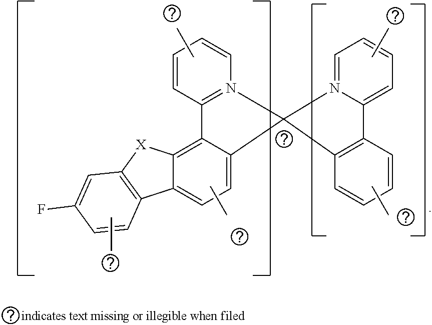

This application discloses that fluorine at a particular position of the ligand can improve device performance comprising a device lifetime and thermal stability. Although such a metal complex has reached a high level in the industry, there is still room for improvement. This application has neither disclosed nor taught metal complexes comprising ligands having specific fused polycyclic substituents and the effects of such metal complexes on device performance.

### SUMMARY

The present disclosure aims to provide a series of metal complexes each comprising a ligand Lₐ having a structure of Formula 1 to solve at least part of the above-mentioned problems. These metal complexes can be used as light-emitting materials in electroluminescent devices. These new metal complexes are applied in organic electroluminescent devices, are capable of providing better device performance such as improved device efficiency and an improved device lifetime, especially a greatly improved device lifetime, and can significantly improve the overall device performance.

According to an embodiment of the present disclosure, disclosed is a metal complex comprising a metal M and a ligand Lₐ coordinated to the metal M, wherein Lₐ has a structure represented by Formula 1:

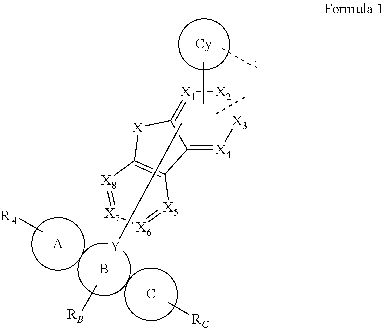

wherein
the metal M is selected from a metal with a relative atomic mass greater than 40;
the ring Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;
the ring Cy is joined to the metal M by a metal-carbon bond or a metal-nitrogen bond;
X is selected from the group consisting of O, S, Se, NR′, CR′R′, SiR′R′ and GeR′R′; when two R′ are present at the same time, the two R′ are the same or different;
Y is selected from the group consisting of C, CR_{Y}, SiR_{Y} and GeR_{Y};
X₁ to X₈ are, at each occurrence identically or differently, selected from C, CRₓ or N; at least one of X₁ to X₈ is selected from C and joined to Y; at least one of X₁ to X₄ is selected from C and joined to the ring Cy;
X₁, X₂, X₃ or X₄ is joined to the metal M by a metal-carbon bond or a metal-nitrogen bond; the ring A, the ring B and the ring C are, at each occurrence identically or differently, selected from a carbocyclic ring having 5 to 10 ring atoms, a heterocyclic ring having 5 to 10 ring atoms or a combination thereof;
the substituents R_{A}, R_{B} and R_{C} represent, at each occurrence identically or differently, mono-substitution, multiple substitutions or non-substitution;
the substituents R′, Rₓ, R_{Y}, R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C}, R_{Y} can be optionally joined to form a ring;
adjacent substituents R′, Rₓ can be optionally joined to form a ring; and
“ [symbol] ” in Formula 1 represents the connection to the metal M.

According to another embodiment of the present disclosure, further disclosed is an organic electroluminescent device comprising an anode, a cathode and an organic layer disposed between the anode and the cathode, wherein at least one layer of the organic layer comprises the metal complex described in the preceding embodiments.

According to another embodiment of the present disclosure, further disclosed is a compound composition comprising the metal complex described in the preceding embodiments.

The present disclosure discloses a series of metal complexes each comprising a ligand Lₐ having a structure of Formula 1, wherein the ligand Lₐ comprises a fused polycyclic structure fused by rings A, B and C, and the fused polycyclic structure is specifically joined to any one of X₁ to X₈ in Formula 1 by a Y group in the ring B. These novel metal complexes can be used as light-emitting materials in organic electroluminescent devices, when applied in organic electroluminescent devices, are capable of providing excellent device performance such as improved device efficiency and an improved device lifetime, especially a greatly improved device lifetime, and can significantly improve the overall device performance.

### BRIEF DESCRIPTION OF DRAWINGS

FIG. 1 is a schematic diagram of an organic light-emitting apparatus that may comprise a metal complex and a compound composition disclosed herein.

FIG. 2 is a schematic diagram of another organic light-emitting apparatus that may comprise a metal complex and a compound composition disclosed herein.

### DETAILED DESCRIPTION

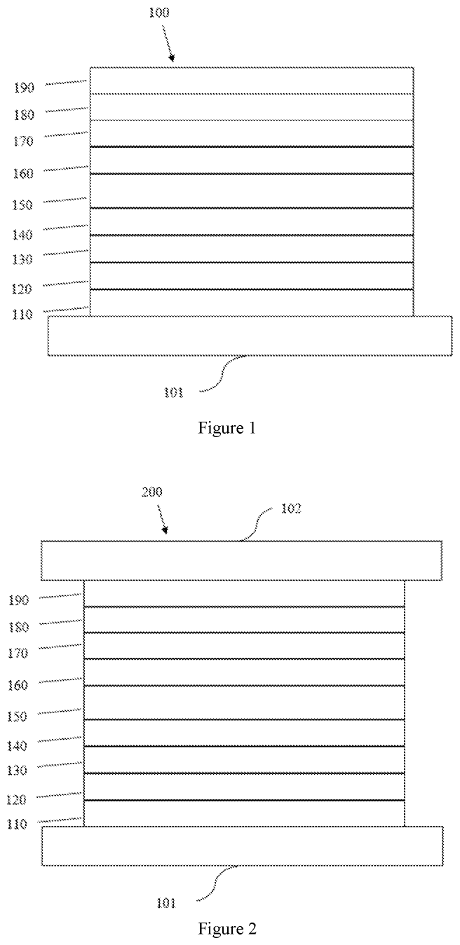

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, an n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refer to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fused cyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

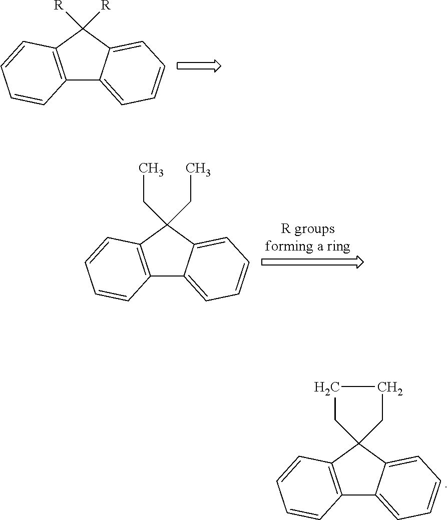

The expression that adjacent substituents can be optionally joined to form a ring is also intended to mean that two substituents bonded to carbon atoms which are directly bonded to each other are joined to each other via a chemical bond to form a ring, which can be exemplified by the following formula:

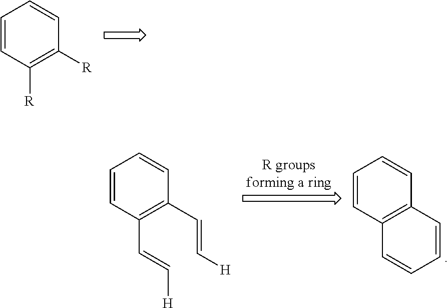

The expression that adjacent substituents can be optionally joined to form a ring is also intended to mean that two substituents bonded to a further distant carbon atom are joined to each other via a chemical bond to form a ring, which can be exemplified by the following formula:

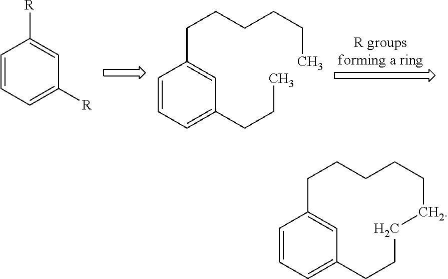

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

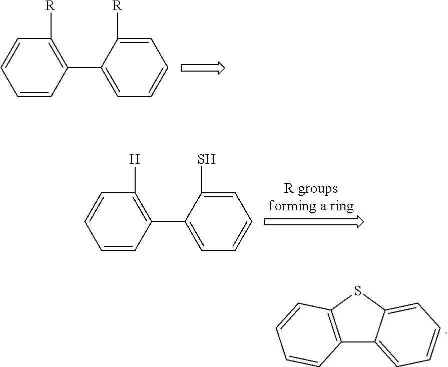

According to an embodiment of the present disclosure, disclosed is a metal complex comprising a metal M and a ligand Lₐ coordinated to the metal M, wherein Lₐ has a structure represented by Formula 1:

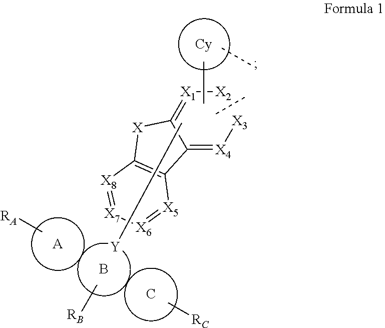

wherein
the metal M is selected from a metal with a relative atomic mass greater than 40;
the ring Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;
the ring Cy is joined to the metal M by a metal-carbon bond or a metal-nitrogen bond;
X is selected from the group consisting of O, S, Se, NR′, CR′R′, SiR′R′ and GeR′R′; when two R′ are present at the same time, the two R′ are the same or different;
Y is selected from the group consisting of C, CR_{Y}, SiR_{Y} and GeR_{Y};
X₁ to X₈ are, at each occurrence identically or differently, selected from C, CRₓ or N; at least one of X₁ to X₈ is selected from C and joined to Y; at least one of X₁ to X₄ is selected from C and joined to the ring Cy;
X₁, X₂, X₃ or X₄ is joined to the metal M by a metal-carbon bond or a metal-nitrogen bond;
the ring A, the ring B and the ring C are, at each occurrence identically or differently, selected from a carbocyclic ring having 5 to 10 ring atoms, a heterocyclic ring having 5 to 10 ring atoms or a combination thereof;
the substituents R_{A}, R_{B} and R_{C} represent, at each occurrence identically or differently, mono-substitution, multiple substitutions or non-substitution;
the substituents R′, Rₓ, R_{Y}, R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C}, R_{Y} can be optionally joined to form a ring;
adjacent substituents R′, Rₓ can be optionally joined to form a ring; and
“ [symbol] ” in Formula 1 represents the connection to the metal M.

In the present disclosure, the expression that “adjacent substituents R_{A}, R_{B}, R_{C}, R_{Y} can be optionally joined to form a ring” is intended to mean that any one or more of groups of adjacent substituents, such as two substituents R_{A}, two substituents R_{B}, two substituents R_{C}, substituents R_{A} and R_{B}, substituents R_{A} and R_{C}, substituents R_{B} and R_{C}, substituents R_{A} and R_{Y}, substituents R_{Y} and R_{C}, and substituents R_{Y} and R_{B}, can be joined to form a ring. Obviously, it is also possible that none of these substituents are joined to form a ring.

In the present disclosure, the ring formed by optionally joining the substituents may be a carbocyclic ring or a heterocyclic ring, and the heterocyclic ring may comprise one or more heteroatoms of O, S, N, Se, P, Si, Ge or B. The carbocyclic ring or heterocyclic ring may be aromatic or non-aromatic. For example, when any one or more of these groups of adjacent substituents, such as two substituents R_{A}, two substituents R_{B}, two substituents R_{C}, substituents R_{A} and R_{B}, substituents R_{A} and R_{C}, and substituents R_{B} and R_{C}, are joined to form a ring, the formed ring may be a carbocyclic ring or a heterocyclic ring comprising one or more heteroatoms of O, S, N, Se, P, Si, Ge or B.

In the present disclosure, the expression that “adjacent substituents R′, Rₓ can be optionally joined to form a ring” is intended to mean that any one or more of groups of adjacent substituents, such as two substituents R′, two substituents Rₓ, and substituents Rₓ and R′, can be joined to form a ring. Obviously, it is also possible that none of these substituents are joined to form a ring.

In the present disclosure, the group represented by

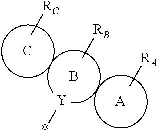

represents a fused polycyclic structure having at least three rings, wherein the ring A is fused with the ring B, the ring B is fused with the ring C, and the fused polycyclic structure is joined to any one of X₁ to X₈ in Formula 1 by Y in the ring B. For example, when the ring A, the ring B and the ring C are all selected from a benzene ring, the fused polycyclic structure may form a group having the following structure:

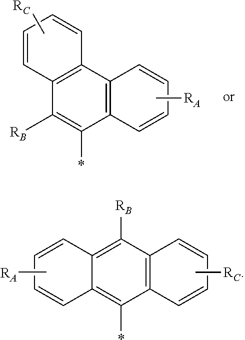

Obviously, in some cases, the ring A and the ring C in the fused polycyclic structure can also be fused with each other.

According to an embodiment of the present disclosure, Cy is any structure selected from the group consisting of:

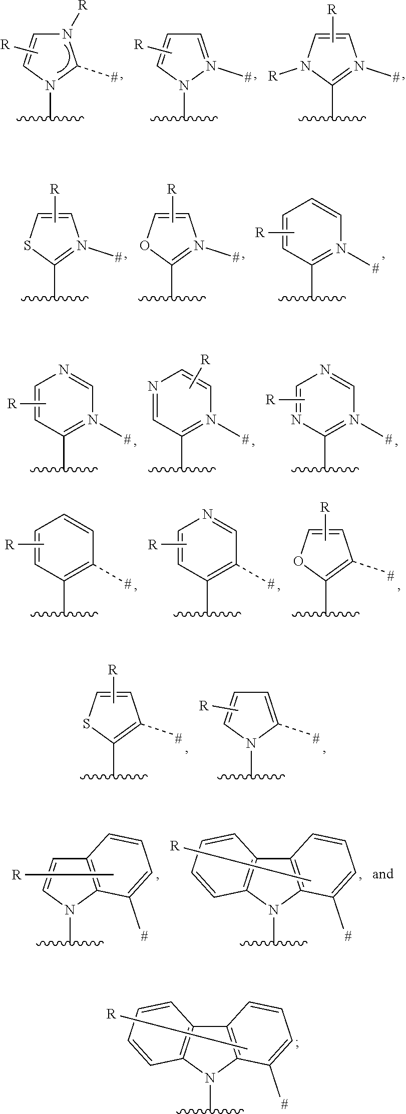

wherein
the substituent R represents, at each occurrence identically or differently, mono-substitution, multiple substitutions or non-substitution; when a plurality of R are present in any structure, the plurality of R are the same or different;
the substituent R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring; and
“#” represents a position where Cy is joined to the metal M, and

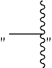

represents a position where Cy is joined to X₁, X₂, X₃ or X₄.

In the present disclosure, the expression that “adjacent substituents R can be optionally joined to form a ring” is intended to mean that any one or more of groups of any two adjacent substituents R can be joined to form a ring. Obviously, it is also possible that none of these substituents are joined to form a ring.

According to an embodiment of the present disclosure, Lₐ is, at each occurrence identically or differently, selected from the group consisting of:

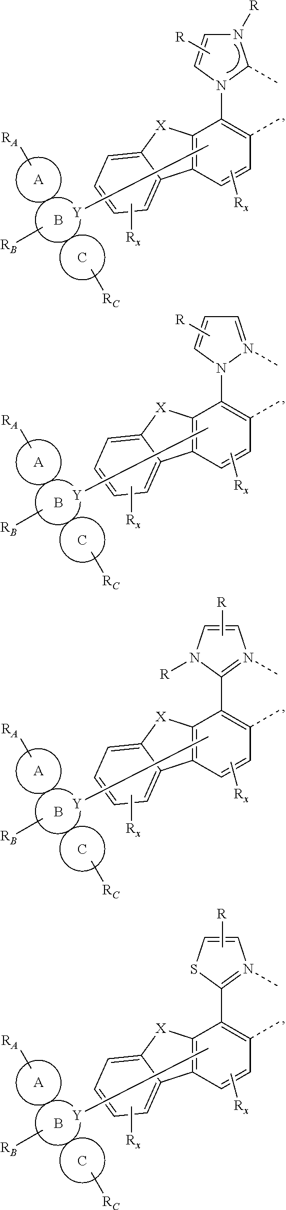

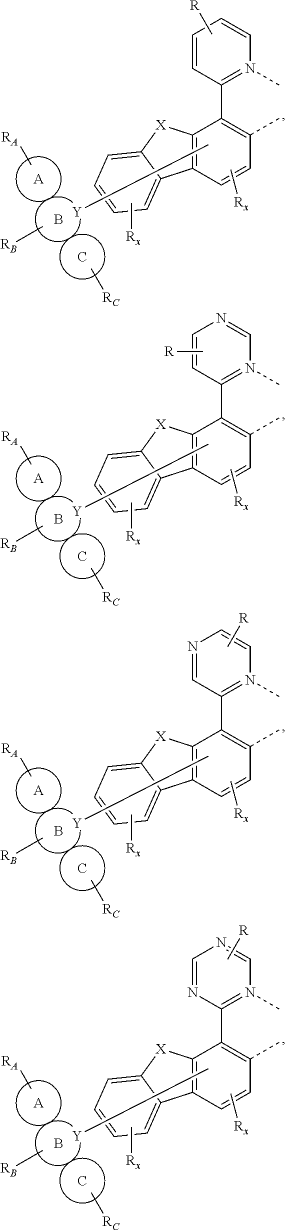

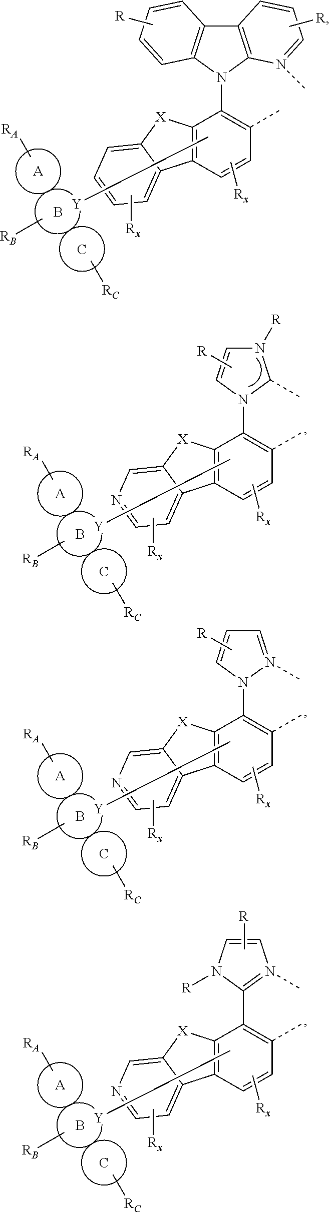

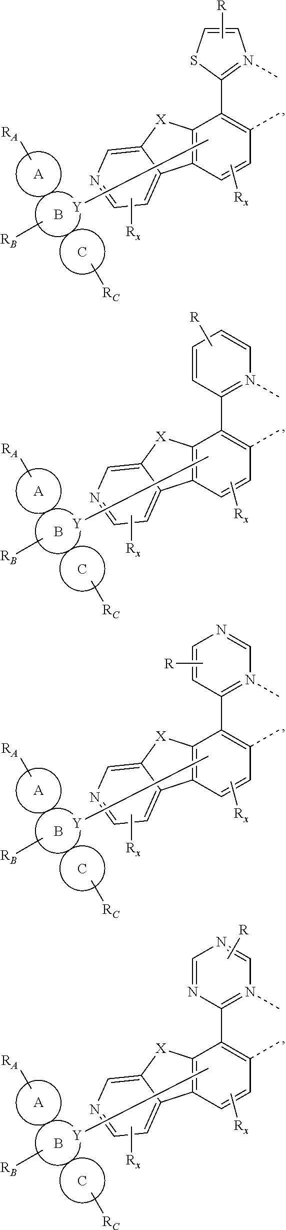

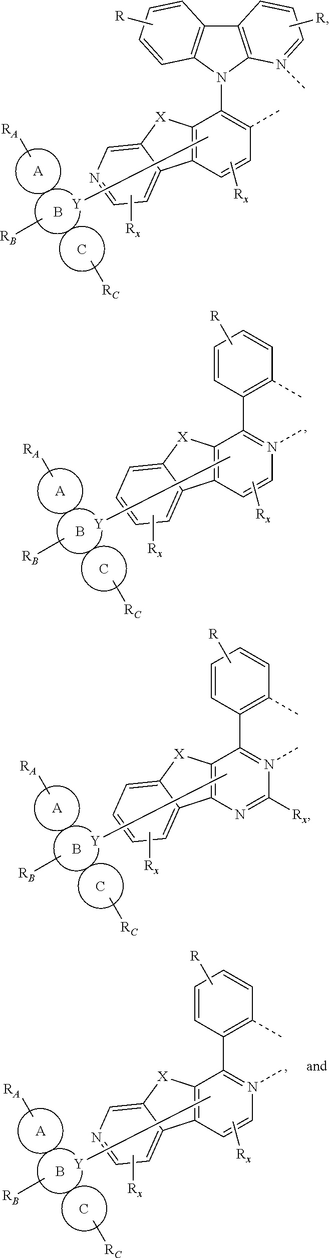

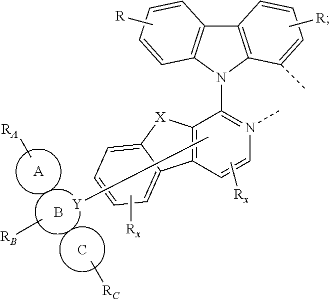

X is selected from the group consisting of O, S, Se, NR′, CR′R′, SiR′R′ and GeR′R′; when two R′ are present at the same time, the two R′ are the same or different;
Y is selected from the group consisting of C, CR_{Y}, SiR_{Y} and GeR_{Y};
the ring A, the ring B and the ring C are, at each occurrence identically or differently, selected from a carbocyclic ring having 5 to 10 ring atoms, a heterocyclic ring having 5 to 10 ring atoms or a combination thereof;
the substituents R, Rₓ, R_{A}, R_{B} and R_{C} represent, at each occurrence identically or differently, mono-substitution, multiple substitutions or non-substitution;
the substituents R′, R, Rₓ, R_{Y}, R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C}, R_{Y} can be optionally joined to form a ring;
adjacent substituents R′, R, Rₓ can be optionally joined to form a ring; and
“ [symbol] ” in the ligand Lₐ represents the connection to the metal M.

In the present disclosure, the expression that “adjacent substituents R′, R, Rₓ can be optionally joined to form a ring” is intended to mean that any one or more of groups of adjacent substituents, such as two substituents R′, two substituents R, two substituents Rₓ, and substituents R and Rₓ, can be joined to form a ring. Obviously, it is also possible that none of these substituents are joined to form a ring.

According to an embodiment of the present disclosure, the metal complex has a general formula of M(Lₐ)ₘ(L_{b})ₙ(L_{c})_{q};
wherein
the metal M is, at each occurrence identically or differently, selected from the group consisting of Cu, Ag, Au, Ru, Rh, Pd, Os, Ir and Pt; preferably, M is, at each occurrence identically or differently, selected from Pt or Ir;
the ligands Lₐ, L_{b} and L_{c} are a first ligand, a second ligand and a third ligand coordinated to the metal M, respectively, and the ligands Lₐ, L_{b} and L_{c} are the same or different; wherein the ligands Lₐ, L_{b} and L_{c} can be optionally joined to form a multidentate ligand; for example, any two of the ligands Lₐ, L_{b} and L_{c} may be joined to form a tetradentate ligand, the ligands Lₐ, L_{b} and L_{c} may be joined to each other to form a hexadentate ligand, or none of the ligands Lₐ, L_{b} and L_{c} are joined so that the multidentate ligand is not formed;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are the same or different; when n is equal to 2, two L_{b} are the same or different; when q is equal to 2, two L_{c} are the same or different;
the ligands L_{b} and L_{c} are, at each occurrence identically or differently, selected from the group consisting of the following structures:

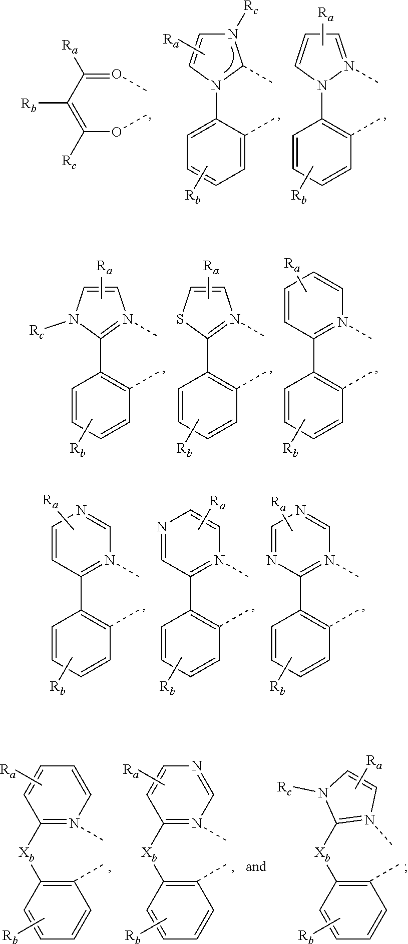

wherein
X_{b} is, at each occurrence identically or differently, selected from the group consisting of: O, S, Se, NR_{N1} and CR_{C1}R_{C2};
the substituents Rₐ and R_{b} represent, at each occurrence identically or differently, mono-substitution, multiple substitutions or non-substitution;
the substituents Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{C1} and R_{C2} can be optionally joined to form a ring.

In the present disclosure, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring. Obviously, it is also possible that none of these substituents are joined to form a ring.

According to an embodiment of the present disclosure, the metal complex has a general structure of Ir(Lₐ)ₘ(L_{b})₃₋ₘ which is represented by Formula 2:

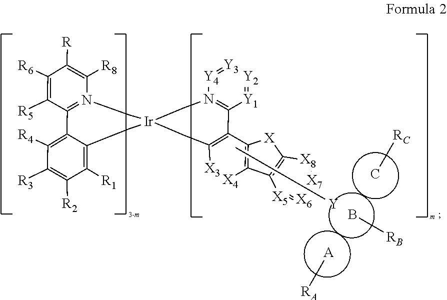

wherein
m is selected from 1, 2 or 3; when m is selected from 1, two L_{b} are the same or different;
when m is selected from 2 or 3, a plurality of Lₐ are the same or different;
X is selected from the group consisting of O, S, Se, NR′, CR′R′, SiR′R′ and GeR′R′; when two R′ are present at the same time, the two R′ are the same or different;
Y is selected from the group consisting of C, CR_{Y}, SiR_{Y} and GeR_{Y};
Y₁ to Y₄ are, at each occurrence identically or differently, selected from CR_{y} or N;
X₃ to X₈ are, at each occurrence identically or differently, selected from C, CRₓ or N; and at least one of X₃ to X₈ is selected from C and joined to Y;
the ring A, the ring B and the ring C are, at each occurrence identically or differently, selected from a carbocyclic ring having 5 to 10 ring atoms, a heterocyclic ring having 5 to 10 ring atoms or a combination thereof;
the substituents R_{A}, R_{B} and R_{C} represent, at each occurrence identically or differently, mono-substitution, multiple substitutions or non-substitution;
the substituents R′, R₁ to R₈, Rₓ, R_{y}, R_{Y}, R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C}, R_{Y} can be optionally joined to form a ring;
adjacent substituents R′, Rₓ, R_{y} can be optionally joined to form a ring; and
adjacent substituents R₁ to R₈ can be optionally joined to form a ring.

In the present disclosure, the expression that “adjacent substituents R₁ to R₈ can be optionally joined to form a ring” is intended to mean that any one or more groups of the group consisting of any two adjacent substituents of R₁ to R₈ can be joined to form a ring. Obviously, it is also possible that none of these substituents are joined to form a ring.

In the present disclosure, the expression that “adjacent substituents R′, Rₓ, R_{y} can be optionally joined to form a ring” is intended to mean that any one or more of groups of adjacent substituents, such as two substituents R′, two substituents Rₓ, and two substituents R_{y}, can be joined to form a ring. Obviously, it is also possible that none of these substituents are joined to form a ring.

According to an embodiment of the present disclosure, the metal complex has a general structure of Ir(Lₐ)ₘ(L_{b})₃₋ₘ which is represented by Formula 2a:

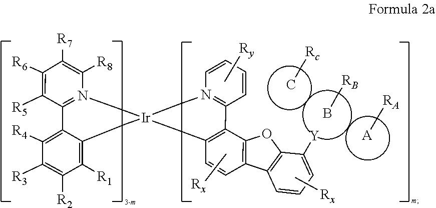

wherein
m is selected from 1, 2 or 3; when m is selected from 1, two Le are the same or different;
when m is selected from 2 or 3, a plurality of Lₐ are the same or different;
Y is selected from the group consisting of C, CR_{Y}, SiR_{Y} and GeR_{Y};
the ring A, the ring B and the ring C are, at each occurrence identically or differently, selected from a carbocyclic ring having 5 to 10 ring atoms, a heterocyclic ring having 5 to 10 ring atoms or a combination thereof;
the substituents Rₓ, R_{y}, R_{A}, R_{B} and R_{C} represent, at each occurrence identically or differently, mono-substitution, multiple substitutions or non-substitution;
the substituents R₁ to R₈, Rₓ, R_{y}, R_{Y}, R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C}, R_{Y} can be optionally joined to form a ring;
adjacent substituents Rₓ, R_{y} can be optionally joined to form a ring; and
adjacent substituents R₁ to R₈ can be optionally joined to form a ring.

In the present disclosure, the expression that “adjacent substituents Rₓ, R_{y} can be optionally joined to form a ring” is intended to mean that any one or more of groups of adjacent substituents, such as two substituents Rₓ and two substituents R_{y}, can be joined to form a ring. Obviously, it is also possible that none of these substituents are joined to form a ring.

According to an embodiment of the present disclosure, X is selected from O or S.

According to an embodiment of the present disclosure, X is selected from O.

According to an embodiment of the present disclosure, Y is selected from C.

According to an embodiment of the present disclosure, X₃ to X₈ are, at each occurrence identically or differently, selected from C or CRₓ, and one of X₃ to X₈ is selected from C and joined to Y; the substituent Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, X₃ to X₈ are, at each occurrence identically or differently, selected from C or CRₓ, and one of X₃ to X₈ is selected from C and joined to Y; at least one of the substituent Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, at least one of X₃ to X₈ is N. For example, one of X₃ to X₈ is selected from N, or two of X₃ to X₈ are selected from N.

According to an embodiment of the present disclosure, at least one of X₁ to X₈ is N. For example, one of X₁ to X₈ is selected from N, or two of X₁ to X₈ are selected from N.

According to an embodiment of the present disclosure, at least one of Y₁ to Y₄ is N. For example, one of Y₁ to Y₄ is selected from N, or two of Y₁ to Y₄ are selected from N.

According to an embodiment of the present disclosure,

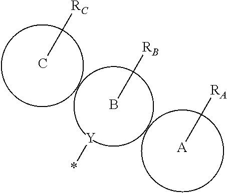

has the following general structure:

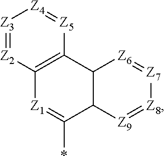

wherein Z₁ is selected from CR_{B} or N, Z₂ to Z₅ are, at each occurrence identically or differently, selected from CR_{A} or N, and Z₆ to Z₉ are, at each occurrence identically or differently, selected from CR_{C} or N.

According to an embodiment of the present disclosure, at least one of Z₁ to Z₉ is selected from N. For example, one of Z₁ to Z₉ is selected from N, or two of Z₁ to Z₉ are selected from N.

According to an embodiment of the present disclosure, at least one of Z₁ to Z₉ is selected from N, for example, Z₁ is selected from N, or one of Z₂ to Z₅ is selected from N, or one of Z₆ to Z₉ is selected from N.

According to an embodiment of the present disclosure, the ring A, the ring B and the ring C are, at each occurrence identically or differently, selected from a carbocyclic ring having a monocyclic or polycyclic structure and having 5 to 10 ring atoms, a heterocyclic ring having a monocyclic or polycyclic structure and having 5 to 10 ring atoms or a combination thereof.

According to an embodiment of the present disclosure, the ring A, the ring B and the ring C are, at each occurrence identically or differently, selected from an aromatic ring having 5 to 10 ring atoms, a heteroaromatic ring having 5 to 10 ring atoms or a combination thereof.

According to an embodiment of the present disclosure, the ring A, the ring B and the ring C are, at each occurrence identically or differently, selected from an aromatic ring having a monocyclic or polycyclic structure and having 5 to 10 ring atoms, a heteroaromatic ring having a monocyclic or polycyclic structure and having 5 to 10 ring atoms or a combination thereof.

According to an embodiment of the present disclosure, the ring A, the ring B and the ring C are, at each occurrence identically or differently, selected from a carbocyclic ring having 5 to 6 ring atoms, a heterocyclic ring having 5 to 6 ring atoms or a combination thereof.

According to an embodiment of the present disclosure, the ring A, the ring B and the ring C are, at each occurrence identically or differently, selected from a benzene ring, a heterocyclic ring having 5 to 6 ring atoms or a combination thereof.

According to an embodiment of the present disclosure, the ring A, the ring B and the ring C are, at each occurrence identically or differently, selected from a benzene ring, a pyridine ring, a pyrimidine ring, a thiophene ring or a furan ring.

According to an embodiment of the present disclosure, the ring A, the ring B and the ring C are, at each occurrence identically or differently, selected from a benzene ring.

According to an embodiment of the present disclosure, at least one of X₃ to X₈ is selected from C and joined to Y.

According to an embodiment of the present disclosure, at least one of X₅ to X₈ is selected from C and joined to Y.

According to an embodiment of the present disclosure, at least one of X₇ or X₈ is selected from C and joined to Y.

According to an embodiment of the present disclosure, at least one of X₃ to X₈ is selected from CRₓ, and the Rₓ is selected from cyano or fluorine.

According to an embodiment of the present disclosure, at least one of X₅ to X₈ is CRₓ, and the Rₓ is selected from cyano or fluorine.

According to an embodiment of the present disclosure, at least one of X₇ or X₈ is selected from CRₓ, and the Rₓ is selected from cyano or fluorine.

According to an embodiment of the present disclosure, at least one of X₃ to X₈ is CRₓ, and the Rₓ is selected from cyano or fluorine; at least one of X₃ to X₈ is selected from C and joined to Y.

According to an embodiment of the present disclosure, at least one of X₅ to X₈ is CRₓ, and the Rₓ is selected from cyano or fluorine; at least one of X₅ to X₈ is selected from C and joined to Y.

According to an embodiment of the present disclosure, one of X₇ and X₈ is selected from CRₓ, and the Rₓ is selected from cyano or fluorine; the other one is selected from C and joined to Y.

According to an embodiment of the present disclosure, X₇ is selected from CRₓ, and the Rₓ is selected from cyano or fluorine; X₈ is selected from C and joined to Y.

According to an embodiment of the present disclosure, the substituents R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, the substituents R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, the substituents R_{A}, R_{B} and R_{C} are, at each occurrence identically or differently, selected from the group consisting of: deuterium, halogen, substituted or unsubstituted alkyl having 1 to 6 carbon atoms, substituted or unsubstituted cycloalkyl having 3 to 6 ring carbon atoms, substituted or unsubstituted alkenyl having 2 to 6 carbon atoms, substituted or unsubstituted aryl having 6 to 12 carbon atoms, substituted or unsubstituted heteroaryl having 3 to 12 carbon atoms, and combinations thereof.

According to an embodiment of the present disclosure, the substituents R_{A}, R_{B} and R_{C} are, at each occurrence identically or differently, selected from the group consisting of: hydrogen, deuterium, fluorine, methyl, ethyl, propyl, butyl, pentyl, cyclohexyl, cyclopentyl, phenyl, pyridyl, pyrimidinyl, and combinations thereof; hydrogens in the above substituents can be partially or fully deuterated.

According to an embodiment of the present disclosure,

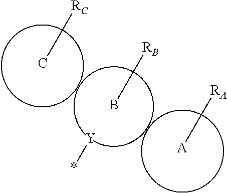

is selected from the group consisting of the following groups:

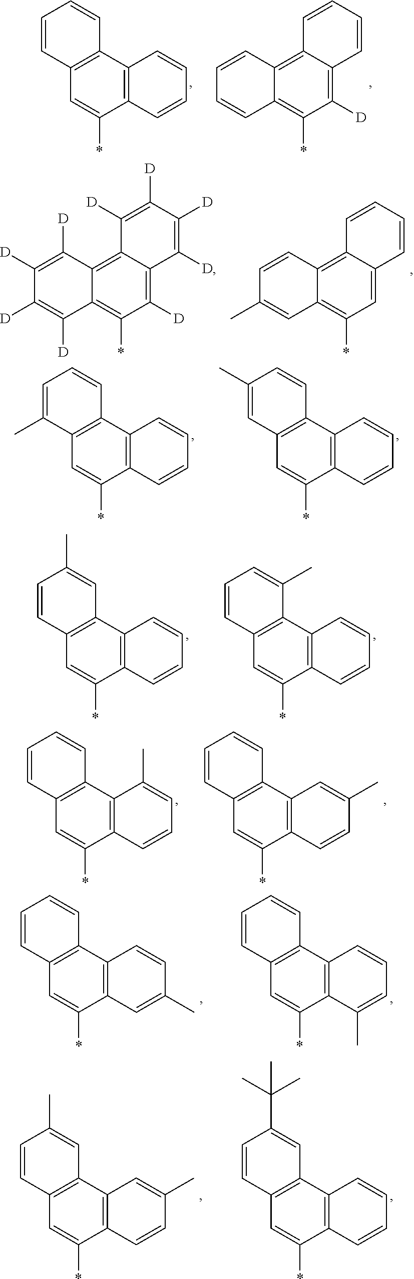

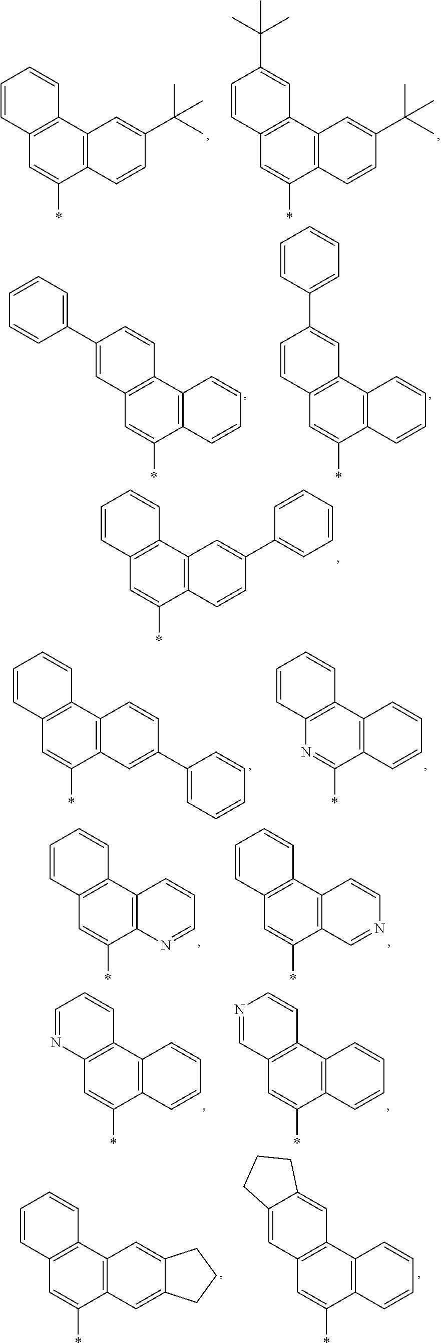

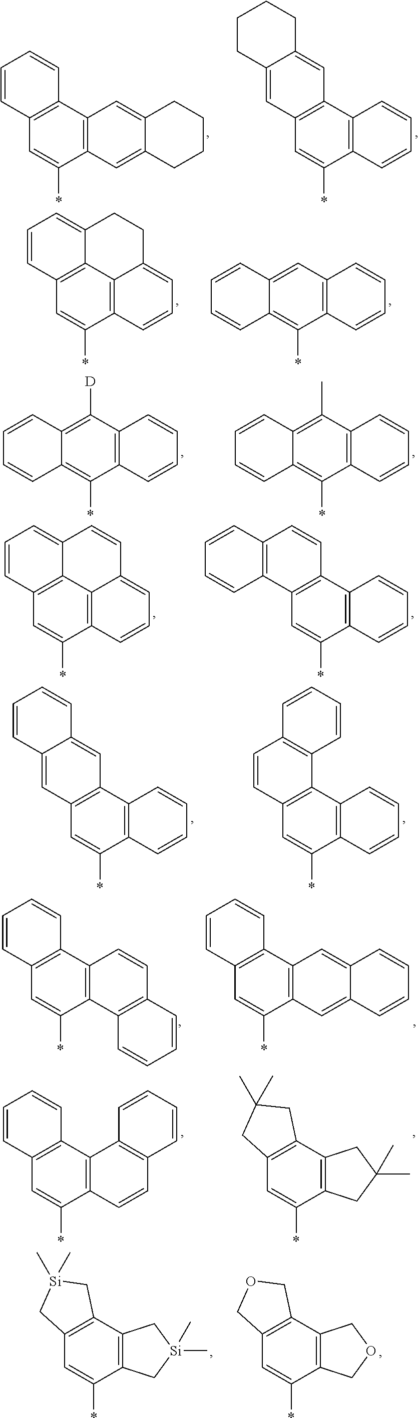

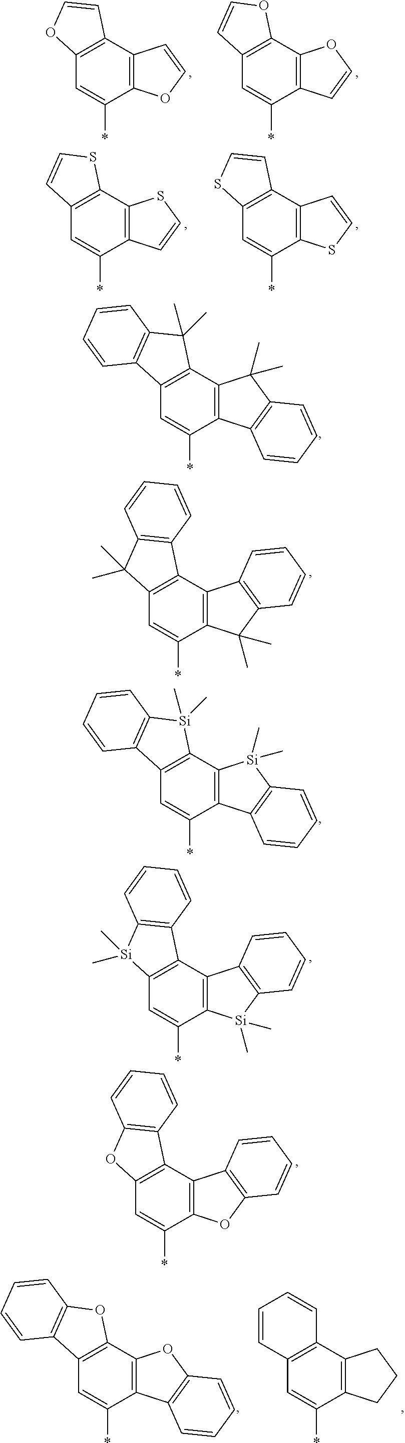

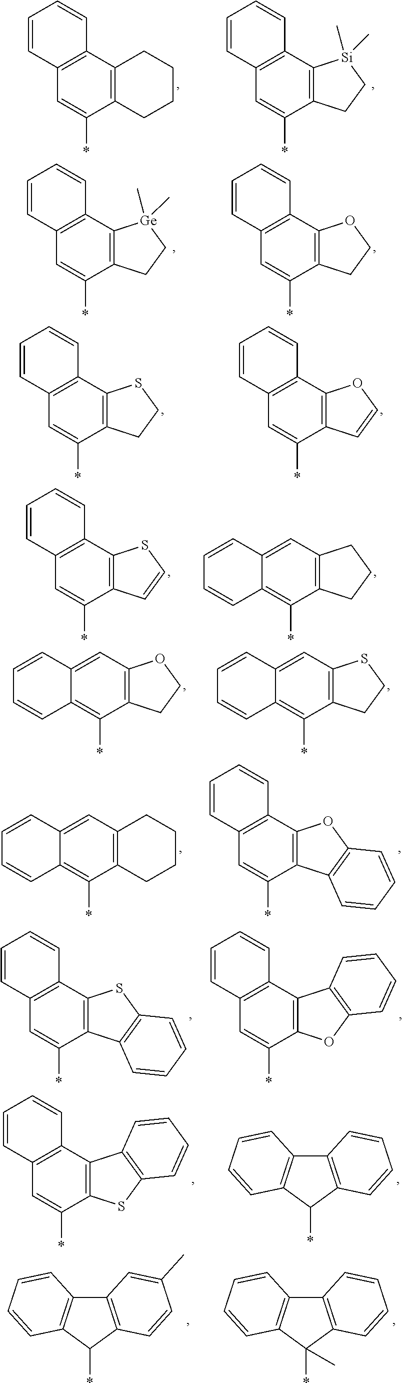

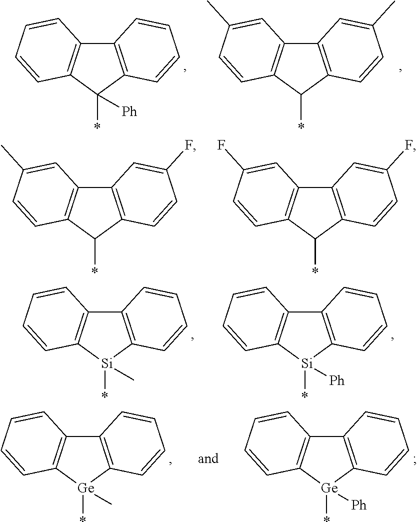

wherein “*” represents a position where the substituent is joined; and
optionally, hydrogens in the above groups can be partially or fully deuterated.

According to an embodiment of the present disclosure, Y₁ to Y₄ are, at each occurrence identically or differently, selected from CR_{y}, and the substituent R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, Y₁ to Y₄ are, at each occurrence identically or differently, selected from CR_{y}, and at least one of the substituent R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, the substituents R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, an isocyano group, a hydroxyl group, a sulfanyl group, and combinations thereof.

According to an embodiment of the present disclosure, the substituents R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, an isocyano group, a hydroxyl group, a sulfanyl group, and combinations thereof.

According to an embodiment of the present disclosure, the substituents R₁ to R₈ are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 18 carbon atoms, substituted or unsubstituted heteroaryl having 3 to 18 carbon atoms, substituted or unsubstituted alkylsilyl having 3 to 15 carbon atoms, and combinations thereof.

According to an embodiment of the present disclosure, at least one or at least two of the substituents R₁ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₁ to R₄ and/or the substituents R₅ to R₈ is at least 4.

According to an embodiment of the present disclosure, at least one or at least two of the substituents R₁ to R₄ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₁ to R₄ is at least 4.

According to an embodiment of the present disclosure, at least one or at least two of the substituents R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₅ to R₈ is at least 4.

According to an embodiment of the present disclosure, at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, at least one, at least two, at least three or all of the substituents R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl, and combinations thereof; optionally, hydrogens in the above groups can be partially or fully deuterated.

According to an embodiment of the present disclosure, the substituents R_{Y} to R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, the substituents R_{Y} to R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, the substituents R_{Y} to R′ are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, and combinations thereof.

According to an embodiment of the present disclosure, the substituents R_{Y} to R_{y} are, at each occurrence identically or differently, selected from the group consisting of: hydrogen, deuterium, fluorine, methyl, ethyl, propyl, butyl, pentyl, cyclohexyl, cyclopentyl, phenyl, pyridyl, pyrimidinyl, and combinations thereof; hydrogens in the above substituents can be partially or fully deuterated.

According to an embodiment of the present disclosure, R is selected from substituted or unsubstituted alkyl having 1 to 20 carbon atoms or substituted or unsubstituted cycloalkyl having 3 to 20 ring carbon atoms.

According to an embodiment of the present disclosure, wherein R is methyl or deuterated methyl.

According to an embodiment of the present disclosure, the ligand Lₐ is, at each occurrence identically or differently, selected from the group consisting of Lₐ₁ to Lₐ₂₅₈, wherein the specific structures of Lₐ₁ to Lₐ₂₅₈ are referred to claim 15.

According to an embodiment of the present disclosure, hydrogens in Lₐ₁ to Lₐ₂₅₈ can be partially or fully deuterated.

According to an embodiment of the present disclosure, the ligand L_{b} is, at each occurrence identically or differently, selected from the group consisting of L_{b1} to L_{b334}, wherein the specific structures of L_{b1} to L_{b334} are referred to claim 16.

According to an embodiment of the present disclosure, hydrogens in L_{b1} to L_{b334} can be partially or fully deuterated.

According to an embodiment of the present disclosure, the ligand L_{c} is, at each occurrence identically or differently, selected from the group consisting of L_{c1} to L_{c50}, wherein the specific structures of L_{c1} to L_{c50} are referred to claim 17.

According to an embodiment of the present disclosure, the metal complex has a structure of Ir(Lₐ)₃, IrLₐ(L_{b})₂, Ir(Lₐ)₂L_{b}, Ir(Lₐ)₂L_{c}, IrLₐ(L_{c})₂ or IrLₐL_{b}L_{c}, wherein the ligand Lₐ is, at each occurrence identically or differently, selected from any one, any two or any three of the group consisting of Lₐ₁ to Lₐ₂₅₈, the ligand L_{b} is, at each occurrence identically or differently, selected from any one or any two of the group consisting of L_{b1} to L_{b334}, and the ligand L_{c} is, at each occurrence identically or differently, selected from any one or any two of the group consisting of L_{c1} to L_{c50}.

According to an embodiment of the present disclosure, the metal complex has a structure of IrLₐ(L_{b})₂, wherein the two Lₐ are the same or different, the ligand Lₐ is, at each occurrence identically or differently, selected from any one of the group consisting of Lₐ₁ to Lₐ₂₅₈, and the ligand L_{b} is, at each occurrence identically or differently, selected from any one or any two of the group consisting of L_{b1} to L_{b334}.

According to an embodiment of the present disclosure, the metal complex is selected from the group consisting of Metal Complex 1 to Metal Complex 495, wherein the specific structures of Metal Complex 1 to Metal Complex 495 are referred to claim 18.

According to an embodiment of the present disclosure, further disclosed is an organic electroluminescent device comprising an anode, a cathode and an organic layer disposed between the anode and the cathode, wherein at least one layer of the organic layer comprises the metal complex described in any one of the preceding embodiments.

According to an embodiment of the present disclosure, the organic layer comprising the metal complex is an emissive layer.

According to an embodiment of the present disclosure, the organic electroluminescent device emits green light.

According to an embodiment of the present disclosure, the organic electroluminescent device emits yellow light.

According to an embodiment of the present disclosure, the emissive layer comprises a first host compound.

According to an embodiment of the present disclosure, the emissive layer further comprises a second host compound.

According to an embodiment of the present disclosure, at least one of the first host compound and the second host compound comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the first host compound has a structure represented by Formula 3:

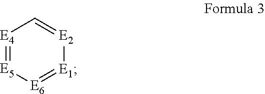

wherein
E₁ to E₆ are, at each occurrence identically or differently, selected from C, CRₑ or N, at least two of E₁ to E₆ are N, and at least one of E₁ to E₆ is C and joined to Formula 4:

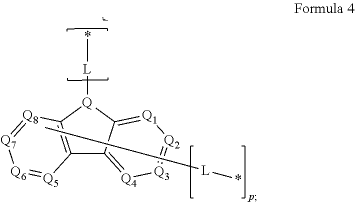

wherein
Q is, at each occurrence identically or differently, selected from the group consisting of O, S, Se, N, NR″, CR″R″, SiR″R″, GeR″R″ and R″C═CR″; when two R″ are present at the same time, the two R″ can be the same or different;
p is 0 or 1, and r is 0 or 1;
when Q is selected from N, p is 0, and r is 1;
when Q is selected from the group consisting of O, S, Se, NR″, CR″R″, SiR″R″, GeR″R″ and R″C═CR″, p is 1, and r is 0;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
“*” represents a position where Formula 4 is joined to Formula 3;
Rₑ, R″ and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₑ, R″, R_{q} can be optionally joined to form a ring.

In the present disclosure, the expression that “adjacent substituents Rₑ, R″, R_{q} can be optionally joined to form a ring” is intended to mean that any one or more of groups of adjacent substituents, such as substituents Rₑ, substituents R″, two substituents R_{q}, and substituents R″ and R_{q}, can be joined to form a ring. Obviously, it is also possible that none of these substituents are joined to form a ring.

According to an embodiment of the present disclosure, the first host compound has a structure represented by Formula 3a or Formula 3b:

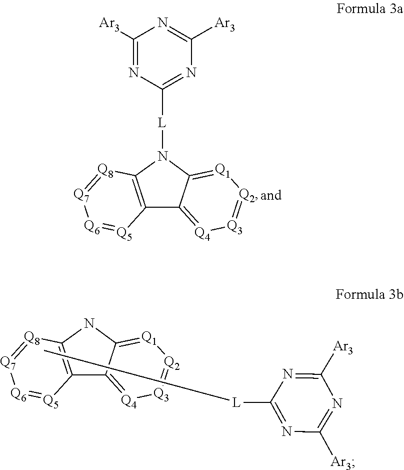

wherein in Formula 3a or Formula 3b,
Q is, at each occurrence identically or differently, selected from the group consisting of O, S, Se, N, NR″, CR″R″, SiR″R″, GeR″R″ and R″C═CR″; when two R″ are present at the same time, the two R″ can be the same or different;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
R″ and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₃ is, at each occurrence identically or differently, selected from substituted or unsubstituted aryl having 6 to 30 carbon atoms, substituted or unsubstituted heteroaryl having 3 to 30 carbon atoms or a combination thereof;
preferably, Ar₃ is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylenyl, substituted or unsubstituted fluorenyl, substituted or unsubstituted dibenzofuryl, substituted or unsubstituted dibenzothienyl, substituted or unsubstituted carbazolyl or a combination thereof; and
adjacent substituents R″, R_{q} can be optionally joined to form a ring.

In the present disclosure, the expression that “adjacent substituents R″, R_{q} can be optionally joined to form a ring” is intended to mean that any one or more of groups of adjacent substituents, such as two substituents R″, two substituents R_{q}, and substituents R″ and R_{q}, can be joined to form a ring. Obviously, it is also possible that none of these substituents are joined to form a ring.

According to an embodiment of the present disclosure, the second host compound has a structure represented by Formula 5 or Formula 6:

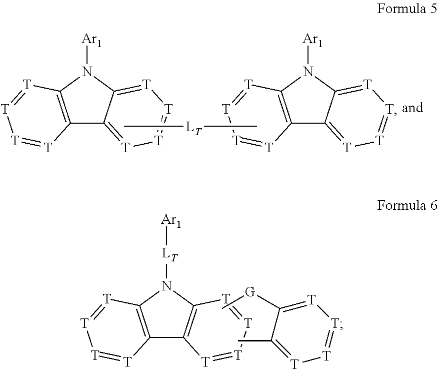

wherein
G is, at each occurrence identically or differently, selected from C(R_{g})₂, NR_{g}, O or S;
L_{T} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
T is, at each occurrence identically or differently, selected from C, CRₜ or N;
Rₜ and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
in Formula 5, adjacent substituents Rₜ can be optionally joined to form a ring;
in Formula 6, adjacent substituents Rₜ, R_{g} can be optionally joined to form a ring;
preferably, the second host compound has a structure represented by one of Formulas 5-a to 5-j and Formulas 6-a to 6-f:

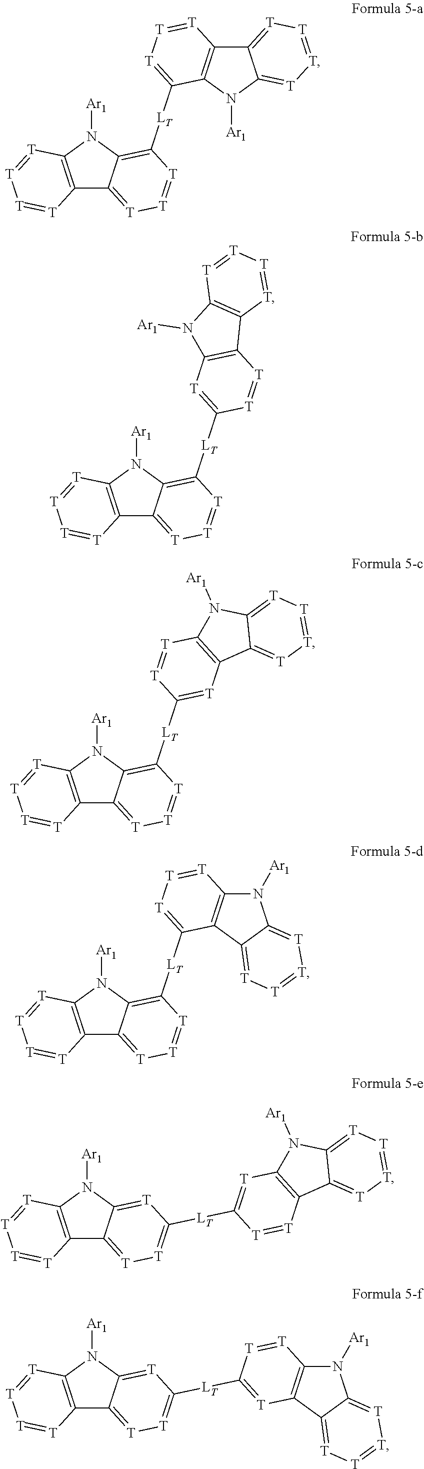

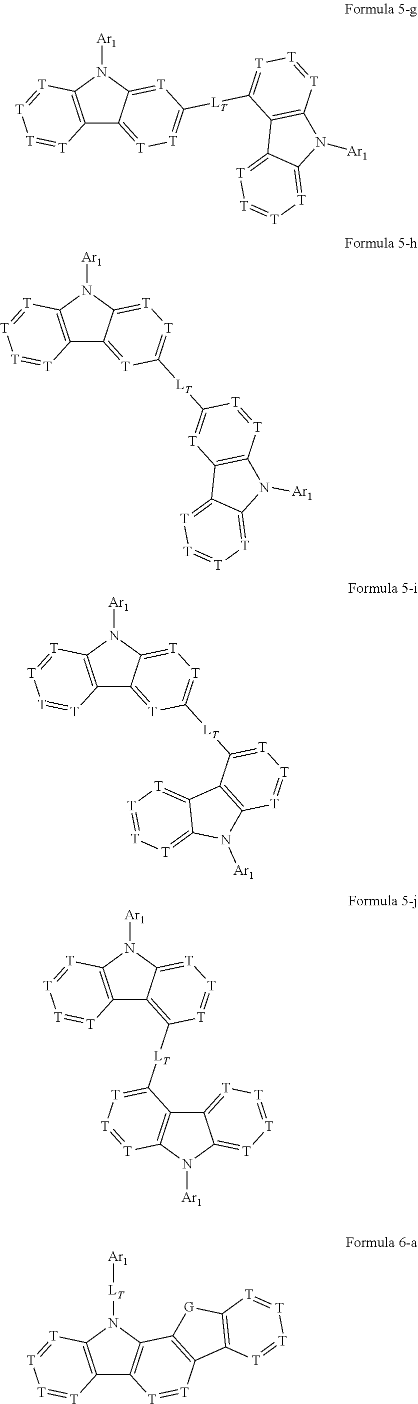

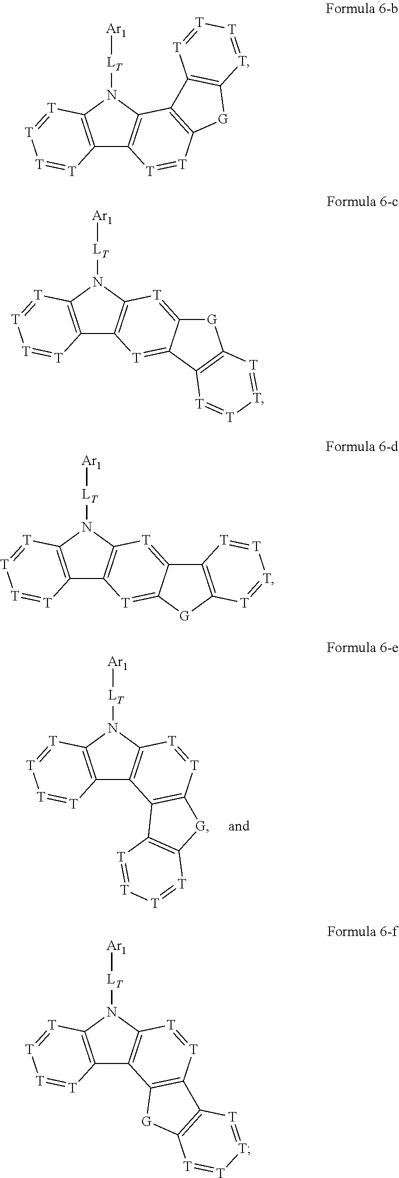

wherein in Formulas 5-a to 5j, T, L_{T} and Ar₁ each have the same meaning as in Formula 5; and
in Formulas 6-a to 6-f, T, G, L_{T} and Ar₁ each have the same meaning as in Formula 6.

In the present disclosure, the expression that “adjacent substituents Rₜ can be optionally joined to form a ring” is intended to mean that one or more groups of the group consisting ofany two adjacent substituents R can be joined to form a ring. Obviously, it is also possible that none of these substituents are joined to form a ring.

In the present disclosure, the expression that “adjacent substituents Rₜ, R_{g} can be optionally joined to form a ring” is intended to mean that any one or more of groups of adjacent substituents, such as two substituents Rₜ, two substituents R_{g}, and substituents Rₜ and R_{g}, can be joined to form a ring. Obviously, it is also possible that none of these substituents are joined to form a ring.

According to an embodiment of the present disclosure, the metal complex is doped in the first host compound and the second host compound, and the weight of the metal complex accounts for 1% to 30% of the total weight of the emissive layer.

According to an embodiment of the present disclosure, the metal complex is doped in the first host compound and the second host compound, and the weight of the metal complex accounts for 3% to 13% of the total weight of the emissive layer.

According to an embodiment of the present disclosure, disclosed is a compound composition comprising the metal complex described in any one of the preceding embodiments.

Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing the compound in the present disclosure is not limited herein. Typically, the following compounds are used as examples without limitation, and synthesis routes and preparation methods thereof are described below.

### Synthesis Example 1: Synthesis of Metal Complex 216

Step 1:

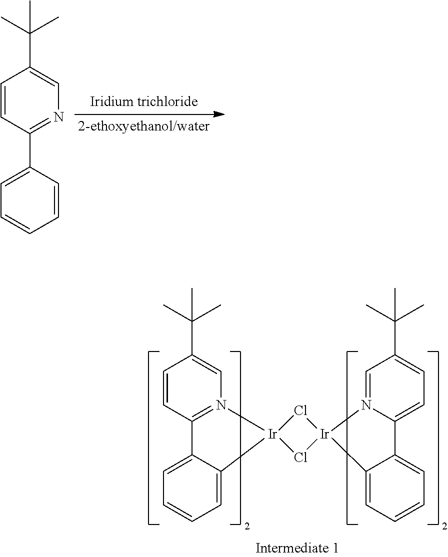

5-t-butyl-2-phenylpyridine (10.0 g, 59.2 mmol), iridium trichloride trihydrate (5.0 g, 14.2 mmol), 300 mL of 2-ethoxyethanol and 100 mL of water were sequentially added to a dry 500 mL round-bottom flask, purged with nitrogen three times, and heated and stirred at 130° C. for 24 h under nitrogen protection. After the reaction was cooled, the reaction solution was filtered. The upper solid was washed three times with methanol and n-hexane respectively and suctioned under reduced pressure to give 7.5 g of Intermediate 1 as a yellow solid (with a yield of 97%).

Step 2:

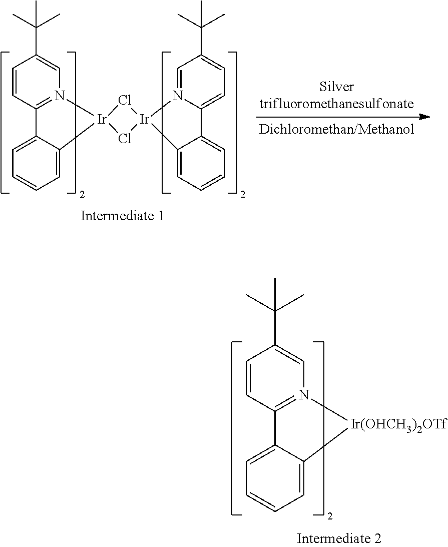

Intermediate 1 (7.5 g, 6.8 mmol), silver trifluoromethanesulfonate (3.8 g, 14.8 mmol), 250 mL of anhydrous dichloromethane and 10 mL of methanol were sequentially added to a dry 500 mL round-bottom flask, purged with nitrogen three times, and stirred overnight at room temperature under nitrogen protection. The reaction product was filtered through Celite and washed twice with dichloromethane. The organic phase below was collected and concentrated under reduced pressure to give 9.2 g of Intermediate 2 (with a yield of 93%).

Step 3:

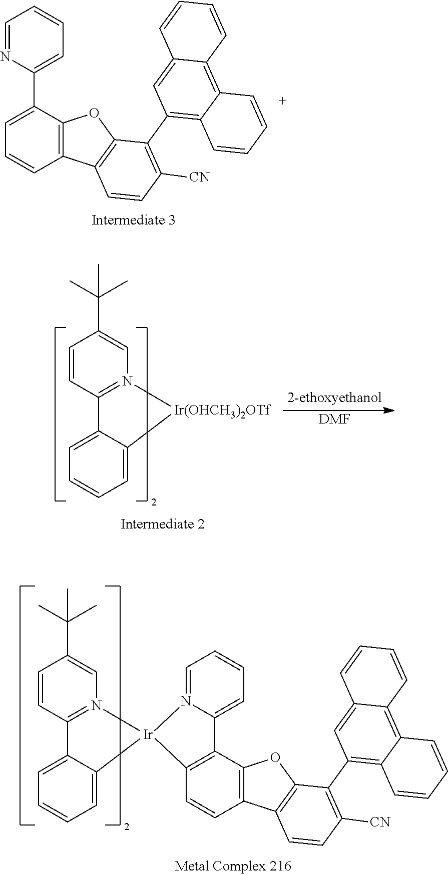

Intermediate 2 (2.2 g, 2.7 mmol), Intermediate 3 (1.7 g, 3.8 mmol), 50 mL of 2-ethoxyethanol and 50 mL of N,N-dimethylformamide (DMF) were sequentially added to a dry 250 mL round-bottom flask, purged with nitrogen three times, and heated at 100° C. for 72 h under nitrogen protection. After the reaction was cooled, the reaction solution was filtered through Celite. The upper solid was washed twice with methanol and n-hexane respectively to give a yellow solid. The solid was dissolved with dichloromethane. The organic phase was collected, concentrated under reduced pressure, and purified by column chromatography to give the product Metal Complex 216 as a yellow solid (0.8 g, with a yield of 30.0%). The product was confirmed as the target product with a molecular weight of 1058.4.

### Synthesis Example 2: Synthesis of Metal Complex 226

Step 1:

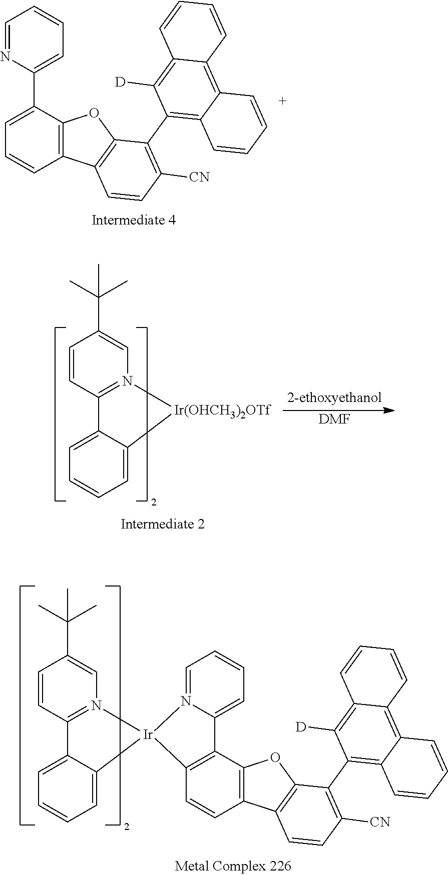

Intermediate 2 (2.2 g, 2.7 mmol), Intermediate 4 (1.8 g, 3.9 mmol), 50 mL of 2-ethoxyethanol and 50 mL of DMF were sequentially added to a dry 250 mL round-bottom flask, purged with nitrogen three times, and heated at 100° C. for 96 h under nitrogen protection. After the reaction was cooled, the reaction solution was filtered through Celite. The upper solid was washed twice with methanol and n-hexane respectively to give a yellow solid. The solid was dissolved with dichloromethane. The organic phase was collected, concentrated under reduced pressure, and purified by column chromatography to give the product Metal Complex 226 as a yellow solid (0.88 g, with a yield of 30.7%). The product was confirmed as the target product with a molecular weight of 1059.4.

### Synthesis Example 3: Synthesis of Metal Complex 246

Step 1:

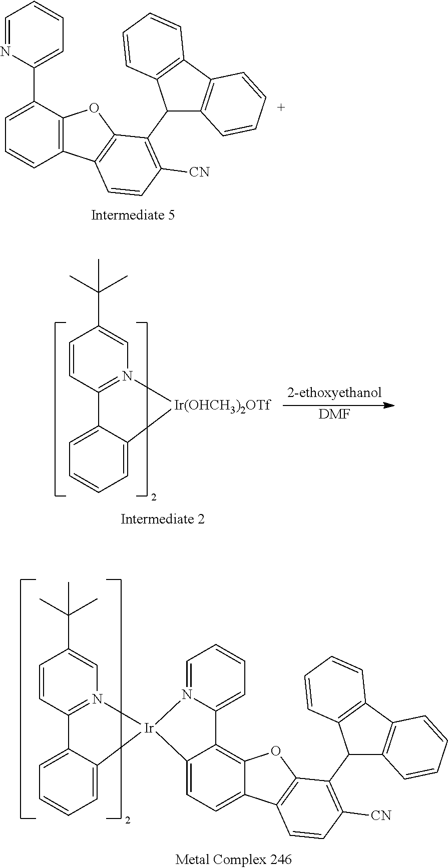

Intermediate 2 (1.7 g, 2.0 mmol), Intermediate 5 (0.9 g, 2.1 mmol), 30 mL of 2-ethoxyethanol and 30 mL of DMF were sequentially added to a dry 250 mL round-bottom flask, purged with nitrogen three times, and heated at 100° C. for 96 h under nitrogen protection. After the reaction was cooled, the reaction solution was filtered through Celite. The upper solid was washed twice with methanol and n-hexane respectively to give a yellow solid. The solid was dissolved with dichloromethane. The organic phase was collected, concentrated under reduced pressure, and purified by column chromatography to give the product Metal Complex 246 as a yellow solid (0.35 g, with a yield of 16.7%). The product was confirmed as the target product with a molecular weight of 1046.4.

### Synthesis Example 4: Synthesis of Metal Complex 255

Step 1:

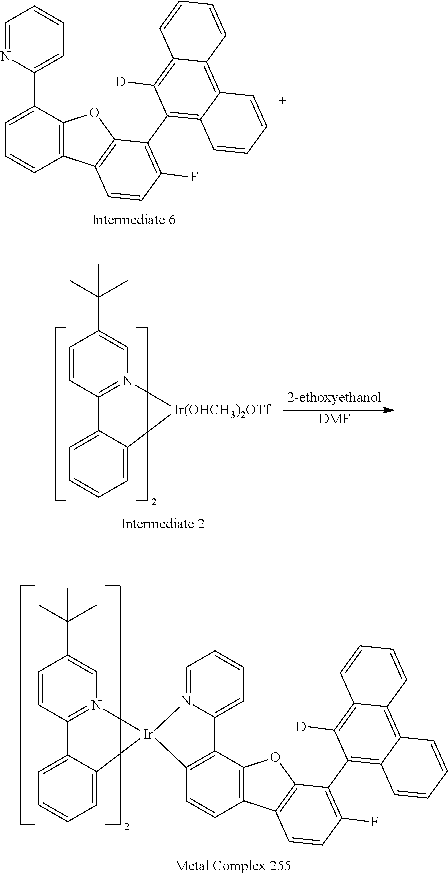

Intermediate 2 (1.5 g, 1.8 mmol), Intermediate 6 (1.2 g, 2.7 mmol), 50 mL of 2-ethoxyethanol and 50 mL of DMF were sequentially added to a dry 250 mL round-bottom flask, purged with nitrogen three times, and heated at 100° C. for 96 h under nitrogen protection. After the reaction was cooled, the reaction solution was filtered through Celite. The upper solid was washed twice with methanol and n-hexane respectively to give a yellow solid. The solid was dissolved with dichloromethane. The organic phase was collected, concentrated under reduced pressure, and purified by column chromatography to give the product Metal Complex 255 as a yellow solid (0.88 g, with a yield of 61.2%). The product was confirmed as the target product with a molecular weight of 1052.4.

Those skilled in the art will appreciate that the above preparation methods are merely exemplary. Those skilled in the art can obtain other compound structures of the present disclosure through the modifications of the preparation methods.

### Device Example 1

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second at a vacuum degree of about 10⁻⁸ torr. Compound HI was used as a hole injection layer (HIL). Compound HT was used as a hole transport layer (HTL). Compound H1 was used as an electron blocking layer (EBL). Metal complexes 216 of the present disclosure, as dopant, was co-deposited with compounds H1 and H2 for use as an emissive layer (EML). On the EML, Compound HB was used as a hole blocking layer (HBL). On the HBL, Compound ET and 8-hydroxyquinolinolato-lithium (Liq) were co-deposited as an electron transport layer (ETL). Finally, 8-hydroxyquinolinolato-lithium (Liq) with a thickness of 1 nm was deposited as an electron injection layer (EIL), and Al with a thickness of 1200 nm was deposited as a cathode. The device was transferred back to the glovebox and encapsulated with a glass lid to complete the device.

### Device Example 2

The implementation in Device Example 2 was the same as that in Device Example 1, except that in the EML, Metal Complex 216 of the present disclosure was replaced with Metal Complex 226 of the present disclosure.

### Device Comparative Example 1

The implementation in Device Comparative Example 1 was the same as that in Device Example 1, except that in the emissive layer (EML), Metal Complex 216 of the present disclosure was replaced with Compound GD1.

### Device Comparative Example 2

The implementation in Device Comparative Example 2 was the same as that in Device Example 1, except that in the emissive layer (EML), Metal Complex 216 of the present disclosure was replaced with Compound GD2.

### Device Comparative Example 3

The implementation in Device Comparative Example 3 was the same as that in Device Example 1, except that in the emissive layer (EML), Metal Complex 216 of the present disclosure was replaced with Compound GD3.

Detailed structures and thicknesses of layers of the devices are shown in Table 1. A layer using more than one material is obtained by doping different compounds at their weight ratios as recorded.

TABLE 1
Device structures in Examples 1 and 2 and Comparative Examples 1 to 3

| Device ID | HIL | HTL | EBL | EML | HBL | ETL |
|---|---|---|---|---|---|---|
| Example 1 | Compound | Compound | Compound | Compound H1: | Compound | Compound |
| | HI | HT | H1 | Compound H2: | HB | ET:Liq |
| | (100 Å) | (350 Å) | (50 Å) | Metal Complex | (50 Å) | (40:60) (350 |
| | | | | 216 (63:31:6) | | Å) |
| | | | | (400 Å) | | |
| Example 2 | Compound | Compound | Compound | Compound H1: | Compound | Compound |
| | HI | HT | H1 | Compound H2: | HB | ET:Liq |
| | (100 Å) | (350 Å) | (50 Å) | Metal Complex | (50 Å) | (40:60) (350 |
| | | | | 226 (63:31:6) | | Å) |
| | | | | (400 Å) | | |
| Comparative | Compound | Compound | Compound | Compound H1: | Compound | Compound |
| Example 1 | HI | HT | H1 | Compound H2: | HB | ET:Liq |
| | (100 Å) | (350 Å) | (50 Å) | Compound GD1 | (50 Å) | (40:60) (350 |
| | | | | (63:31:6) (400 | | Å) |
| | | | | Å) | | |
| Comparative | Compound | Compound | Compound | Compound H1: | Compound | Compound |
| Example 2 | HI | HT | H1 | Compound H2: | HB | ET:Liq |
| | (100 Å) | (350 Å) | (50 Å) | Compound GD2 | (50 Å) | (40:60) (350 |
| | | | | (63:31:6) (400 | | Å) |
| | | | | Å) | | |
| Comparative | Compound | Compound | Compound | Compound H1: | Compound | Compound |
| Example 3 | HI | HT | H1 | Compound H2: | HB | ET:Liq |
| | (100 Å) | (350 Å) | (50 Å) | Compound GD3 | (50 Å) | (40:60) (350 |
| | | | | (63:31:6) (400 | | Å) |
| | | | | Å) | | |

The materials used in the devices have the following structures:

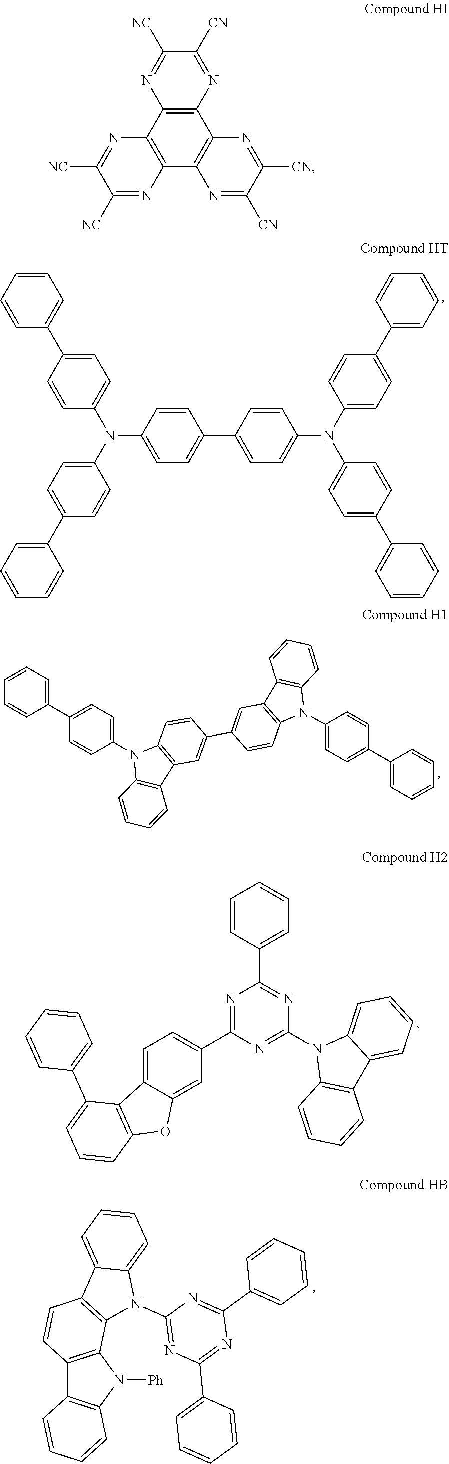 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2nc(-c3ccccc3)nc(-n3c4ccccc4c4ccc5c6ccccc6n(-c6ccccc6)c5c43)n2)cc1]

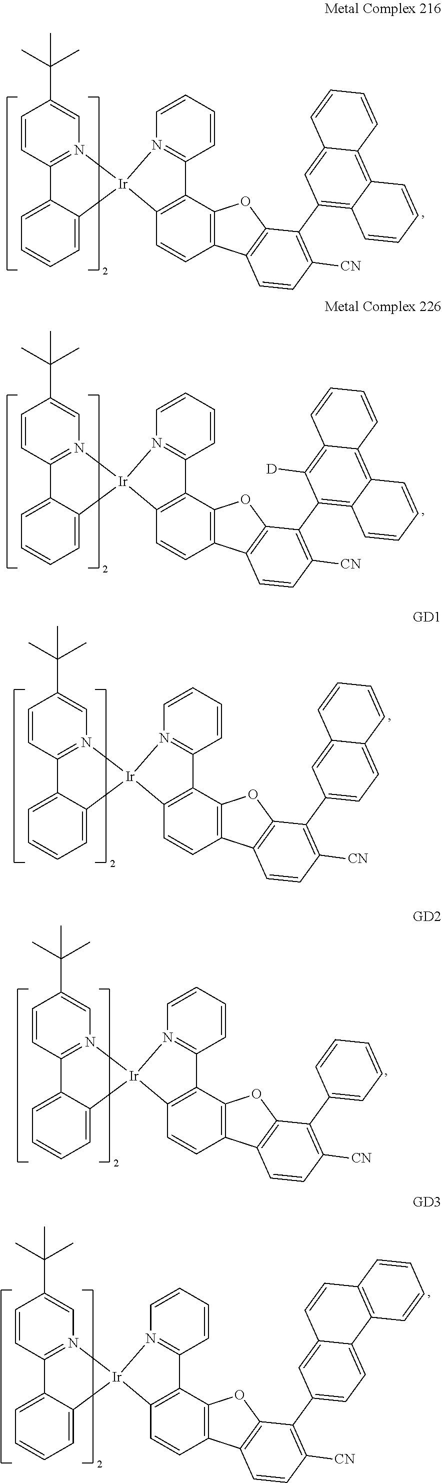

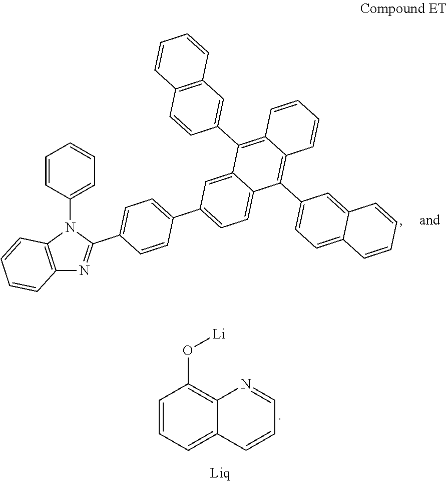

IVL characteristics of the devices were measured. The CIE data, maximum emission wavelength λₘₐₓ, full width at half maximum (FWHM) and voltage (V) of the devices were measured at 1000 cd/m²; the external quantum efficiency (EQE) data was tested at a constant current of 15 mA/cm²; the lifetime (LT97) data was tested at a constant current of 80 mA/cm²; the voltage, external quantum efficiency and lifetime were normalized based on the device results of Comparative Example 1, and these data were recorded and presented in Table 2.

TABLE 2
Device data in Examples 1 and 2 and Comparative Examples 1 to 3

| | | λₘₐₓ | FWHM | Voltage | EQE | LT97 |
|---|---|---|---|---|---|---|
| Device ID | CIE (x, y) | (nm) | (nm) | (V) | (%) | (h) |
| Example 1 | (0.339, 0.637) | 531 | 35.0 | 0.97 | 1.05 | 2.20 |
| Example 2 | (0.339, 0.637) | 531 | 34.9 | 0.97 | 1.06 | 2.50 |
| Comparative | (0.345, 0.633) | 532 | 35.6 | 1.00 | 1.00 | 1.00 |
| Example 1 | | | | | | |
| Comparative | (0.342, 0.635) | 531 | 35.9 | 0.96 | 0.98 | 2.00 |
| Example 2 | | | | | | |
| Comparative | (0.344, 0.633) | 532 | 34.4 | 0.94 | 1.09 | 1.87 |
| Example 3 | | | | | | |

Discussion:

Table 2 shows the device properties of Examples and Comparative Examples. As can be seen from the comparison between Example 1 and Comparative Example 1, the difference was only that the fused polycyclic substituent on the ligand Lₐ of the metal complex was different and the fused ring substituent of Comparative Example 1 had only two rings fused. As can be seen from the above device results, compared with Comparative Example 1, the drive voltage of Example 1 was reduced by 3%, the full width at half maximum was narrowed by 0.6 nm, the EQE was increased by 5%, and especially the device lifetime was increased by 120%. It can be seen that the overall performance of the device of Example 1 was significantly improved.

As can be seen from the comparison between Example 1 and Comparative Example 2, the difference was only that the substituent on the ligand Lₐ of the metal complex was different and Comparative Example 1 had only a phenyl substituent instead of a fused polycyclic substituent. As can be seen from the above device results, compared with Comparative Example 2, the drive voltage of Example 1 was equivalent to that of Comparative Example 2, the full width at half maximum was narrowed by 0.9 nm, the EQE was increased by 7%, and the device lifetime was increased by 10%. In the case that the performance of Comparative Example 2 had been relatively excellent, Example 1 could improve the color purity of the device and further significantly improve the overall performance of the device, which was even rarer.

As can be seen from the above results, the metal complex comprising the ligand Lₐ having a specific fused polycyclic substituent in the present application can improve the device performance in many aspects, especially the device lifetime, and can significantly improve the overall performance of the device, compared with the metal complex having no specific fused polycyclic substituent.

As can be seen from the comparison between Example 1 and Comparative Example 3, the difference was only that the substitution site of the fused polycyclic substituent on the ligand Lₐ of the metal complex was different. As can be seen from the above device results, compared with Comparative Example 3, the drive voltage and the EQE of Example 1 were equivalent to those of Comparative Example 3, and although the full width at half maximum was widened by 0.6 nm, the device lifetime was increased by 17.6%. It indicates that the metal complex comprising the ligand Lₐ having a specific specifically-linked fused ring substituent in the present application can significantly improve the device lifetime, compared with the metal complex having no specifically-linked fused ring substituent.

Furthermore, on the basis that the metal complex used in Example 1 could improve the device performance compared with the metal complex that was not provided by the present disclosure, Example 2 further optimized the metal complex. On the basis of the excellent device performance of Example 1, Example 2 further improved the device performance and especially further increased the device lifetime by 13.6%.

The above results indicate that the metal complex comprising the ligand Lₐ having a specific specifically-linked fused polycyclic substituent in the present application can improve the device performance in many aspects, especially the device lifetime, and can significantly improve the overall performance of the device, compared with the metal complex that is not provided by the present disclosure.

### Device Example 3

The implementation in Device Example 3 was the same as that in Device Example 1, except that in the emissive layer, Metal Complex 216 of the present disclosure was replaced with Metal Complex 255 of the present disclosure.

### Device Comparative Example 4

The implementation in Device Comparative Example 4 was the same as that in Device Example 1, except that in the emissive layer (EML), Metal Complex 216 of the present disclosure was replaced with Compound GD4.

Detailed structures and thicknesses of layers of the devices are shown in Table 3. A layer using more than one material is obtained by doping different compounds at their weight ratios as recorded.

TABLE 3
Device structures in Example 3 and Comparative Example 4

| Device ID | HIL | HTL | EBL | EML | HBL | ETL |
|---|---|---|---|---|---|---|
| Example 3 | Compound | Compound | Compound | Compound H1: | Compound | Compound |
| | HI | HT | H1 | Compound 2: | HB | ET:Liq |
| | (100 Å) | (350 Å) | (50 Å) | Metal Complex | (50 Å) | (40:60) (350 |
| | | | | 255 (63:31:6) | | Å) |
| | | | | (400 Å) | | |
| Comparative | Compound | Compound | Compound | Compound H1: | Compound | Compound |
| Example 4 | HI | HT | H1 | Compound H2: | HB | ET:Liq |
| | (100 Å) | (350 Å) | (50 Å) | Compound GD4 | (50 Å) | (40:60) (350 |
| | | | | (63:31:6) (400 | | Å) |
| | | | | Å) | | |

The new materials used in the devices have the following structures:

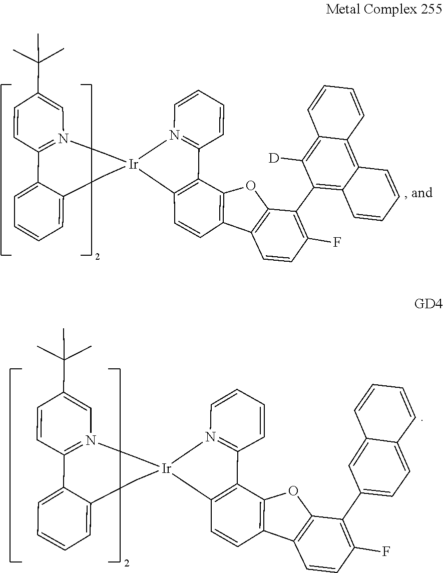

IVL characteristics of the devices were measured. The CIE data, maximum emission wavelength λₘₐₓ, full width at half maximum (FWHM) and voltage (V) of the devices were measured at 1000 cd/m²; the external quantum efficiency (EQE) data was tested at a constant current of 15 mA/cm²; the lifetime (LT97) data was tested at a constant current of 80 mA/cm²; the voltage, external quantum efficiency and lifetime were normalized based on the device results of Comparative Example 4, and these data were recorded and presented in Table 4.

TABLE 4
Device data in Example 3 and Comparative Example 4

| | | λₘₐₓ | FWHM | Voltage | EQE | LT97 |
|---|---|---|---|---|---|---|
| Device ID | CIE (x, y) | (nm) | (nm) | (V) | (%) | (h) |
| Example 3 | (0.351, 0.623) | 530 | 59.6 | 1.00 | 1.03 | 1.16 |
| Comparative | (0.355, 0.621) | 531 | 58.9 | 1.00 | 1.00 | 1.00 |
| Example 4 | | | | | | |

Discussion:

Table 4 shows the device properties of Example and Comparative Example. As can be seen from the comparison between Example 3 and Comparative Example 4, the difference was mainly that the fused polycyclic substituent on the ligand Lₐ of the metal complex was different and the fused ring substituent of Comparative Example 4 had only two rings fused. As can be seen from the above device results, compared with Comparative Example 4, the drive voltage of Example 3 was equivalent to that of Comparative Example 4, and although the full width at half maximum was widened by 0.7 nm, the EQE was increased by 3%, and especially the device lifetime was increased by 16%. It can be seen that the overall performance of the device of Example 3 was significantly improved.

The above results indicate that the metal complex comprising the ligand Lₐ having a specific specifically-linked fused ring substituent in the present application can improve the device performance in many aspects, especially the device lifetime, and can significantly improve the overall performance of the device, compared with the metal complex that is not provided by the present disclosure.

It is to be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of materials and structures described herein may be substituted with other materials and structures without departing from the spirit of the present disclosure. It is to be understood that various theories as to why the present disclosure works are not intended to be limitative.

What is claimed is:

1. A metal complex, comprising a metal M and a ligand Lₐ coordinated to the metal M, wherein the ligand Lₐ has a structure represented by Formula 1: 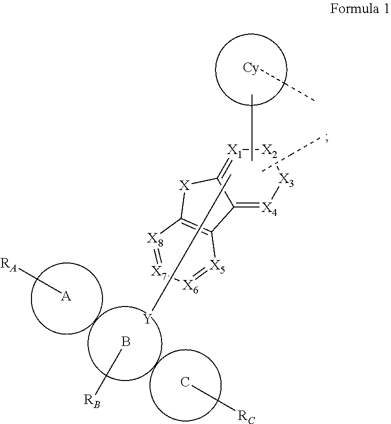
wherein
the metal M is selected from a metal with a relative atomic mass greater than 40;
the ring Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;
the ring Cy is joined to the metal M by a metal-carbon bond or a metal-nitrogen bond;
X is selected from the group consisting of O, S, Se, NR′, CR′R′, SiR′R′ and GeR′R′; when two R′ are present at the same time, the two R′ are the same or different;
Y is selected from the group consisting of C, CR_{Y}, SiR_{Y} and GeR_{Y};
X₁ to X₈ are, at each occurrence identically or differently, selected from C, CRₓ or N; at least one of X₁ to X₈ is selected from C and joined to Y; at least one of X₁ to X₄ is selected from C and joined to the ring Cy;
X₁, X₂, X₃ or X₄ is joined to the metal M by a metal-carbon bond or a metal-nitrogen bond;
the ring A, the ring B and the ring C are, at each occurrence identically or differently, selected from a carbocyclic ring having 5 to 10 ring atoms, a heterocyclic ring having 5 to 10 ring atoms or a combination thereof;
the substituents R_{A}, R_{B} and R_{C} represent, at each occurrence identically or differently, mono-substitution, multiple substitutions or non-substitution;
the substituents R′, Rₓ, R_{Y}, R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C} and R_{Y} can be optionally joined to form a ring;
adjacent substituents R′ and Rₓ can be optionally joined to form a ring; and
“ [symbol] ” in Formula 1 represents the connection to the metal M.

2. The metal complex of claim 1, wherein Cy is any structure selected from the group consisting of: 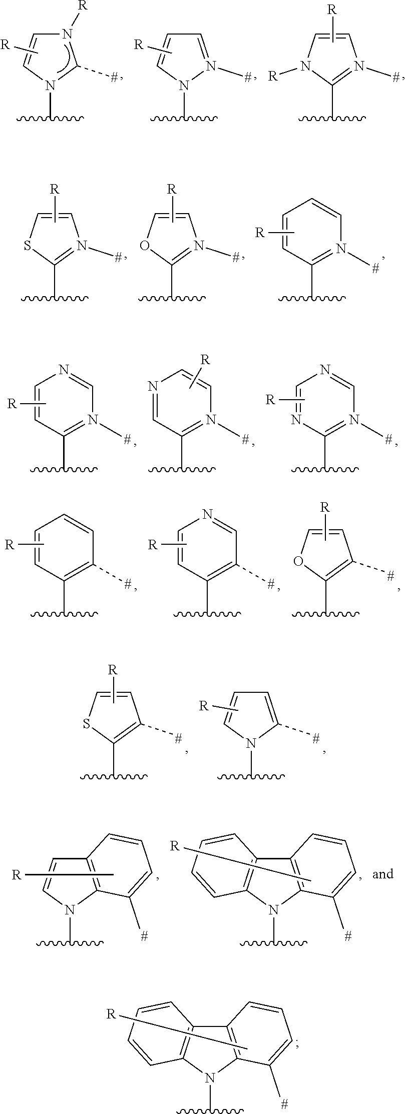
wherein
the substituent R represents, at each occurrence identically or differently, mono-substitution, multiple substitutions or non-substitution; when a plurality of R are present in any structure, the plurality of R are the same or different;
the substituent R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring; and
“#” represents a position where Cy is joined to the metal M, and 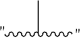
represents a position where Cy is joined to X₁, X₂, X₃ or X₄.

3. The metal complex of claim 1, wherein the metal complex has a general formula of M(Lₐ)ₘ(L_{b})ₙ(L_{c})_{q};
wherein
the metal M is, at each occurrence identically or differently, selected from the group consisting of Cu, Ag, Au, Ru, Rh, Pd, Os, Ir and Pt; preferably, M is, at each occurrence identically or differently, selected from Pt or Ir;
the ligands Lₐ, L_{b} and L_{c} are a first ligand, a second ligand and a third ligand coordinated to the metal M, respectively, and the ligands Lₐ, L_{b} and L_{c} are the same or different; wherein the ligands Lₐ, L_{b} and L_{c} can be optionally joined to form a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are the same or different; when n is equal to 2, two L_{b} are the same or different; when q is equal to 2, two L_{c} are the same or different;
the ligands L_{b} and L_{c} are, at each occurrence identically or differently, selected from the group consisting of the following structures: 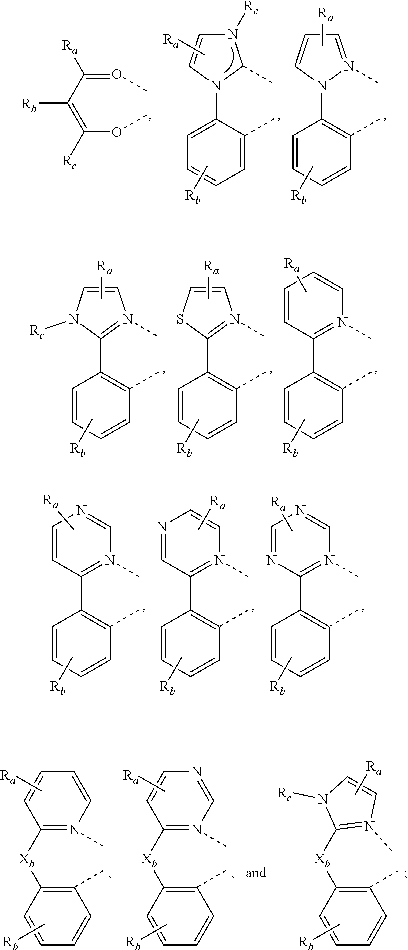
wherein
X_{b} is, at each occurrence identically or differently, selected from the group consisting of: O, S, Se, NR_{N1} and CR_{C1}R_{C2};
the substituents Rₐ and R_{b} represent, at each occurrence identically or differently, mono-substitution, multiple substitutions or non-substitution;
the substituents Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{C1} and R_{C2} can be optionally joined to form a ring.

4. The metal complex of claim 1, wherein the metal complex has a general structure of Ir(Lₐ)ₘ(L_{b})₃₋ₘ which is represented by Formula 2: 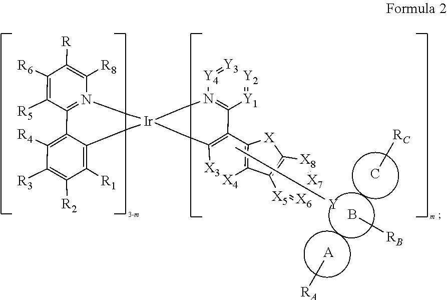
wherein
m is selected from 1, 2 or 3; when m is selected from 1, two L_{b} are the same or different;
when m is selected from 2 or 3, a plurality of Lₐ are the same or different;
X is selected from the group consisting of O, S, Se, NR′, CR′R′, SiR′R′ and GeR′R′; when two R′ are present at the same time, the two R′ are the same or different;
Y is selected from the group consisting of C, CR_{Y}, SiR_{Y} and GeR_{Y};
Y₁ to Y₄ are, at each occurrence identically or differently, selected from CR_{y} or N;
X₃ to X₈ are, at each occurrence identically or differently, selected from C, CRₓ or N; and at least one of X₃ to X₈ is selected from C and joined to Y;
the ring A, the ring B and the ring C are, at each occurrence identically or differently, selected from a carbocyclic ring having 5 to 10 ring atoms, a heterocyclic ring having 5 to 10 ring atoms or a combination thereof;
the substituents R_{A}, R_{B} and R_{C} represent, at each occurrence identically or differently, mono-substitution, multiple substitutions or non-substitution;
the substituents R′, R₁ to R₈, Rₓ, R_{y}, R_{Y}, R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C} and R_{Y} can be optionally joined to form a ring;
adjacent substituents R′, Rₓ and R_{y} can be optionally joined to form a ring; and
adjacent substituents R₁ to R₈ can be optionally joined to form a ring.

5. The metal complex of claim 1, wherein X is selected from O or S; and/or Y is selected from C.

6. The metal complex of claim 4, wherein X₃ to X₈ are, at each occurrence identically or differently, selected from C or CRₓ, and one of X₃ to X₈ is selected from C and joined to Y; the substituent Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof; and
preferably, at least one of the substituent Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

7. The metal complex of claim 1, wherein the ring A, the ring B and the ring C are, at each occurrence identically or differently, selected from a carbocyclic ring having 5 to 6 ring atoms, a heterocyclic ring having 5 to 6 ring atoms or a combination thereof;
preferably, the ring A, the ring B and the ring C are, at each occurrence identically or differently, selected from a benzene ring, a heterocyclic ring having 5 to 6 ring atoms or a combination thereof; and
more preferably, the ring A, the ring B and the ring C are, at each occurrence identically or differently, selected from a benzene ring, a pyridine ring, a pyrimidine ring, a thiophene ring or a furan ring.

8. The metal complex of claim 4, wherein at least one of X₃ to X₈ is selected from C and joined to Y;
preferably, at least one of X₅ to X₈ is selected from C and joined to Y; and
more preferably, at least one of X₇ or X₈ is selected from C and joined to Y.

9. The metal complex of claim 4, wherein at least one of X₃ to X₈ is selected from CRₓ, and the Rₓ is selected from cyano or fluorine;
preferably, at least one of X₅ to X₈ is CRₓ, and the Rₓ is selected from cyano or fluorine; and
more preferably, at least one of X₇ or X₈ is selected from CRₓ, and the Rₓ is selected from cyano or fluorine.

10. The metal complex of claim 1, wherein the substituents R_{A}, R_{B} and R_{C} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof; and
preferably, the substituents R_{A}, R_{B} and R_{C} are, at each occurrence identically or differently, selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

11. The metal complex of claim 1, wherein 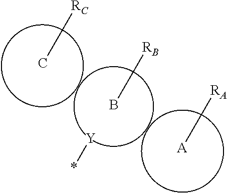
is selected from the group consisting of the following groups: 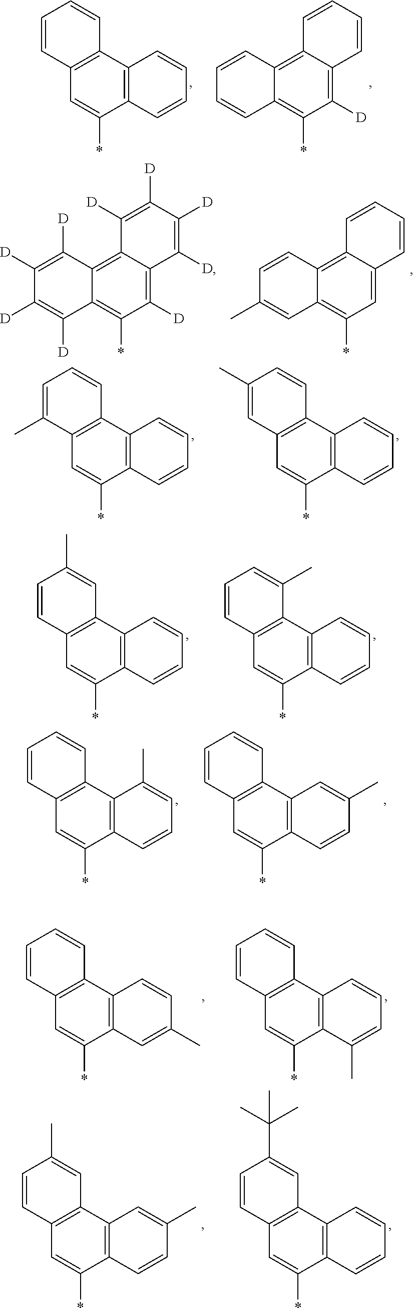 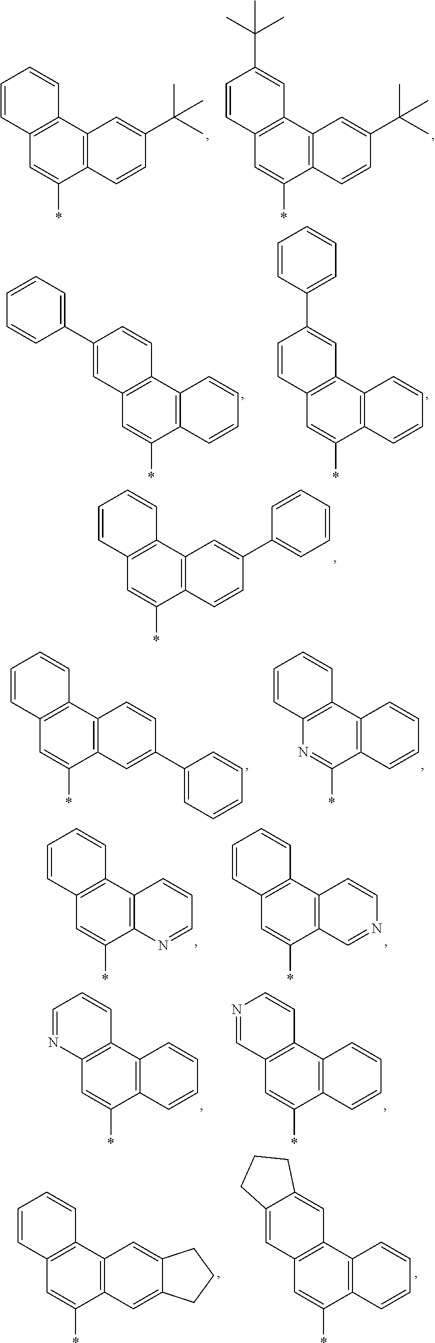 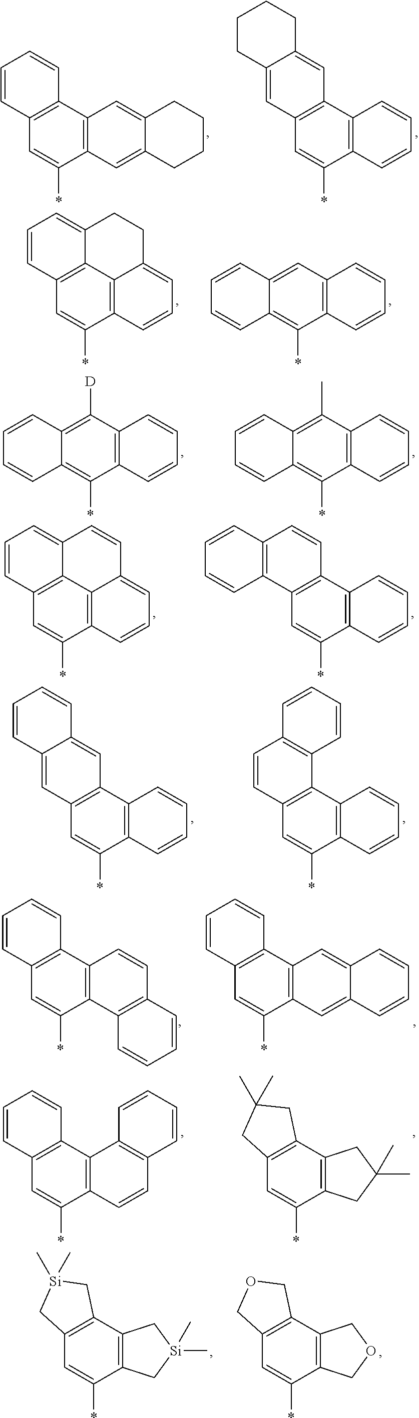 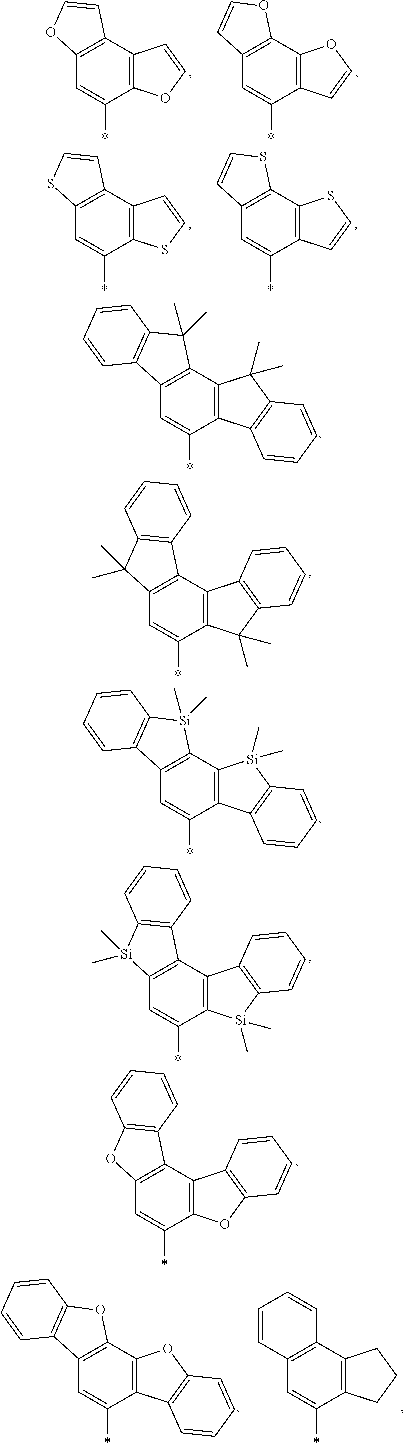 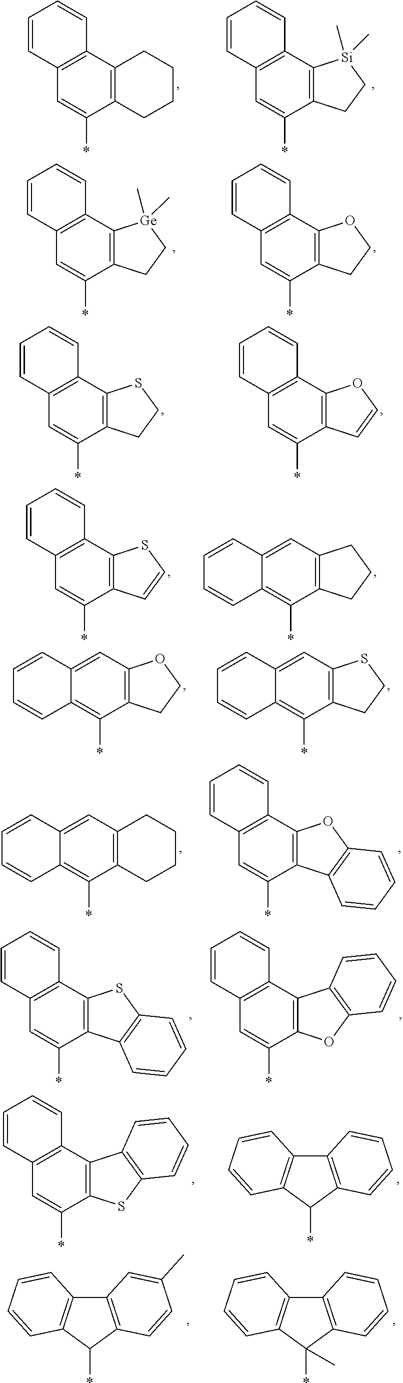 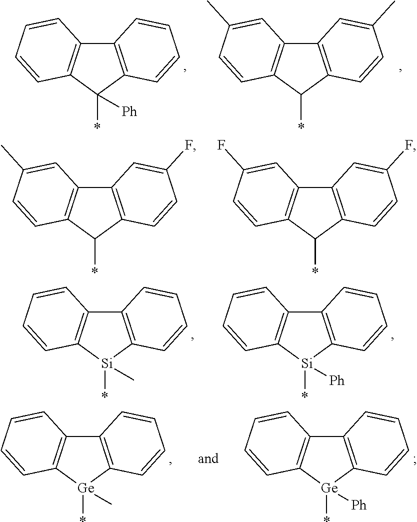
wherein “*” represents a position where the group is joined; and
optionally, hydrogens in the above groups can be partially or fully deuterated.

12. The metal complex of claim 4, wherein Y₁ to Y₄ are, at each occurrence identically or differently, selected from CR_{y}, and the substituent R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof; and
preferably, at least one of the substituent R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

13. The metal complex of claim 4, wherein at least one or at least two of the substituents R₁ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₁ to R₄ and/or the substituents R₅ to R₈ is at least 4; and
preferably, at least one or at least two of the substituents R₁ to R₄ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₁ to R₄ is at least 4; and/or at least one or at least two of the substituents R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of the substituents R₅ to R₈ is at least 4.

14. The metal complex of claim 4, wherein at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, at least one, at least two, at least three or all of the substituents R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, and combinations thereof; and
more preferably, at least one, at least two, at least three or all of the substituents R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl, and combinations thereof;
optionally, hydrogens in the above groups can be partially or fully deuterated.

15. The metal complex of claim 1, wherein the ligand Lₐ is, at each occurrence identically or differently, selected from the group consisting of Lₐ₁ to Lₐ₂₅₈; 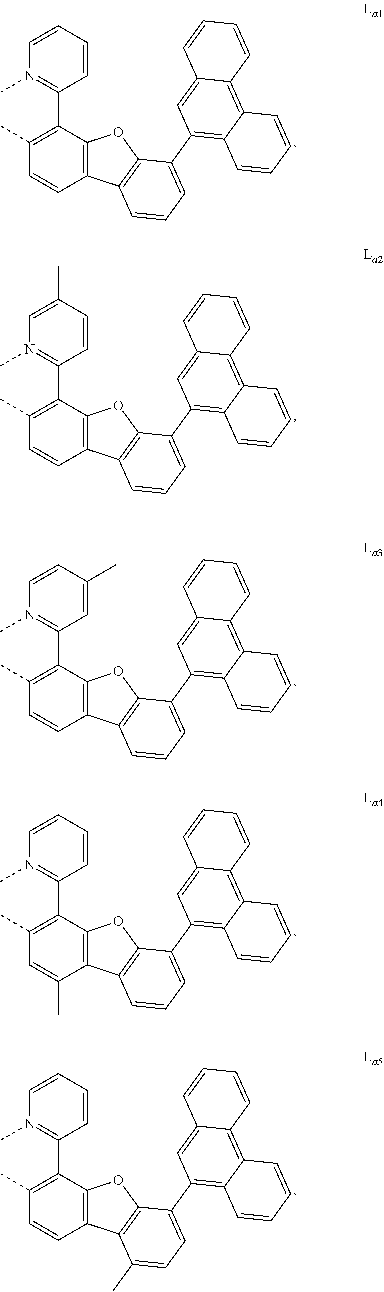 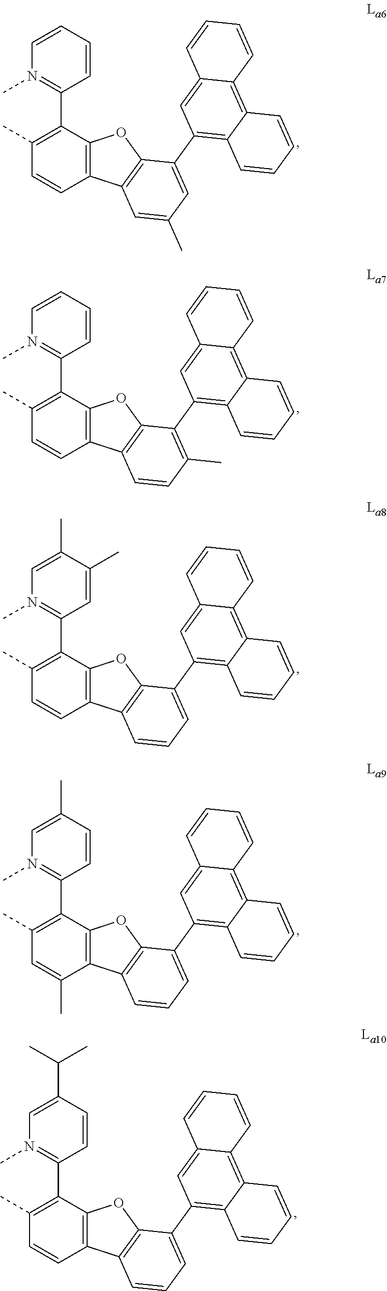 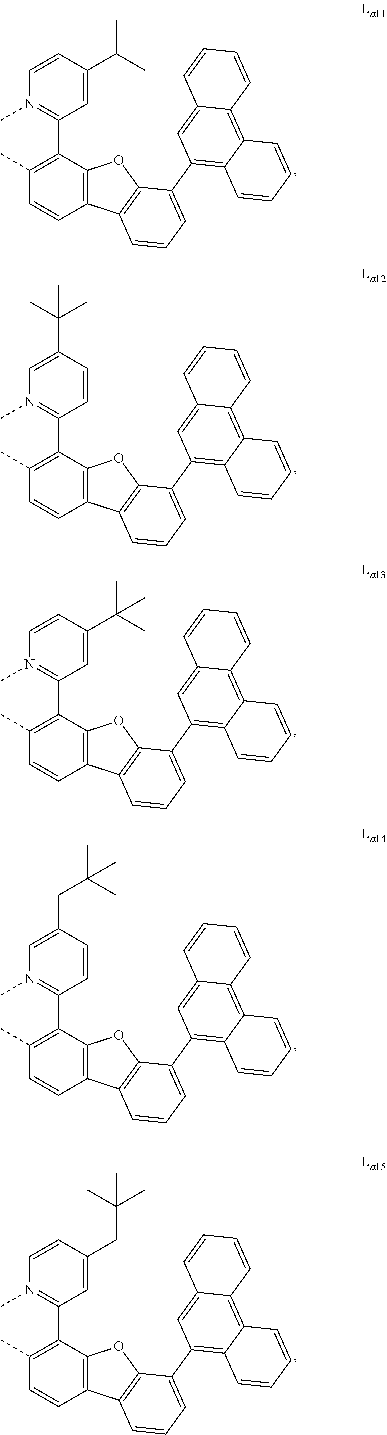 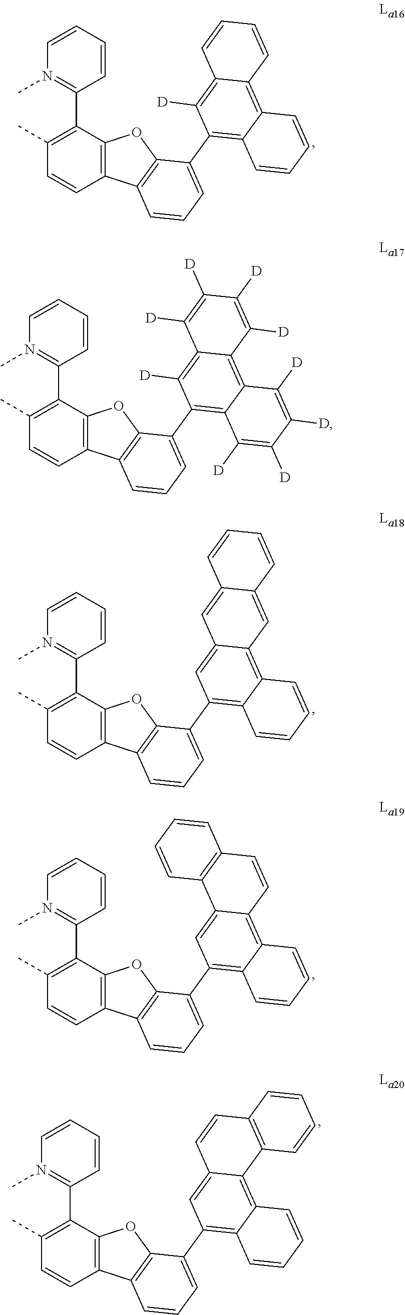 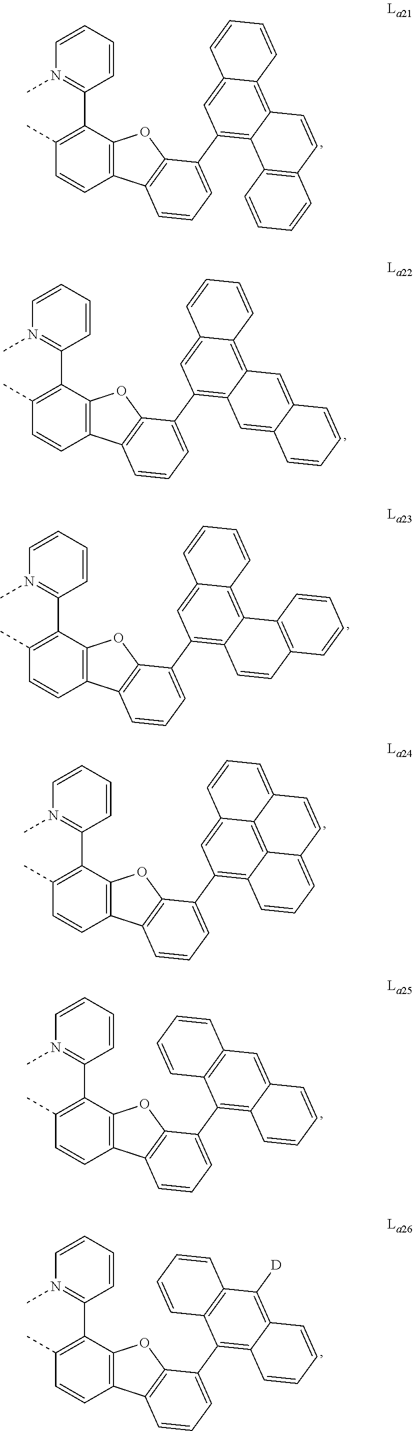 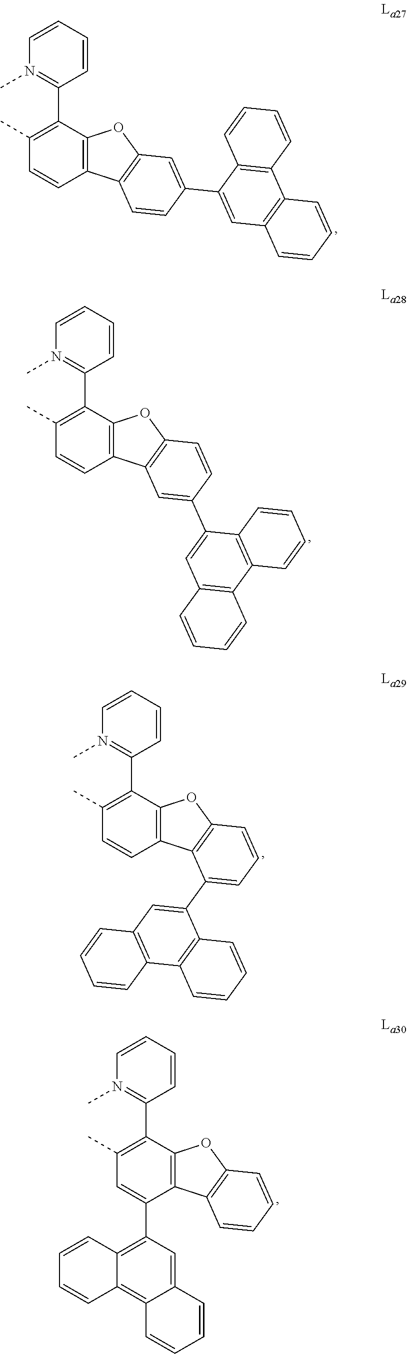 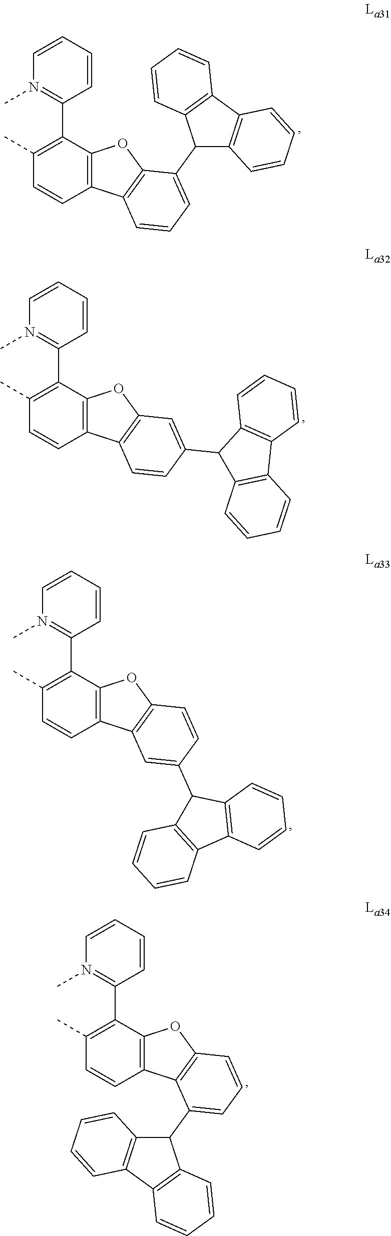 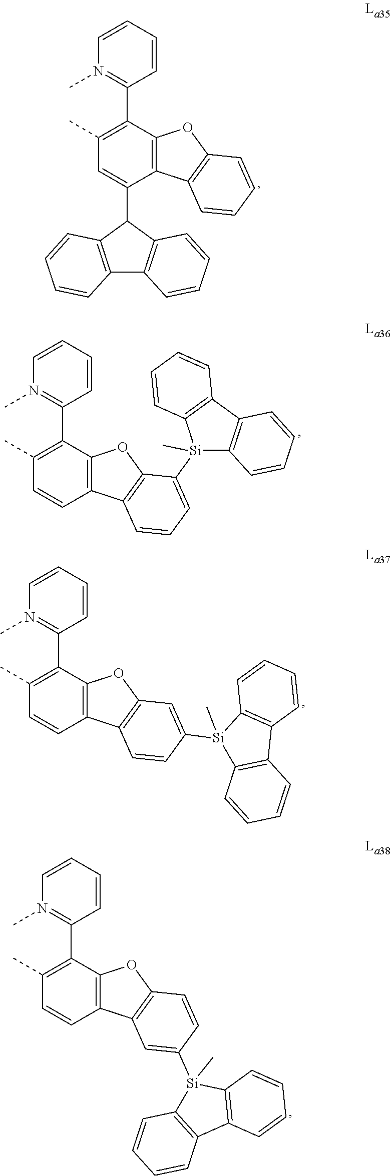 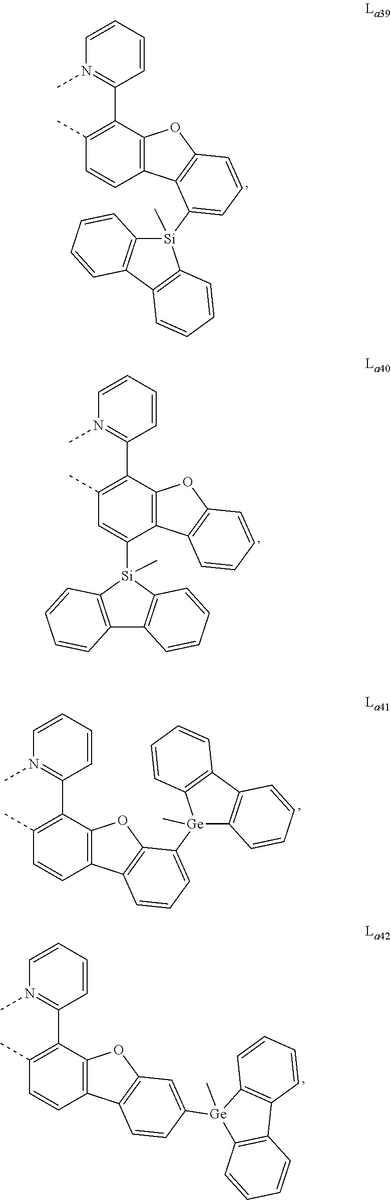 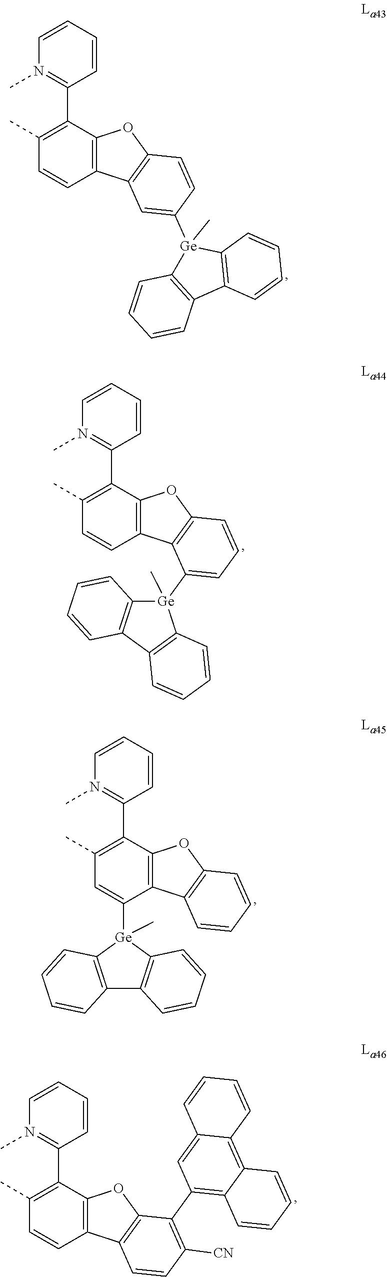 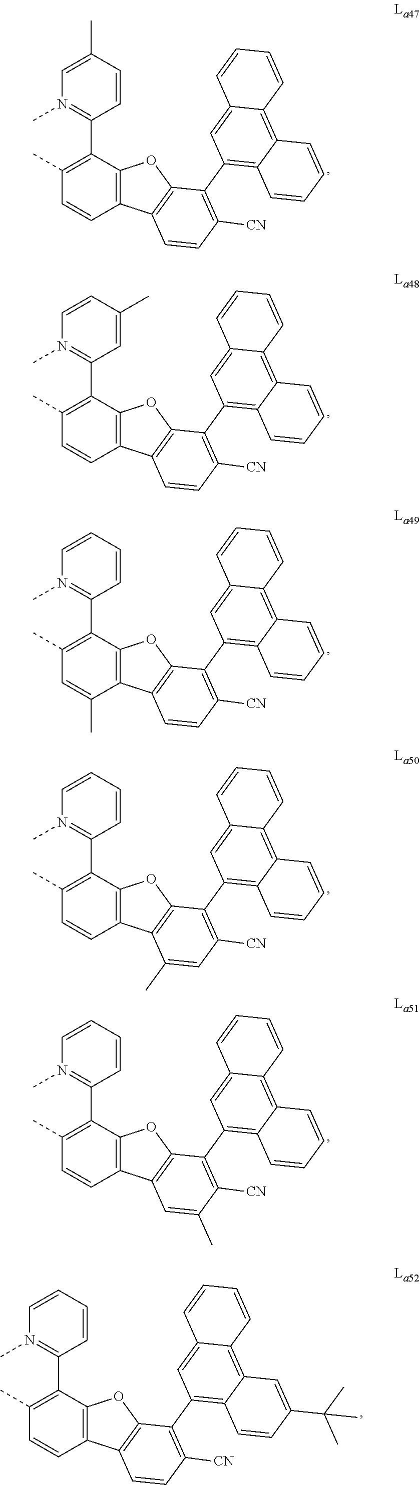 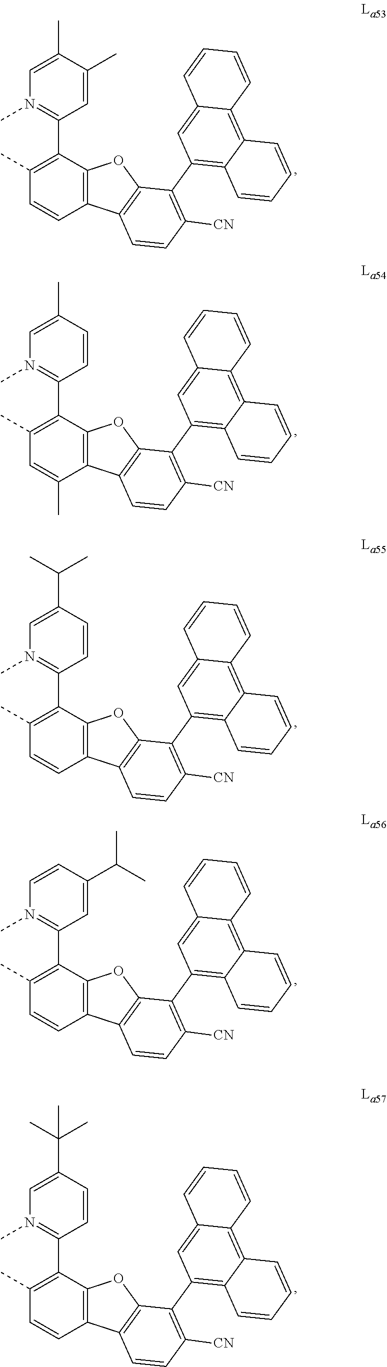 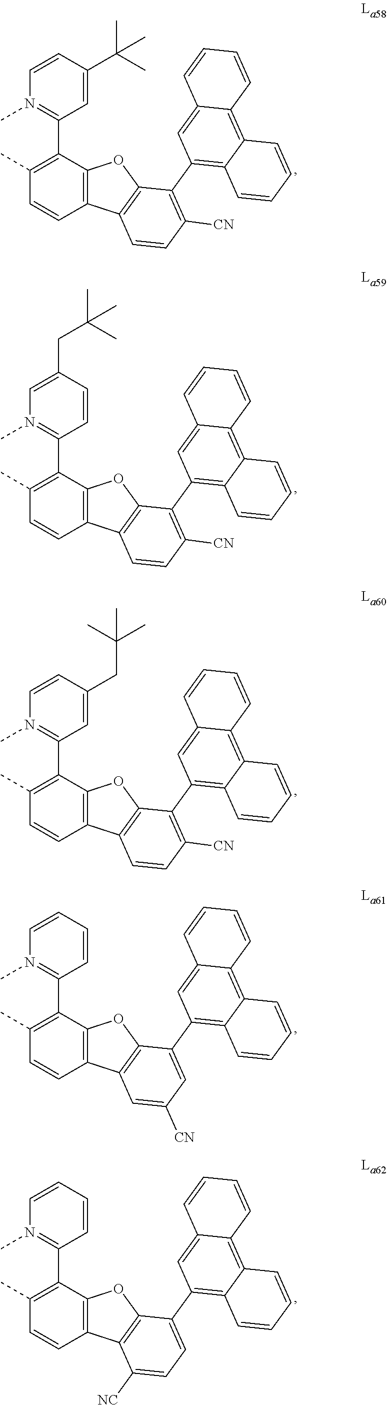 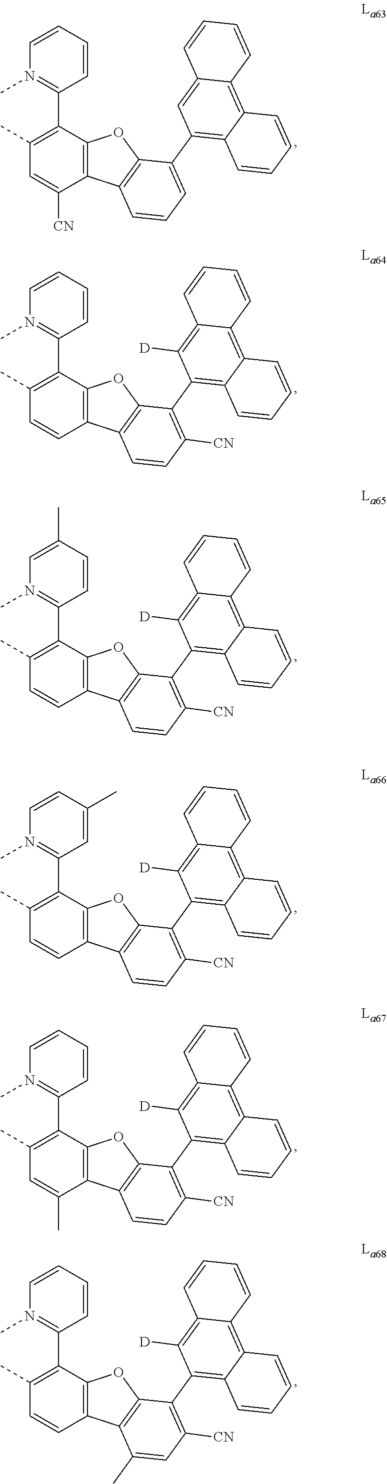 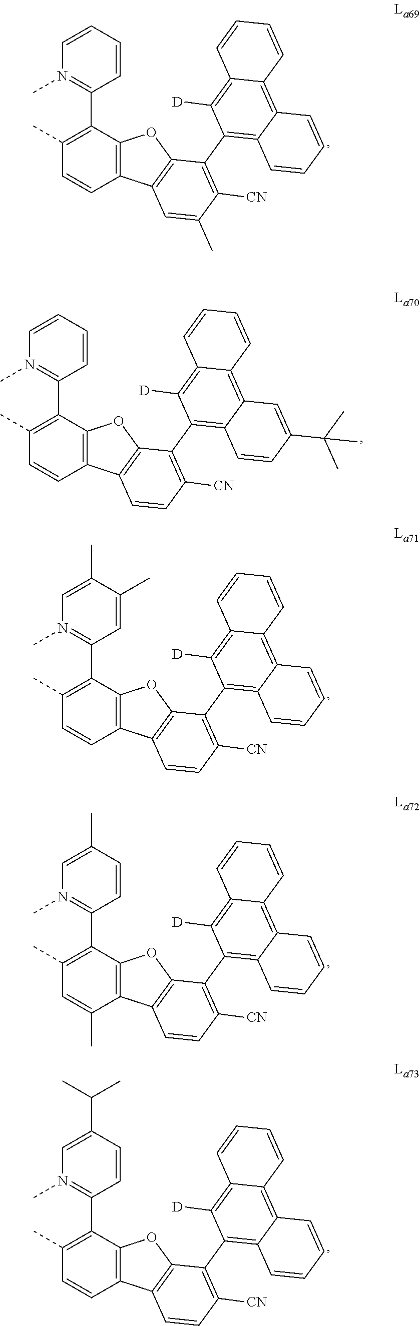 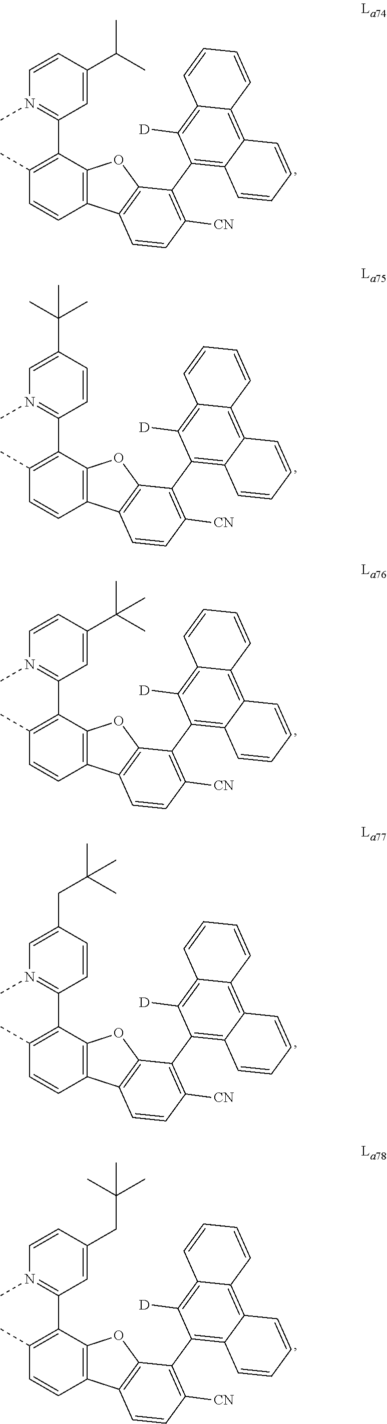 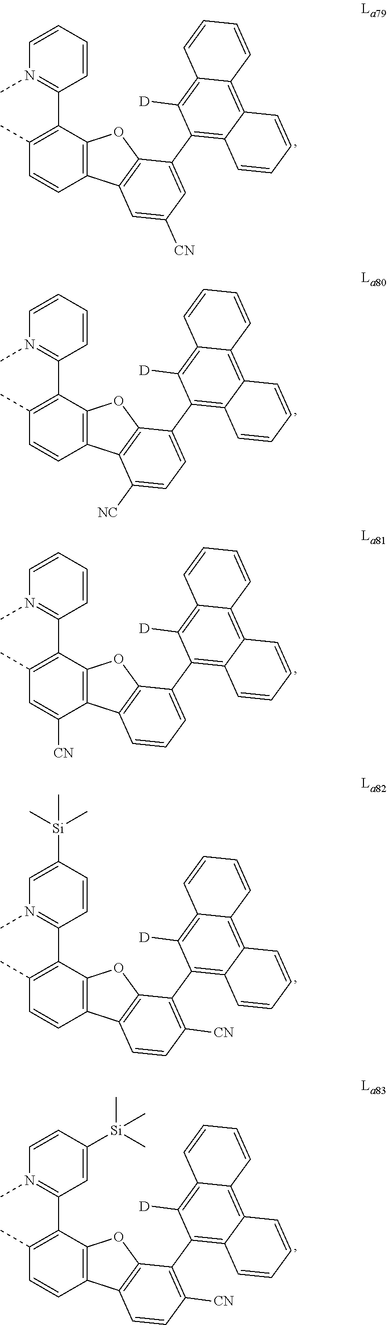 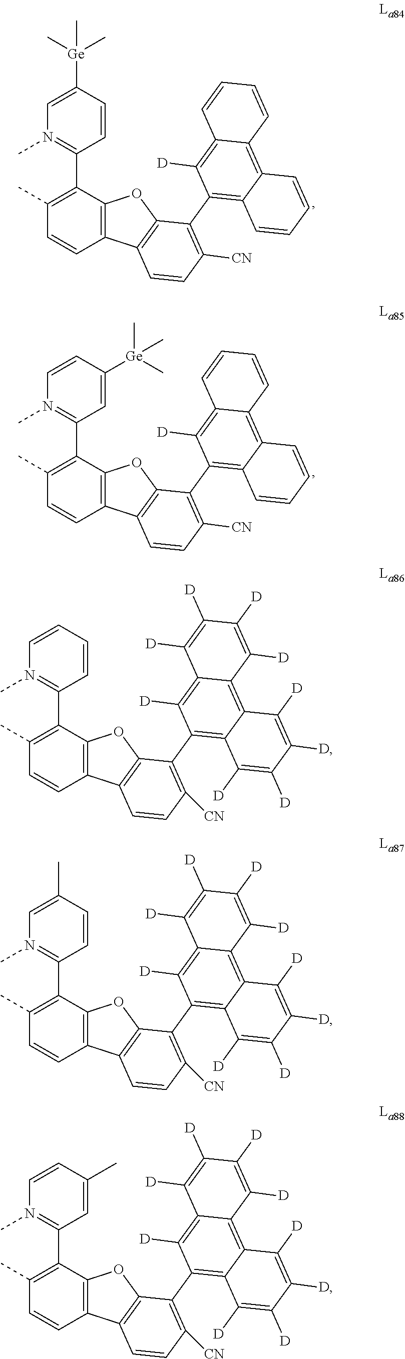 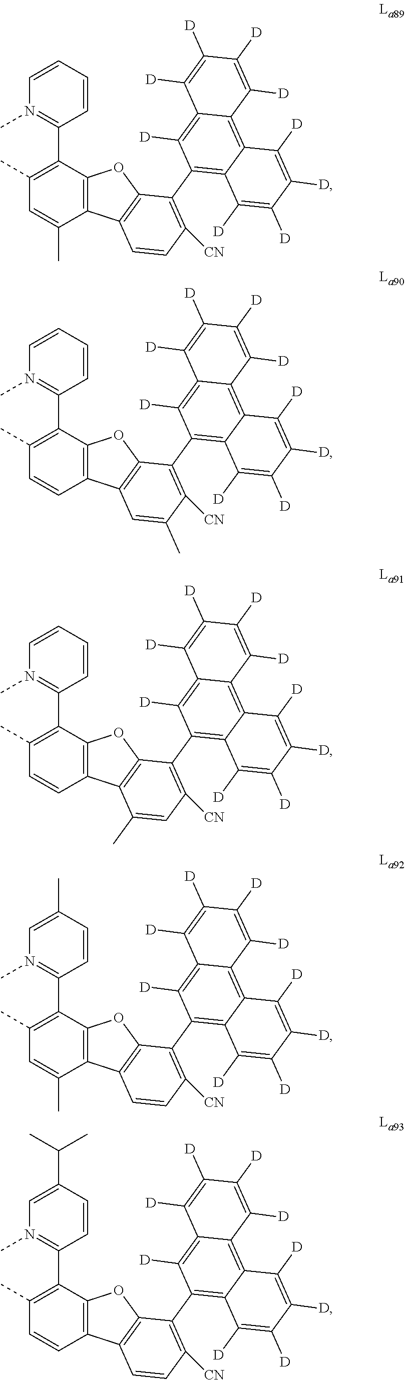 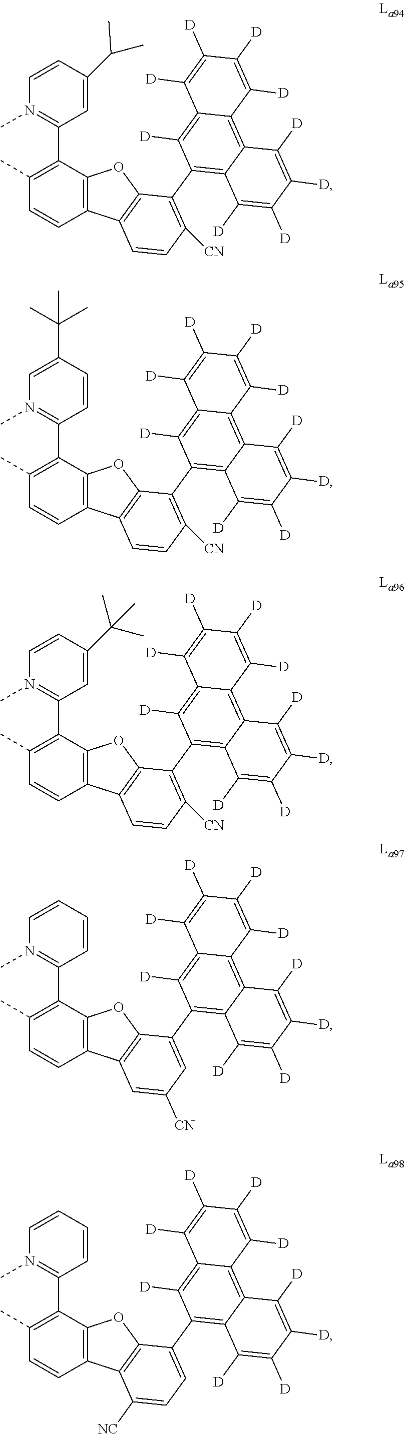 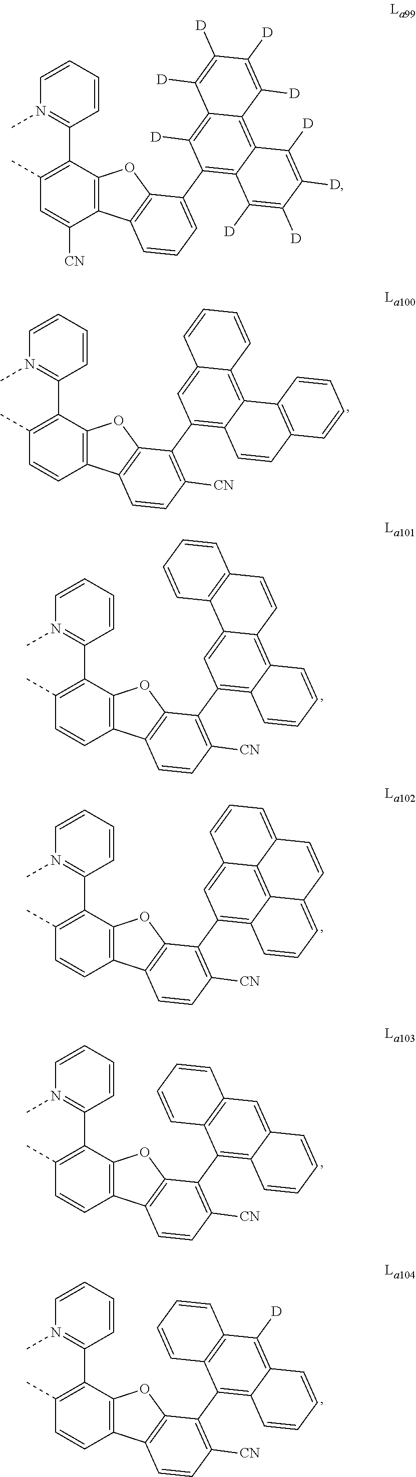 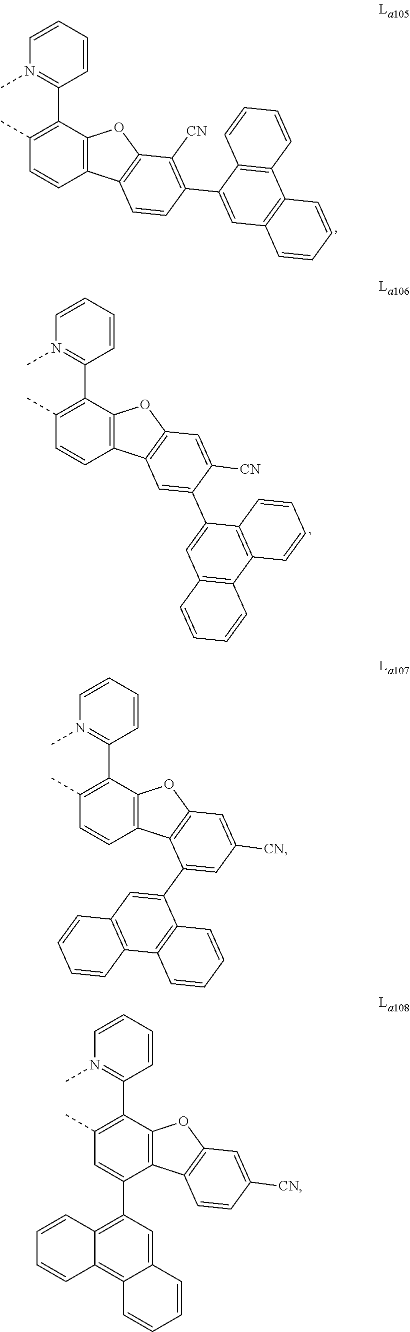 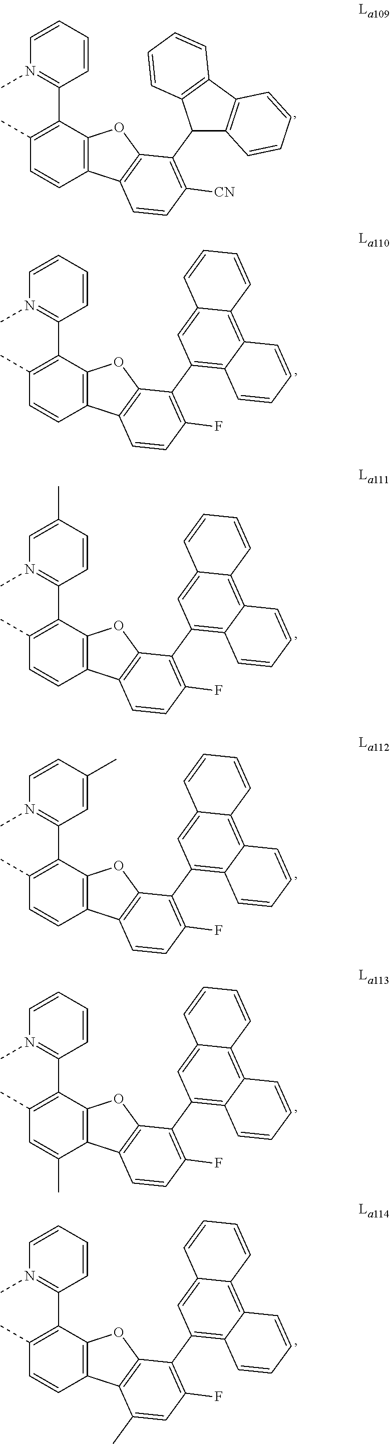 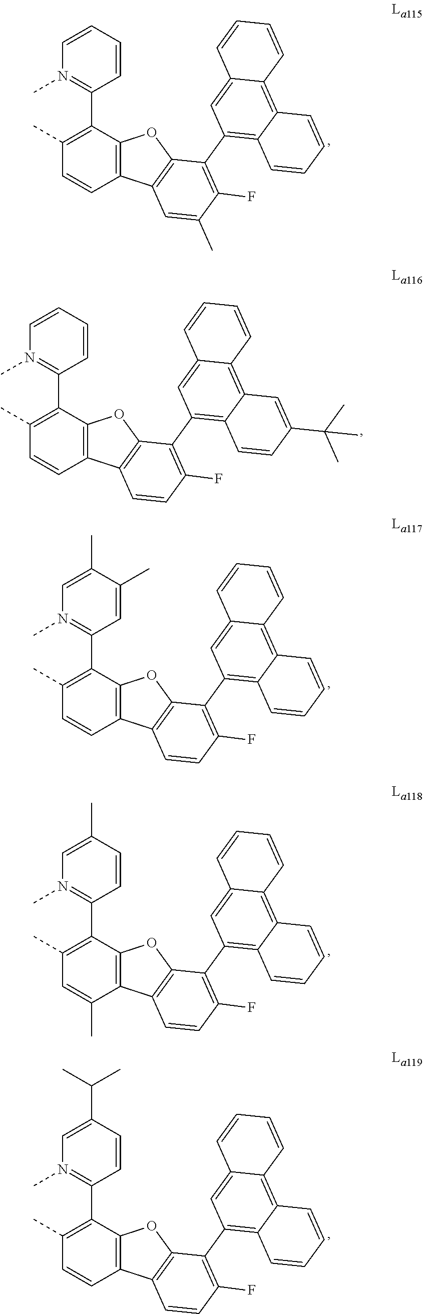 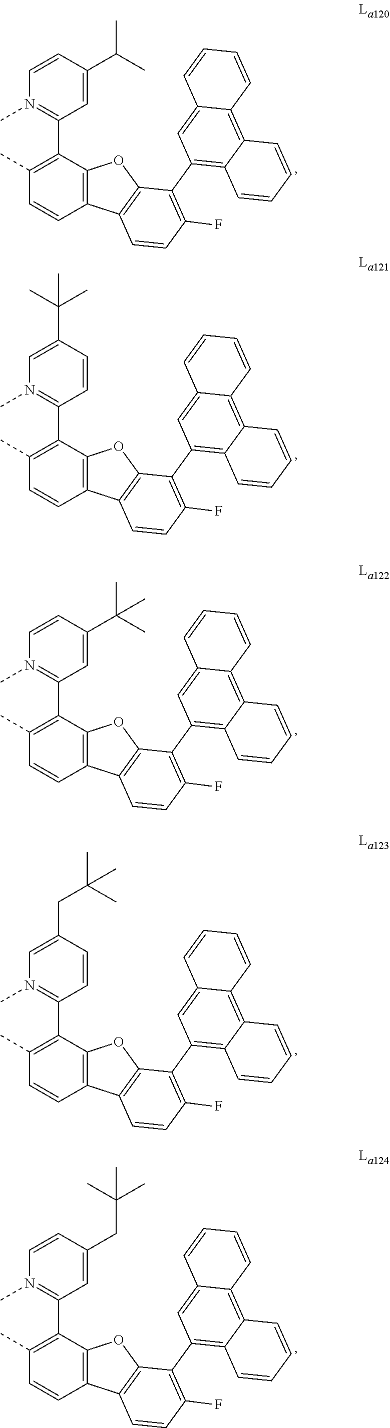 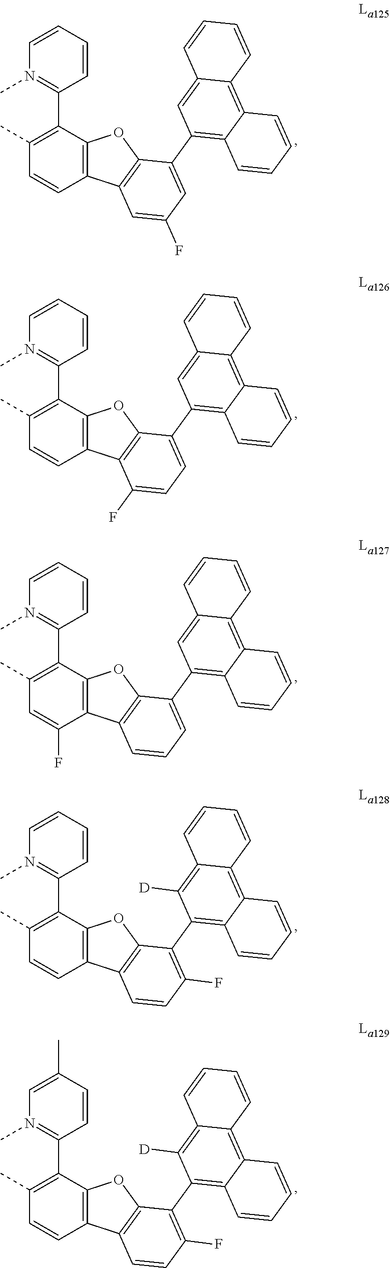 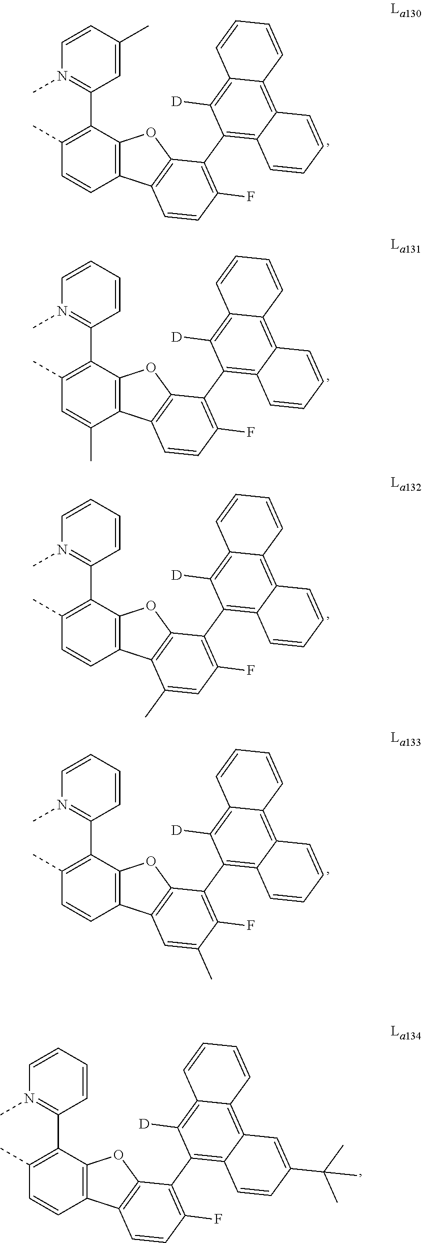 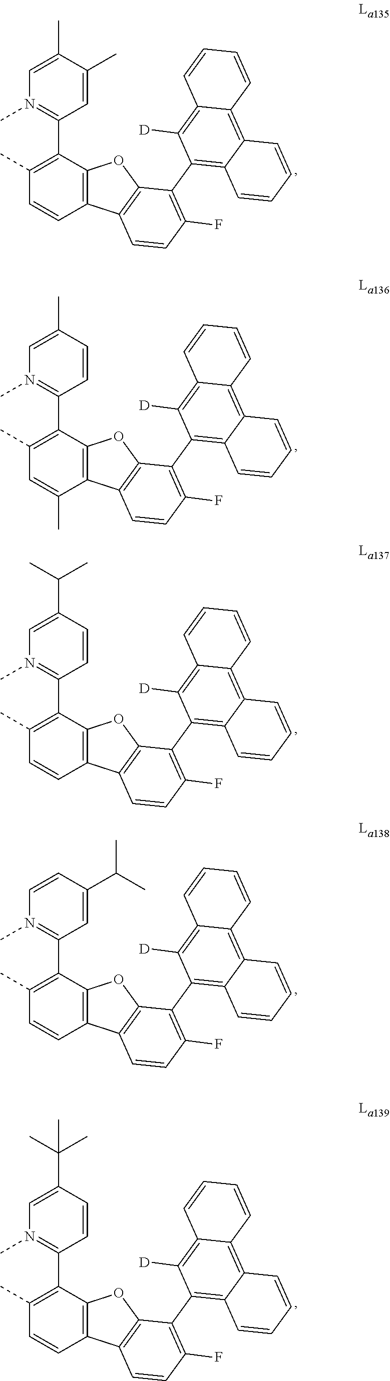 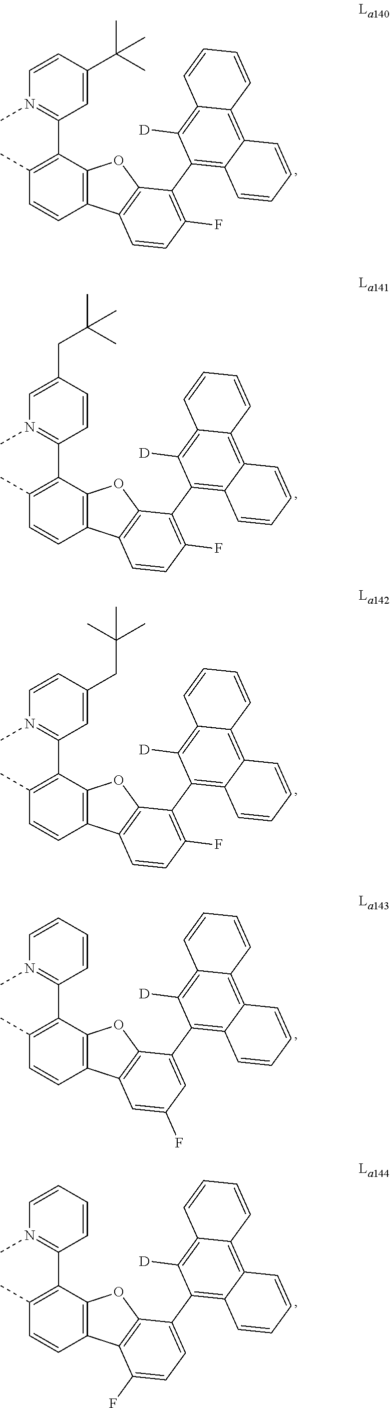 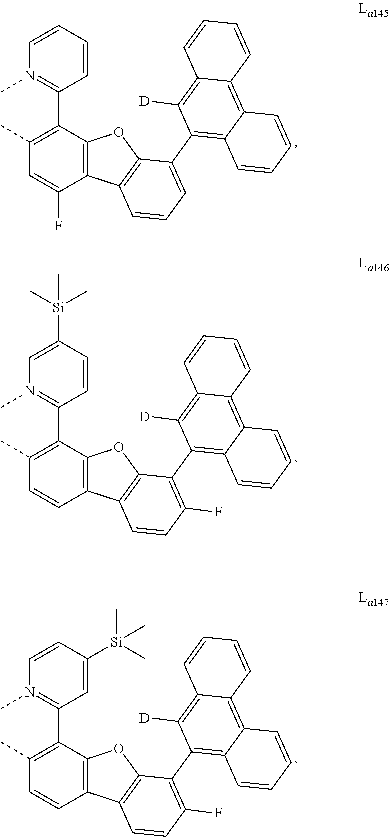 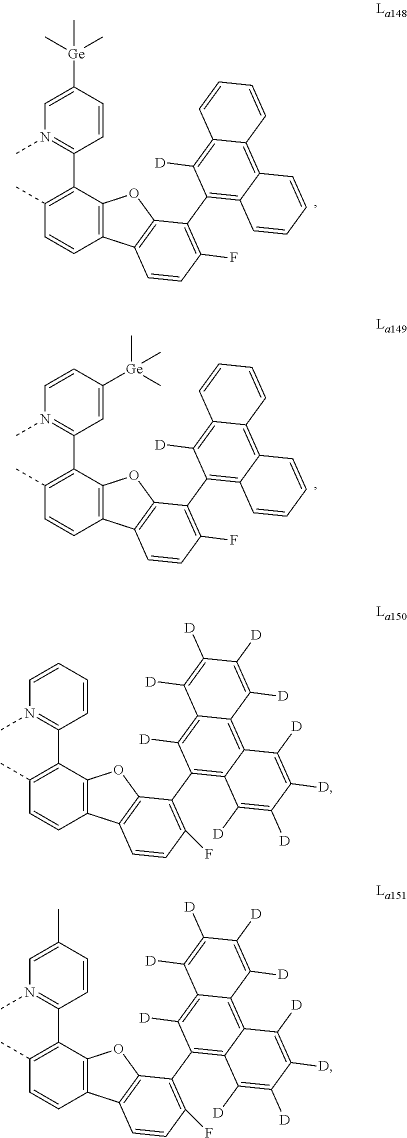 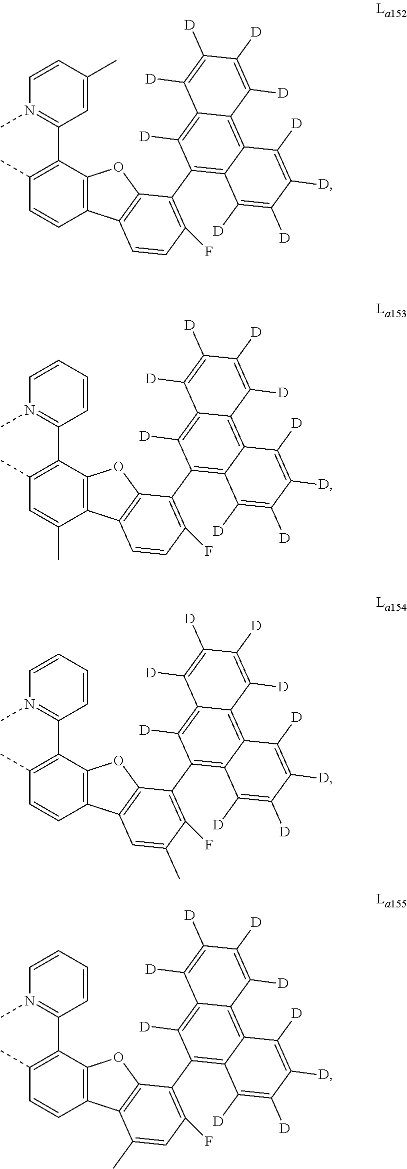 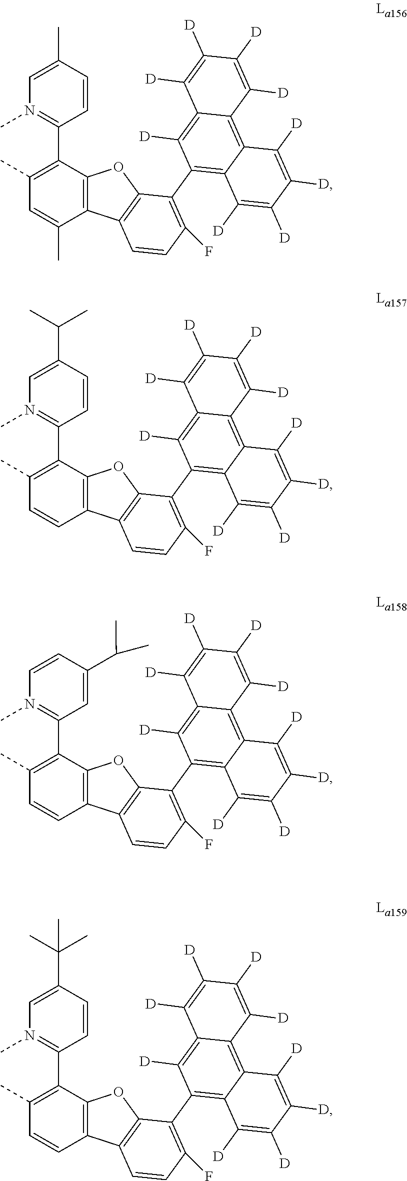 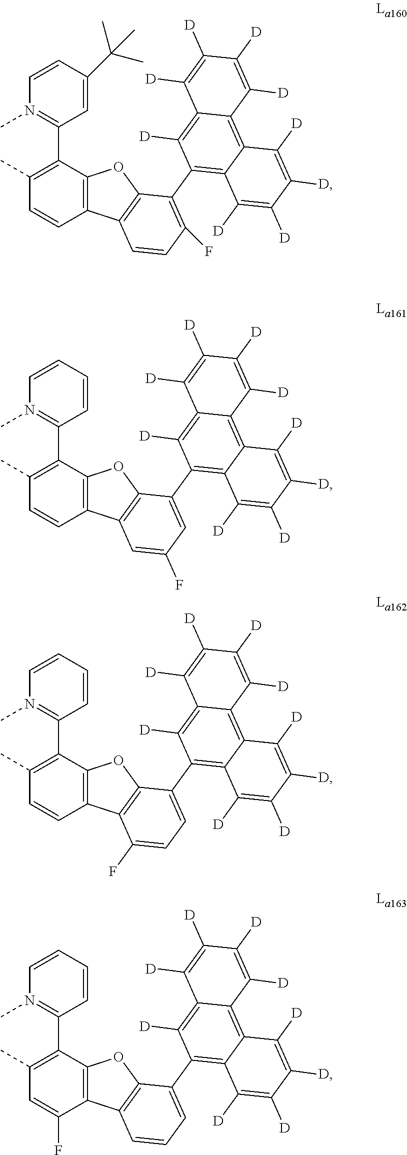 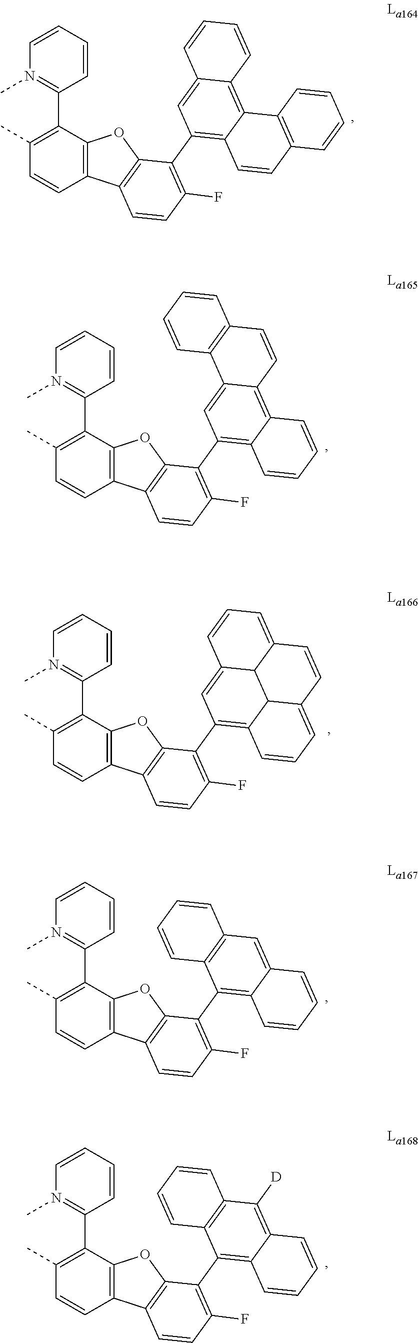 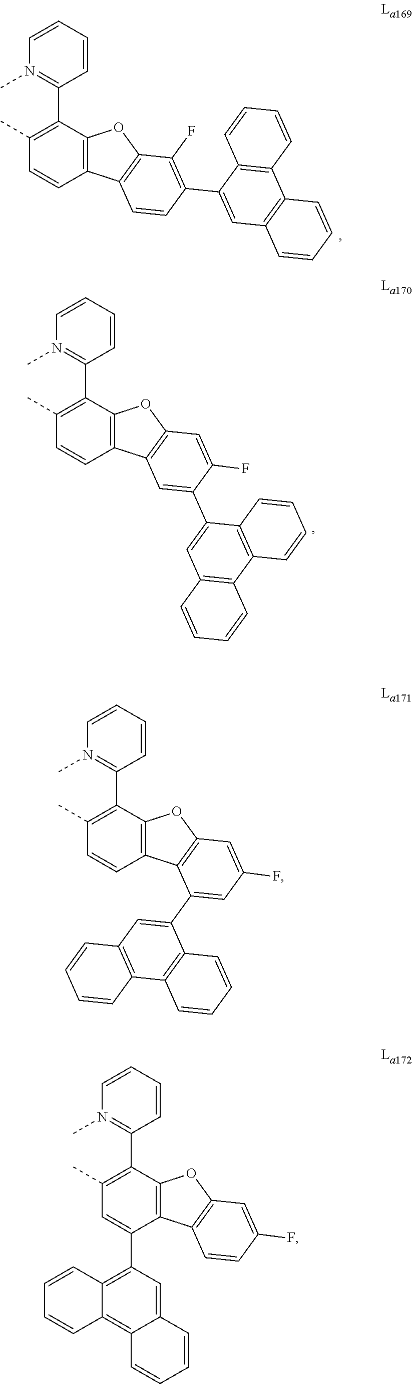 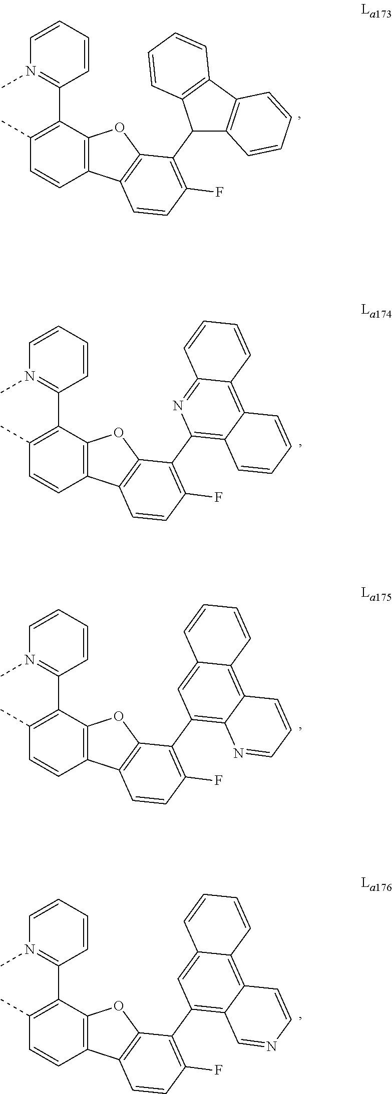 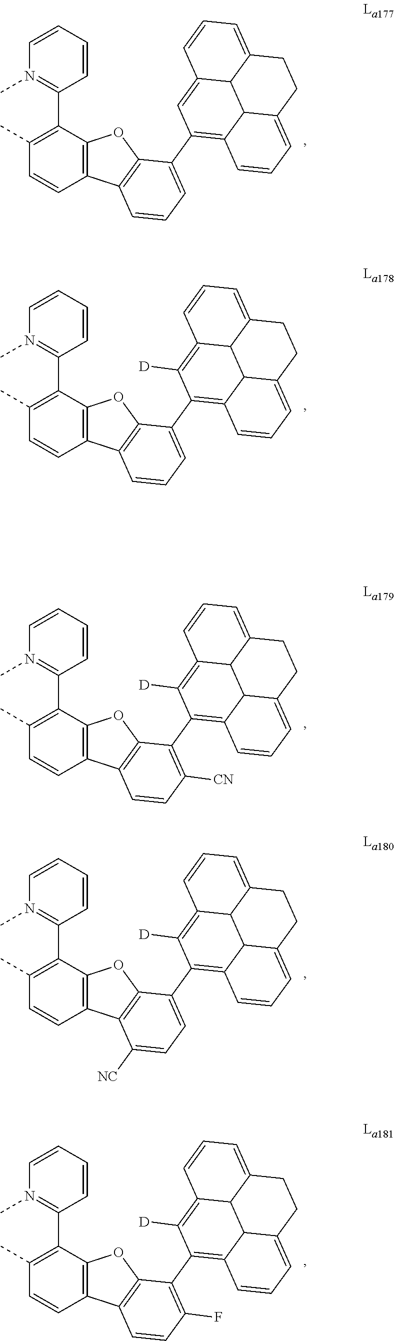 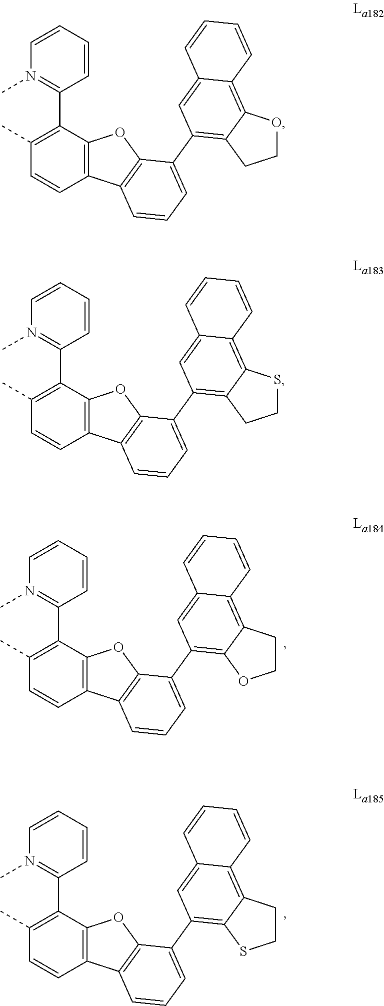 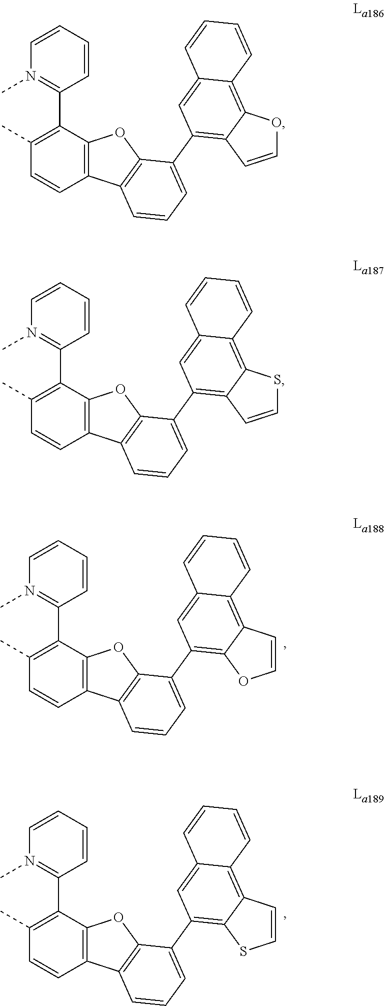 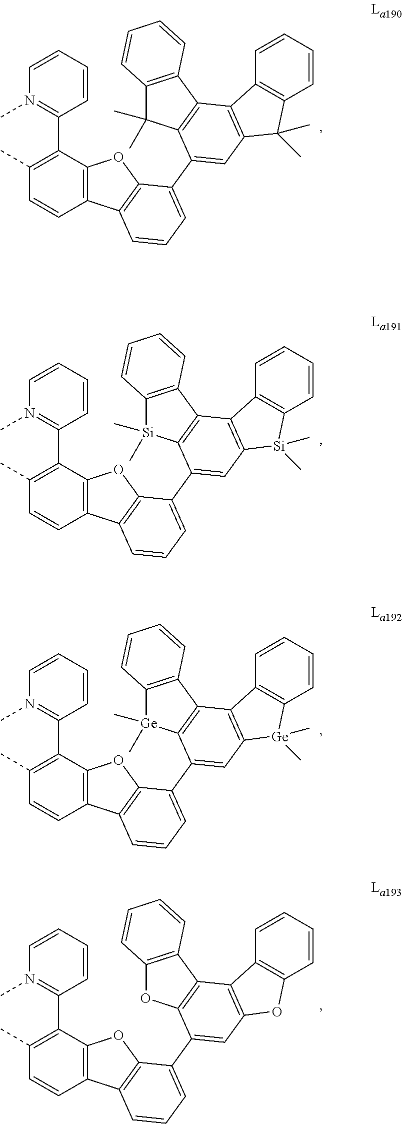 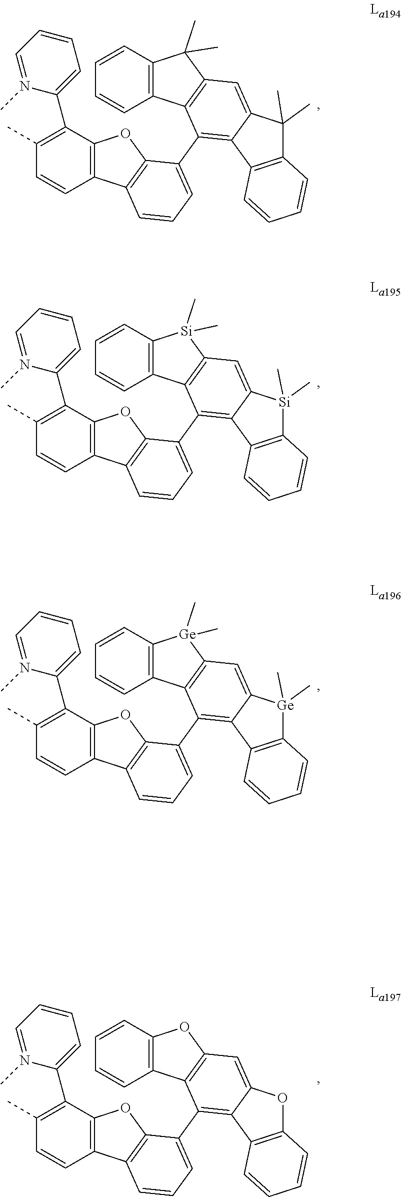 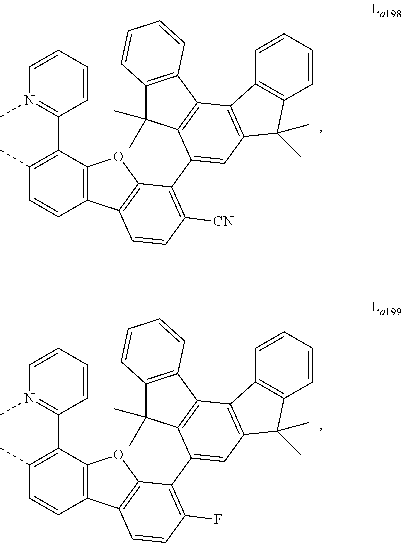 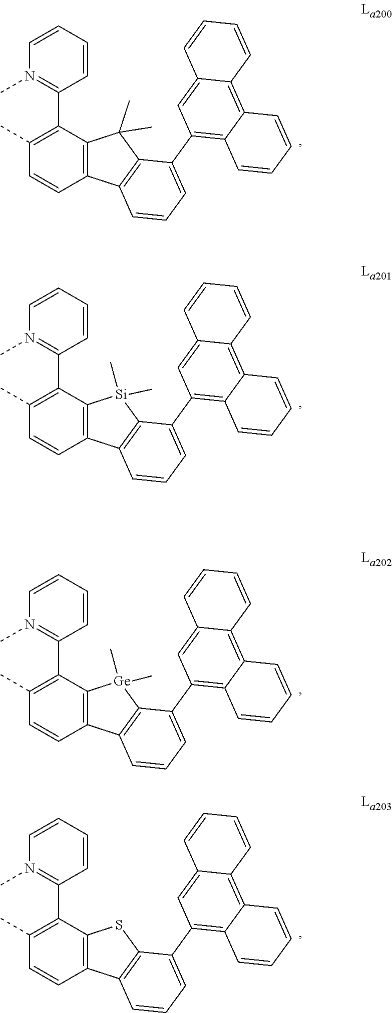 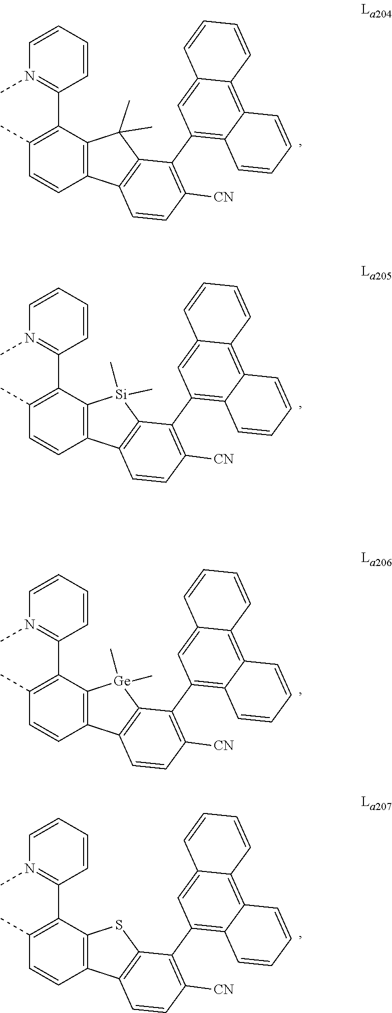 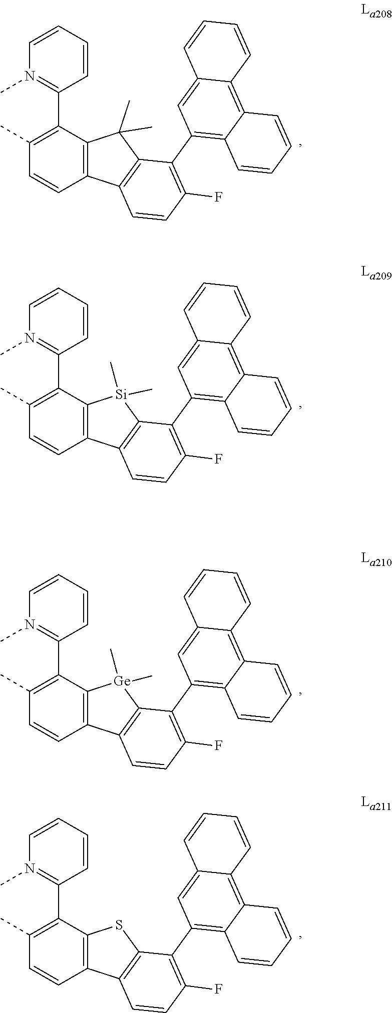 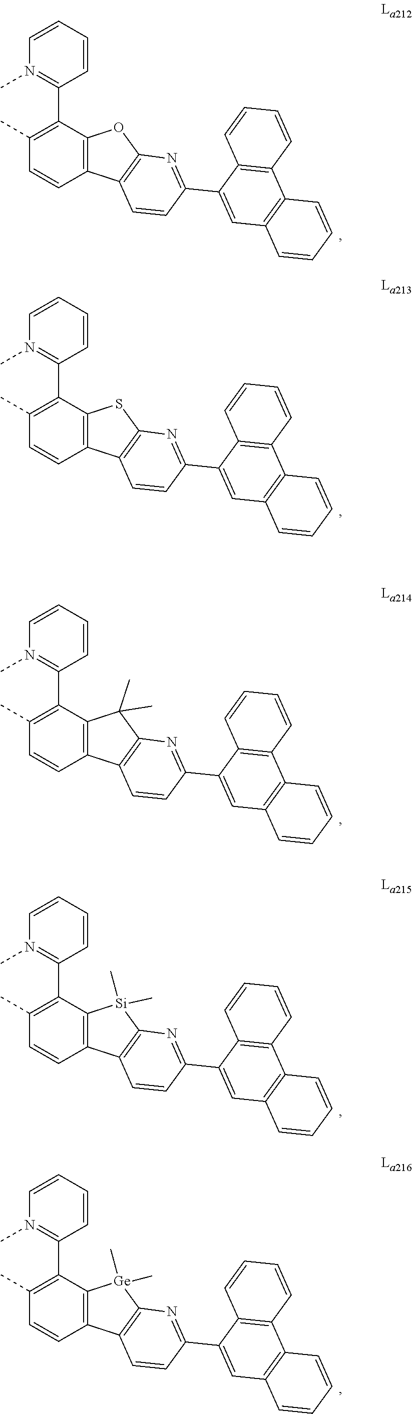 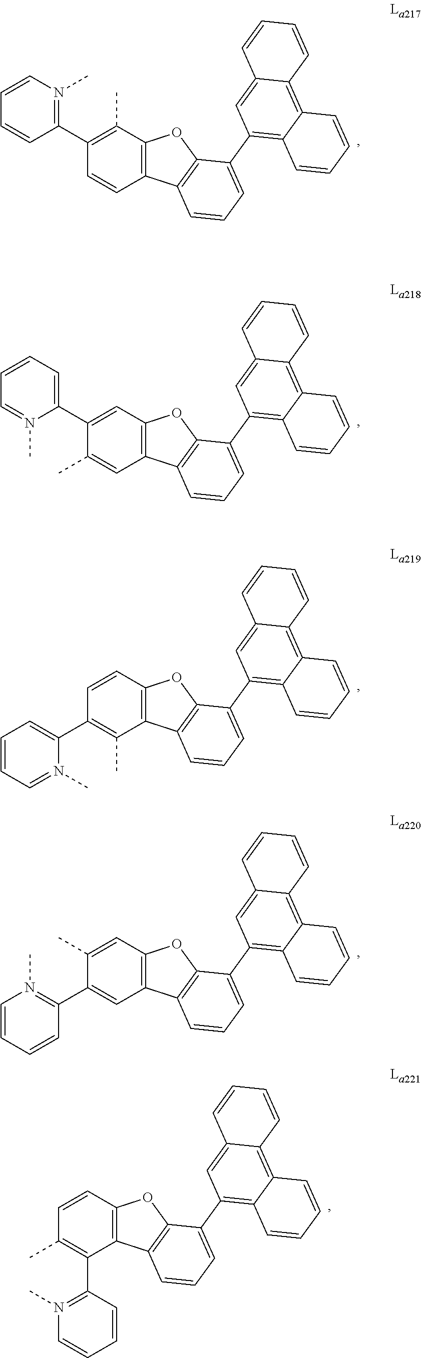 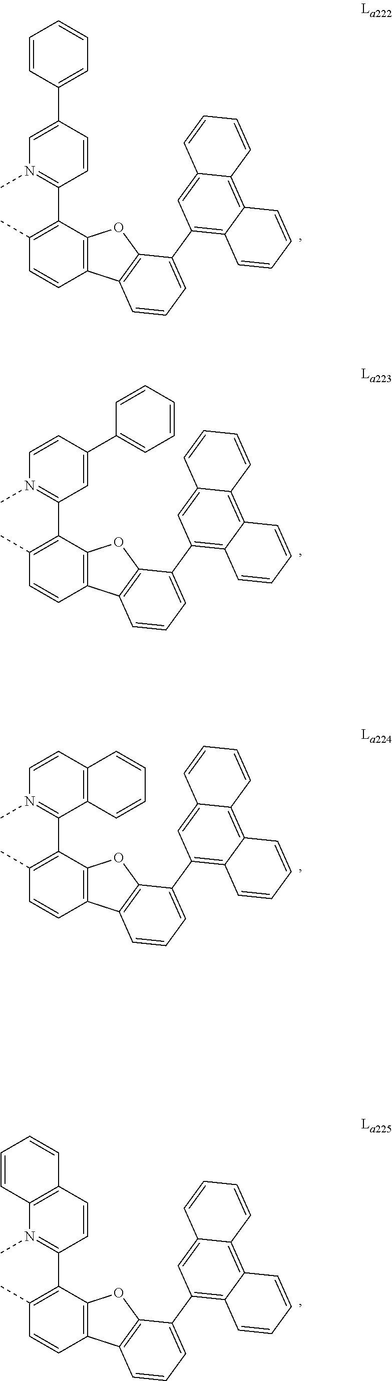 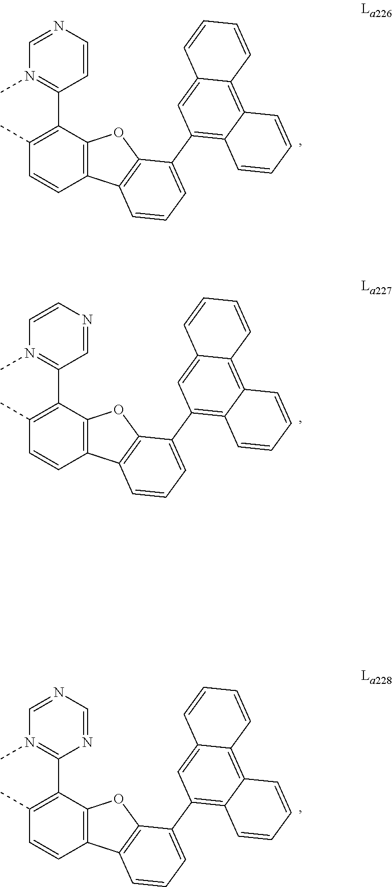 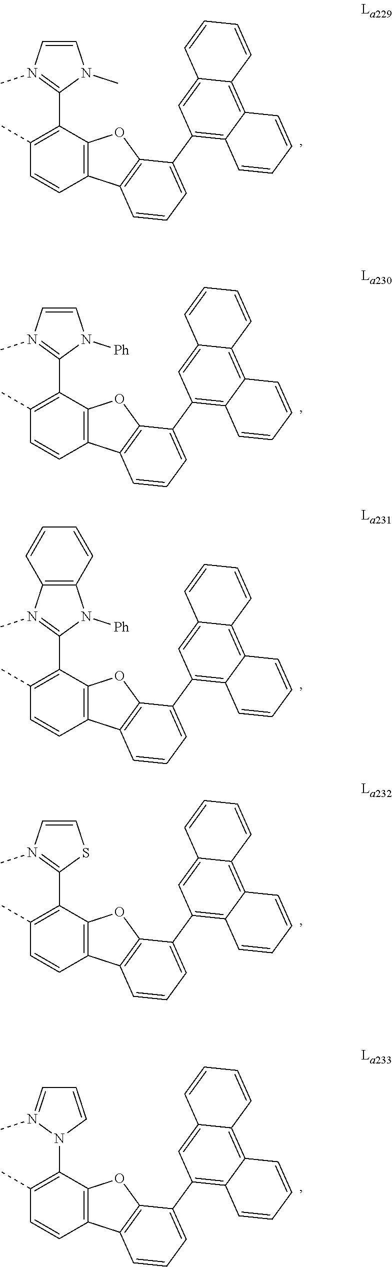 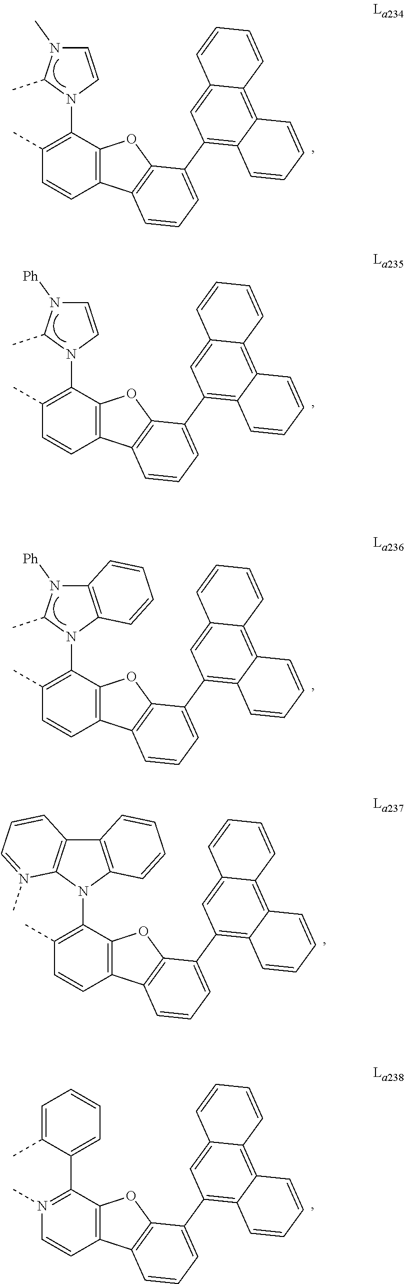 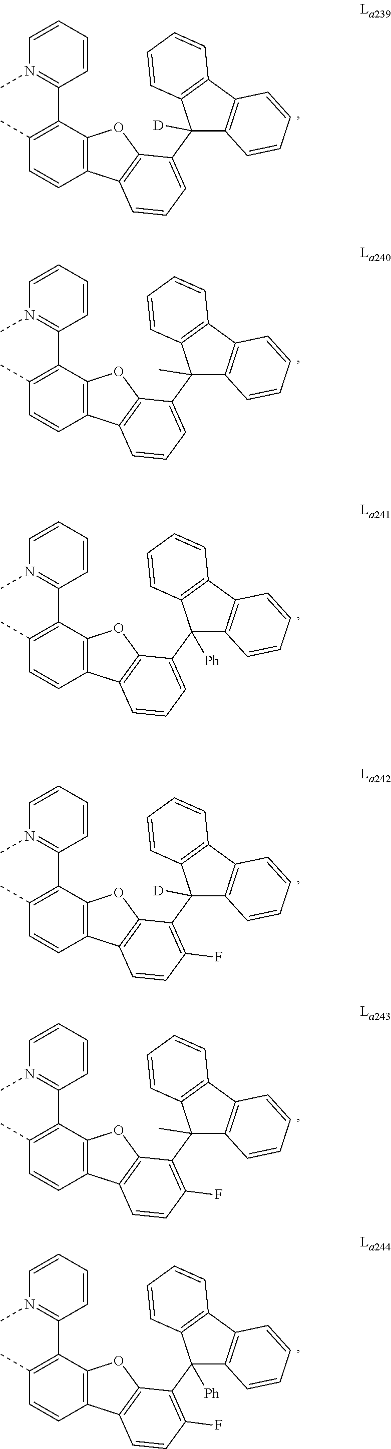 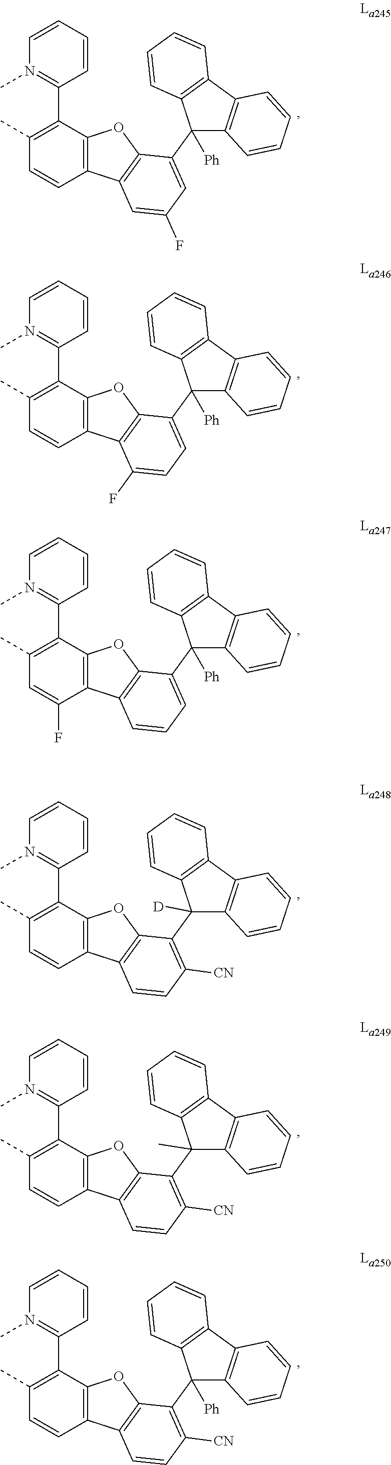 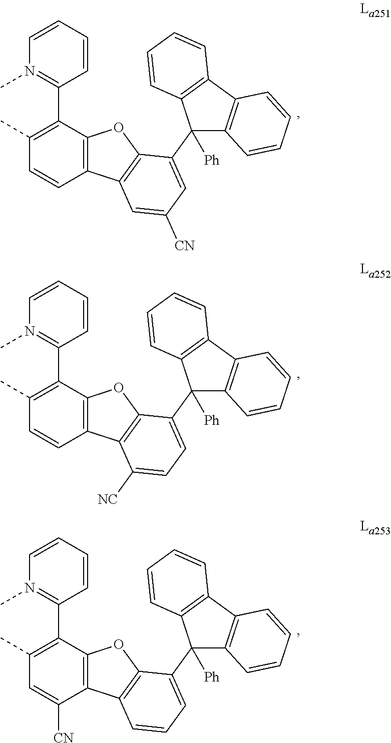 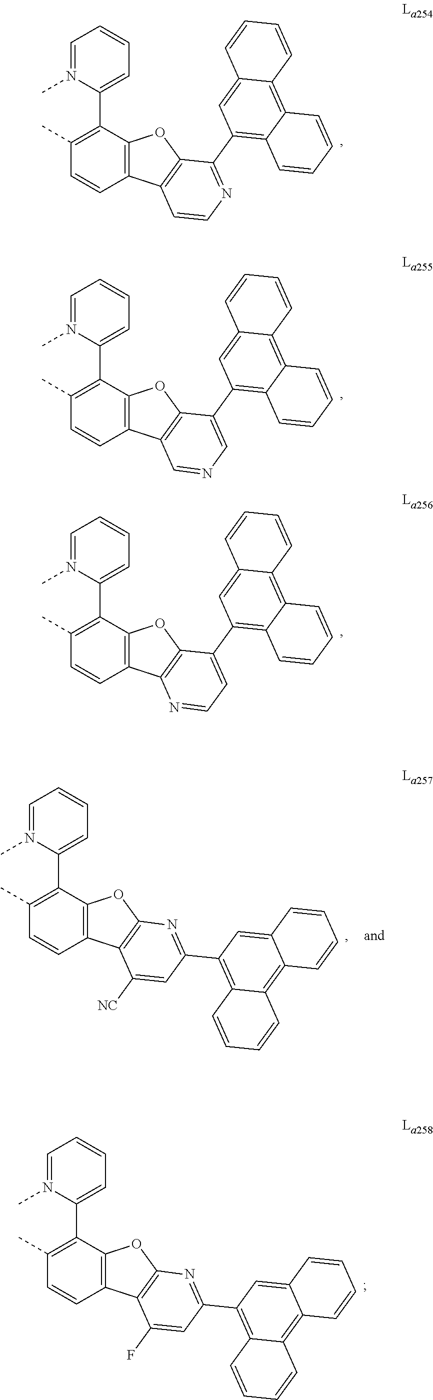
optionally, hydrogens in Lₐ₁ to Lₐ₂₅₈ can be partially or fully deuterated.

16. The metal complex of claim 15, wherein L_{b} is, at each occurrence identically or differently, selected from the group consisting of: 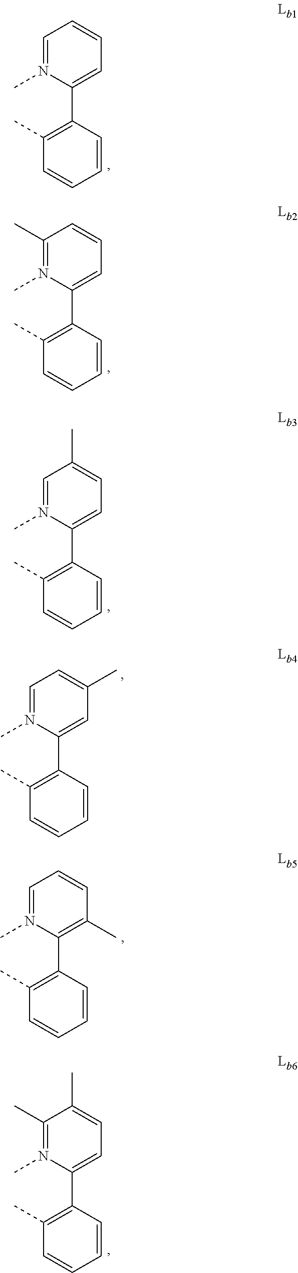 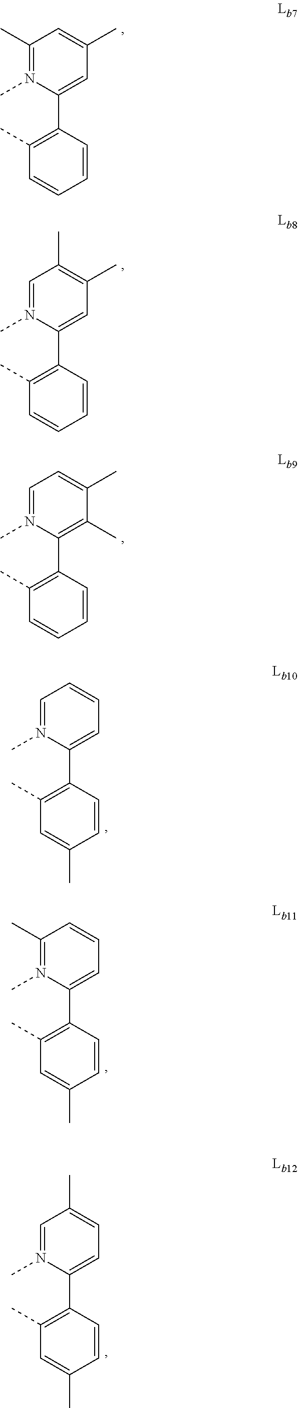 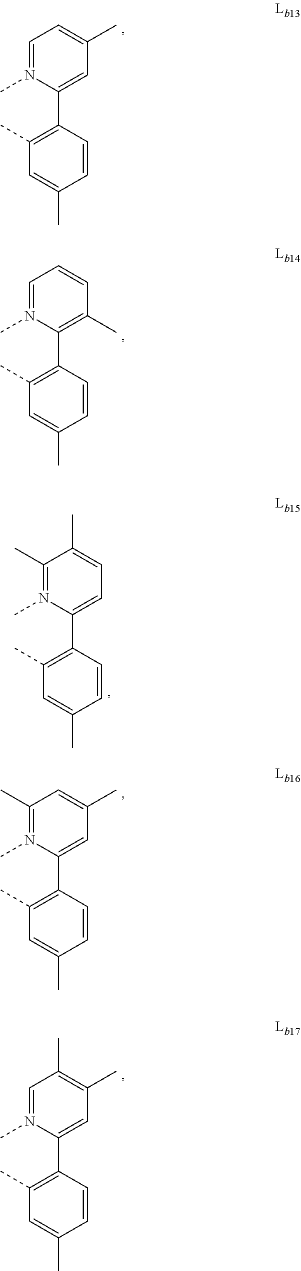 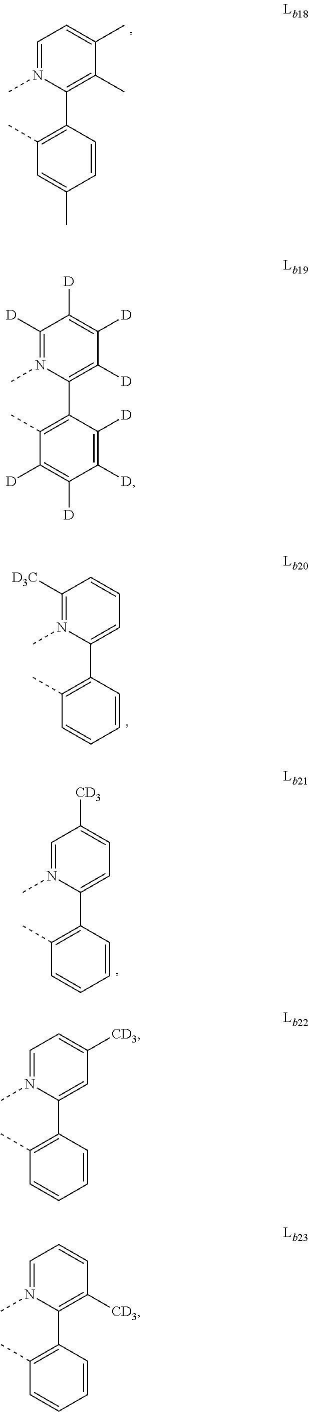 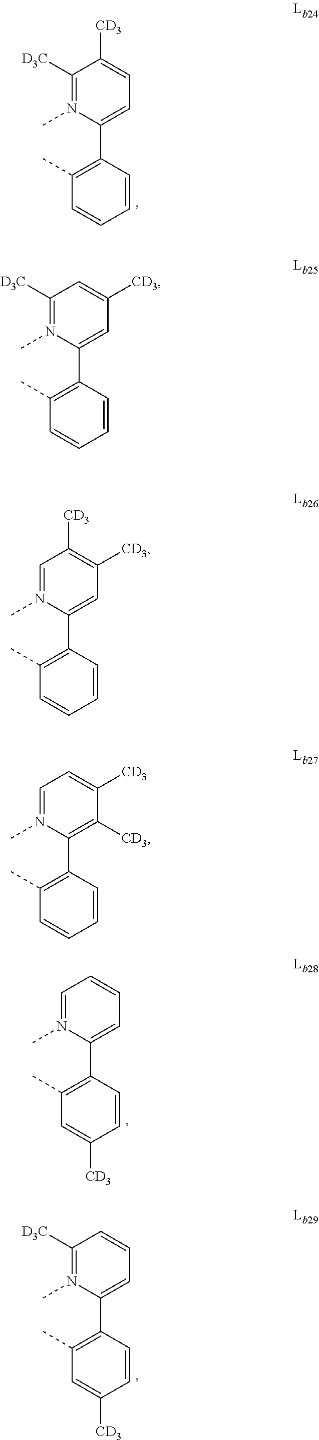 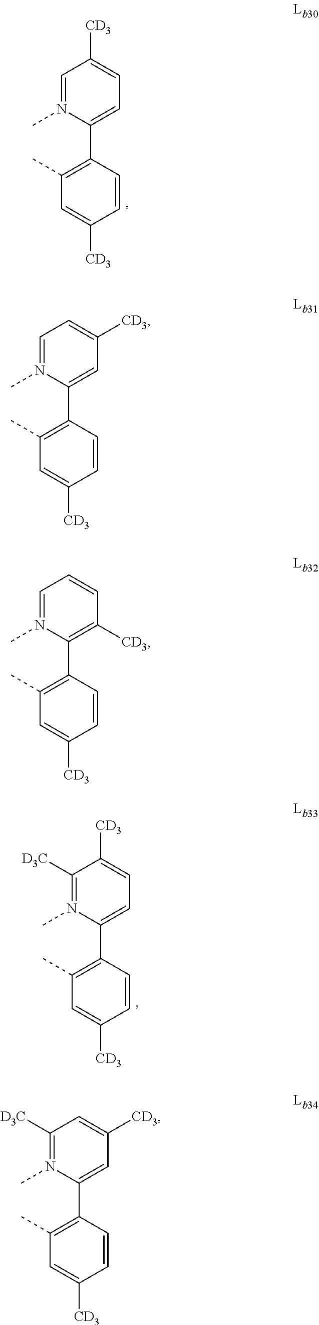 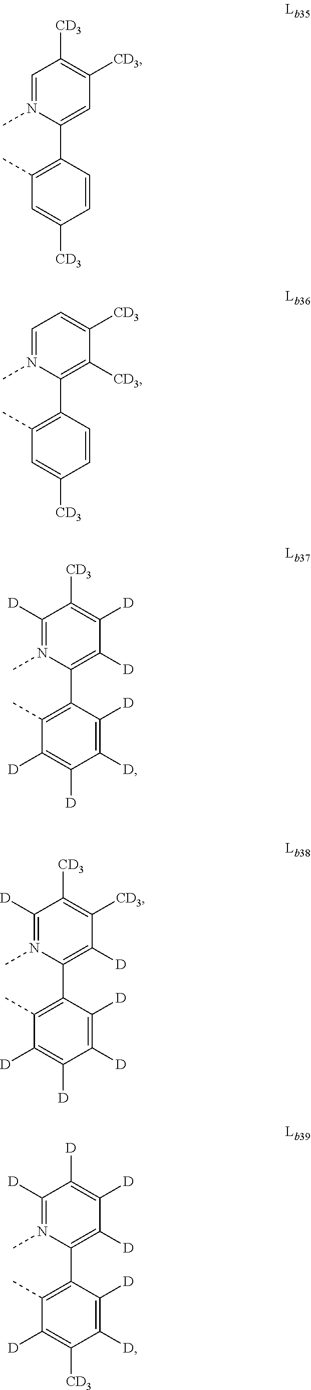 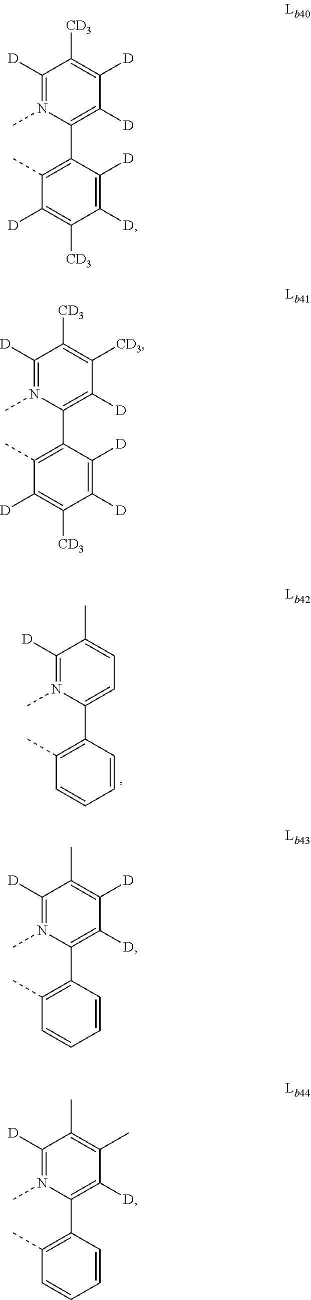 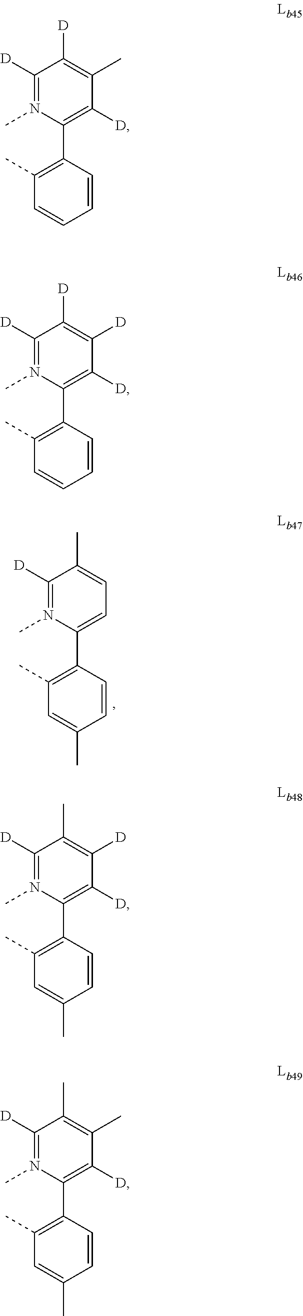 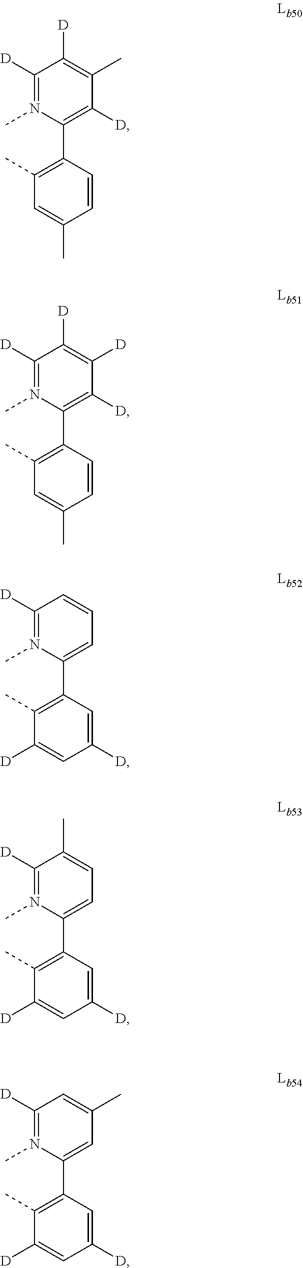 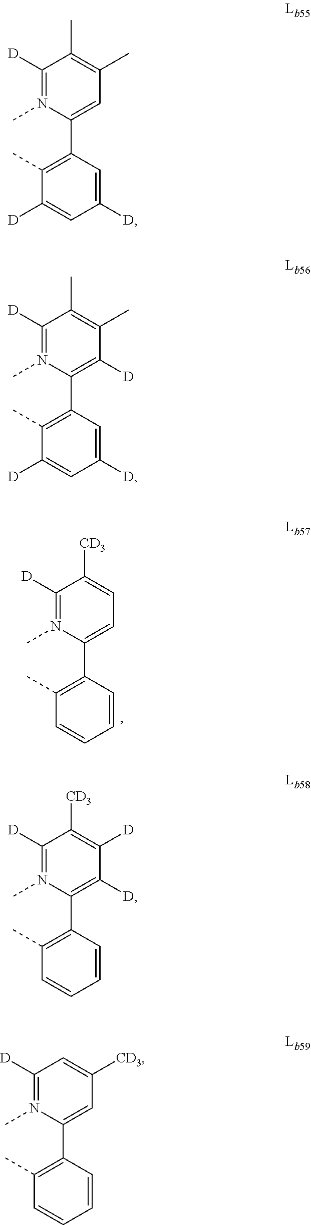 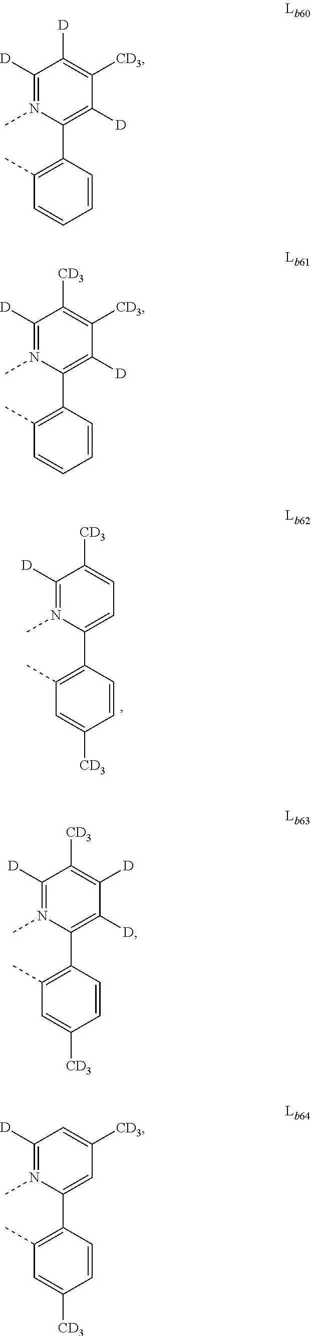 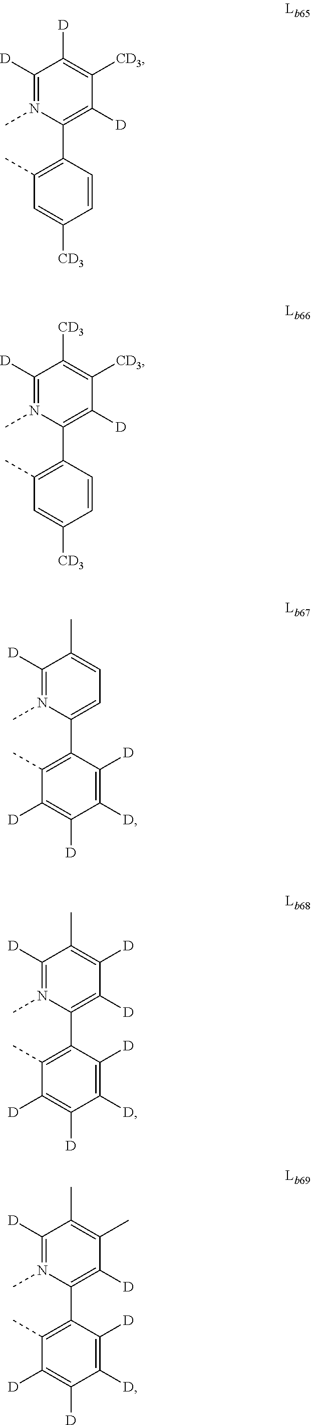 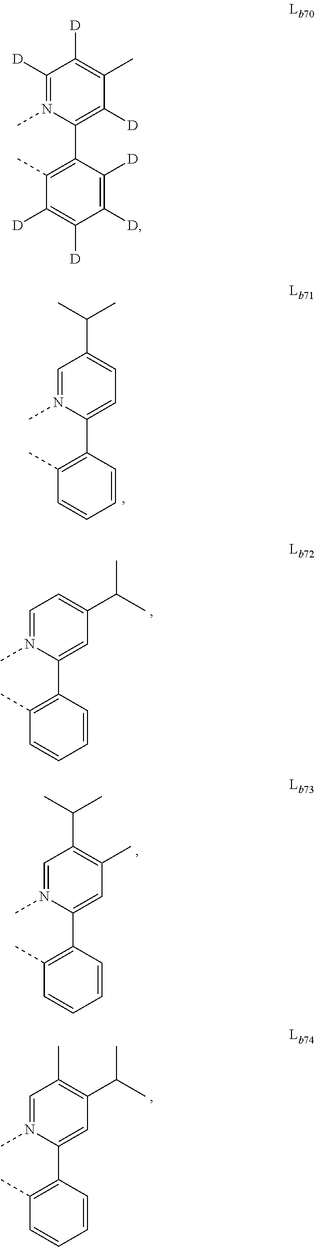 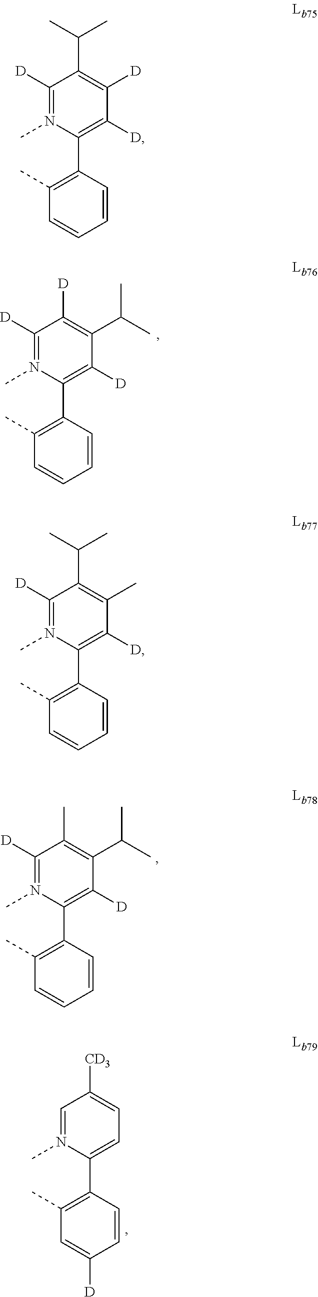 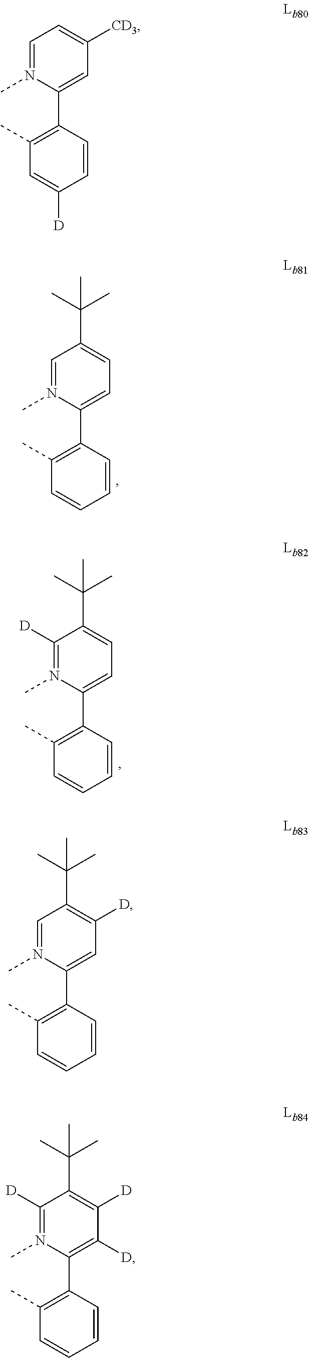 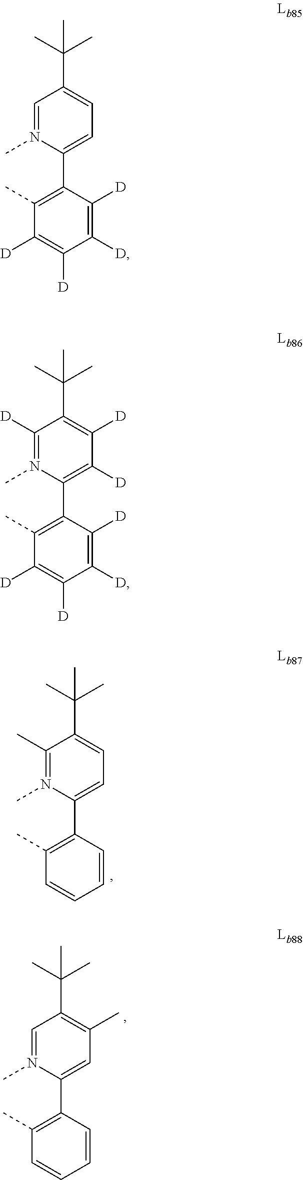 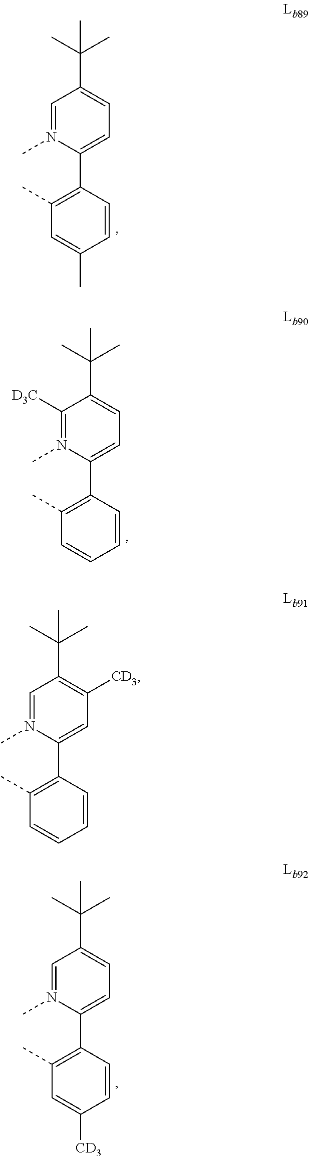 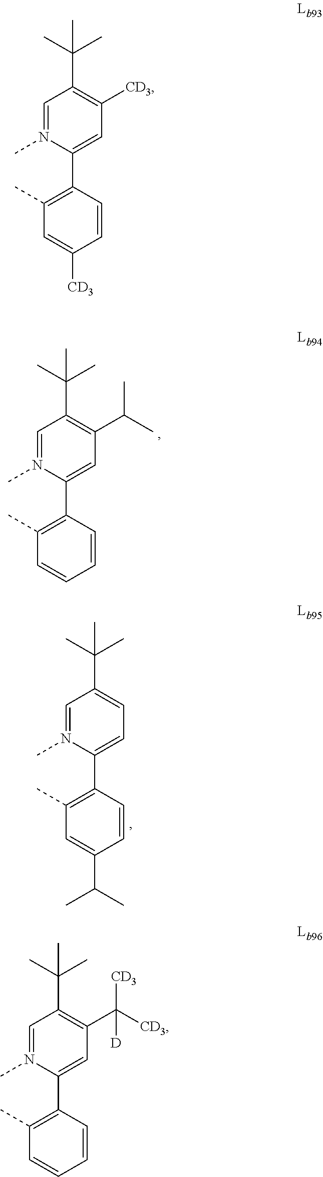 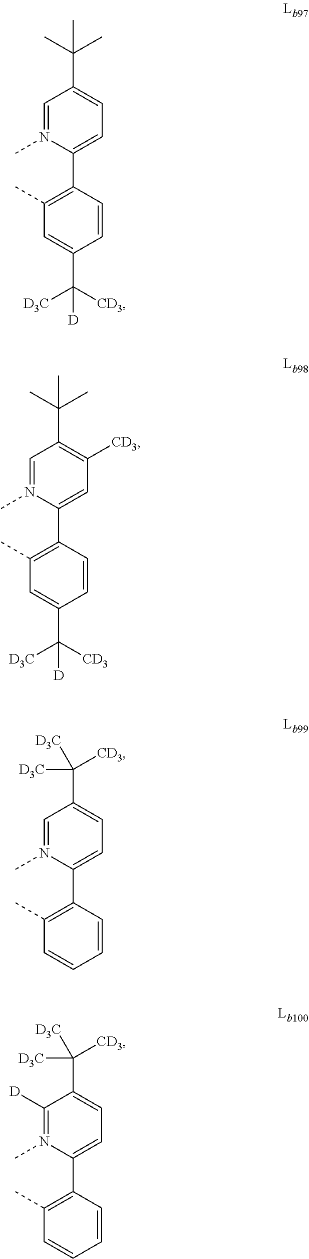 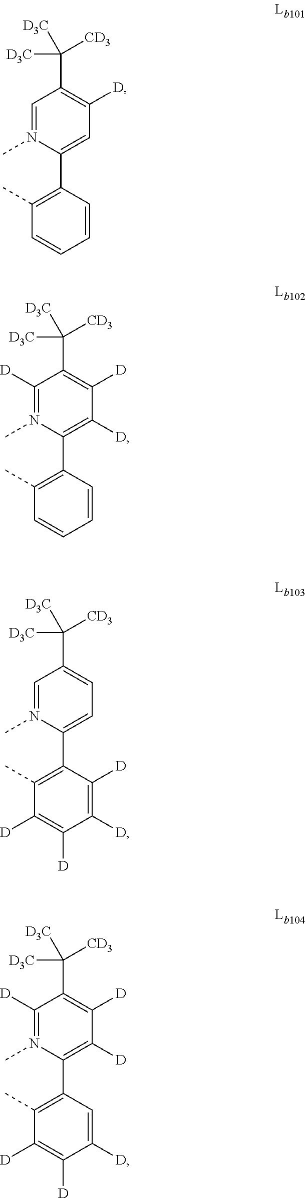 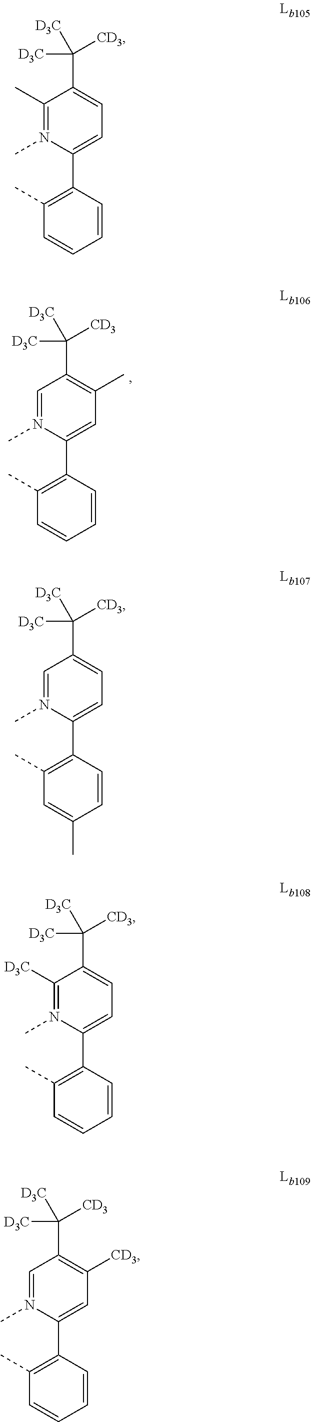 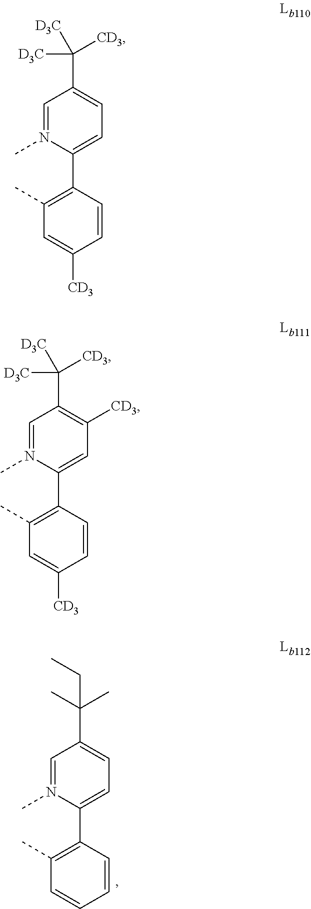 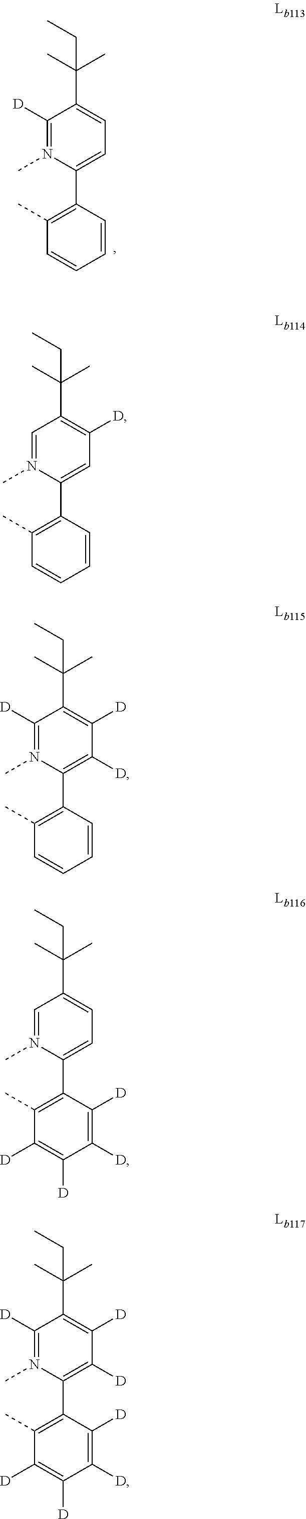 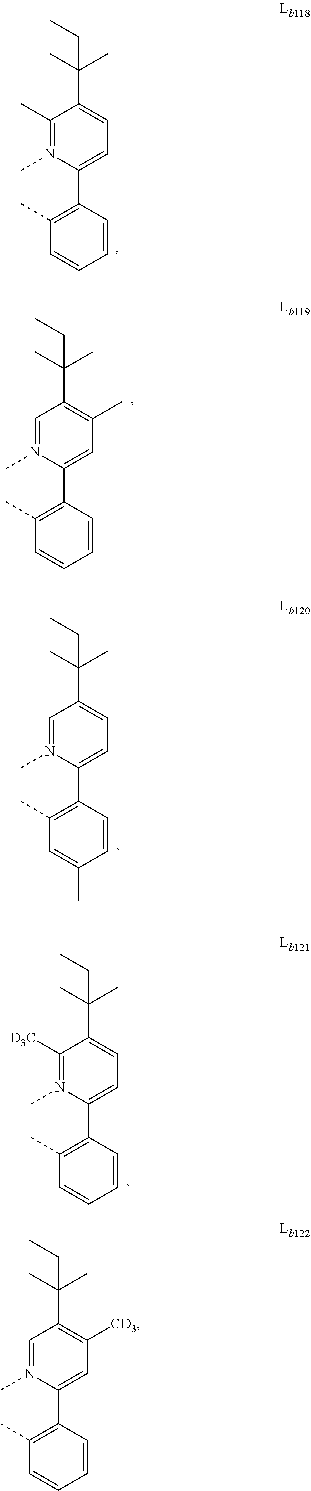 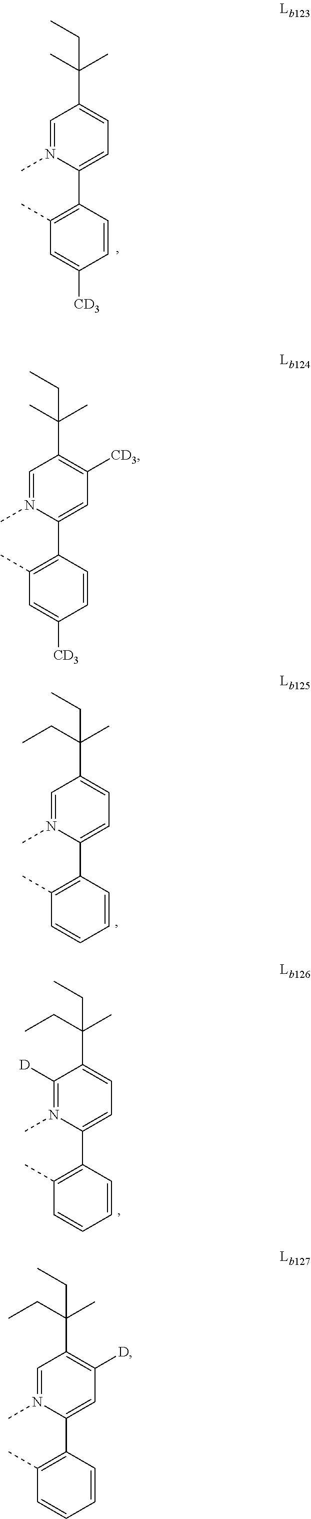 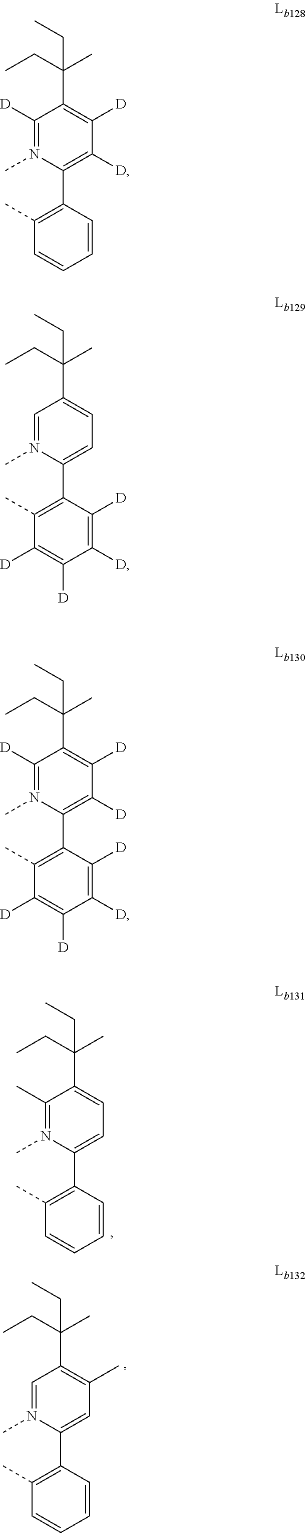 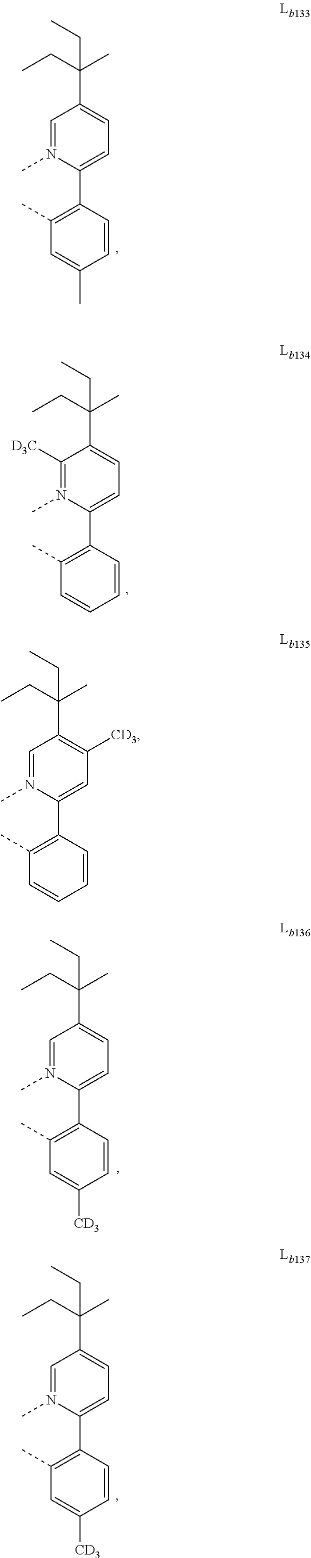 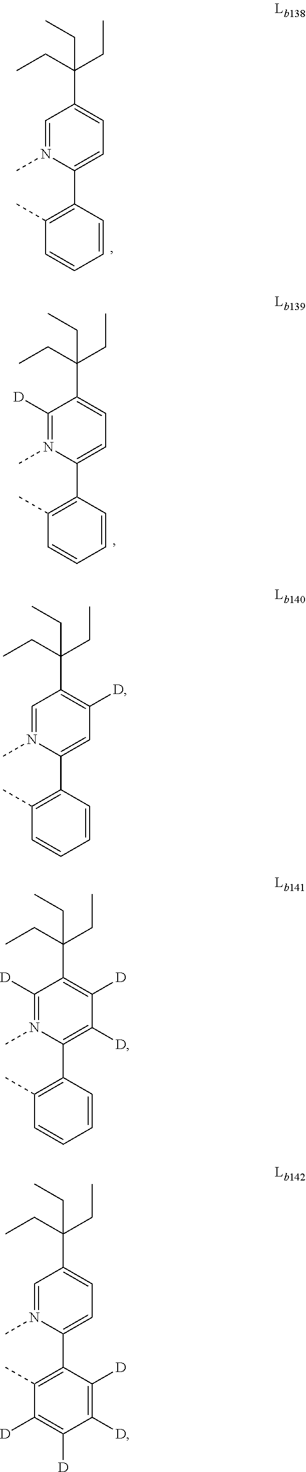 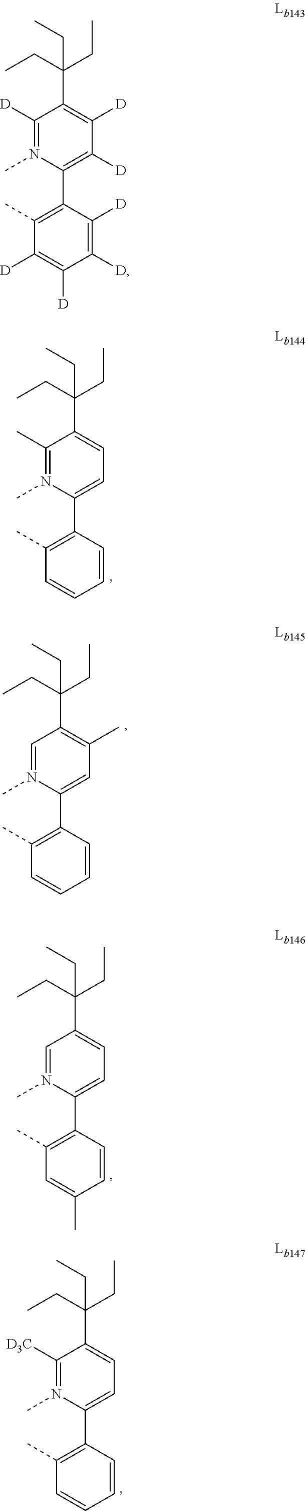 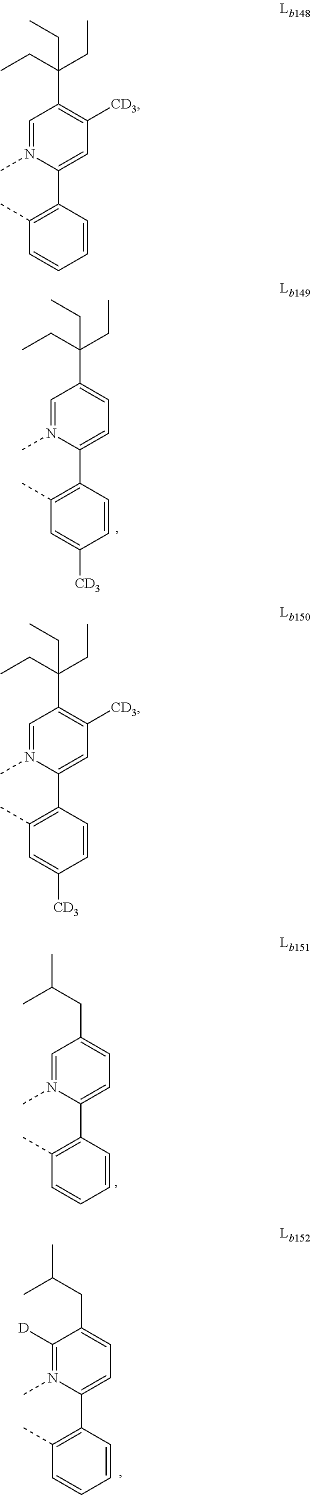 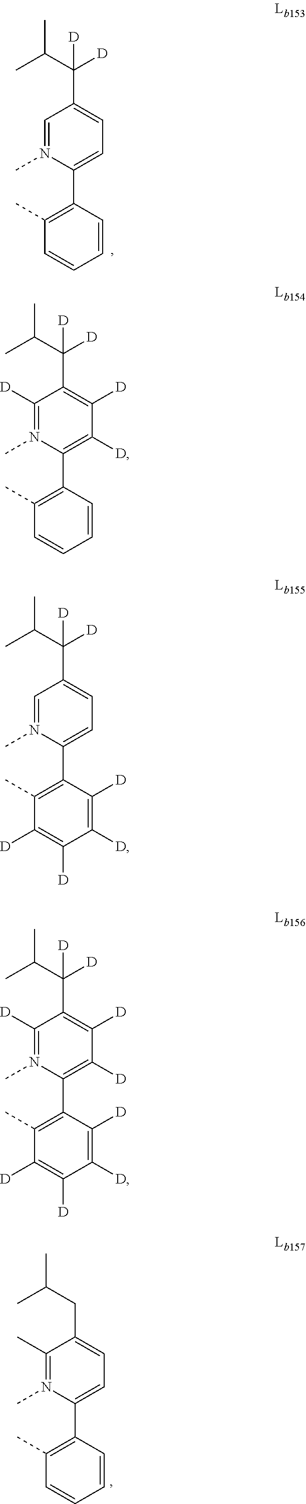 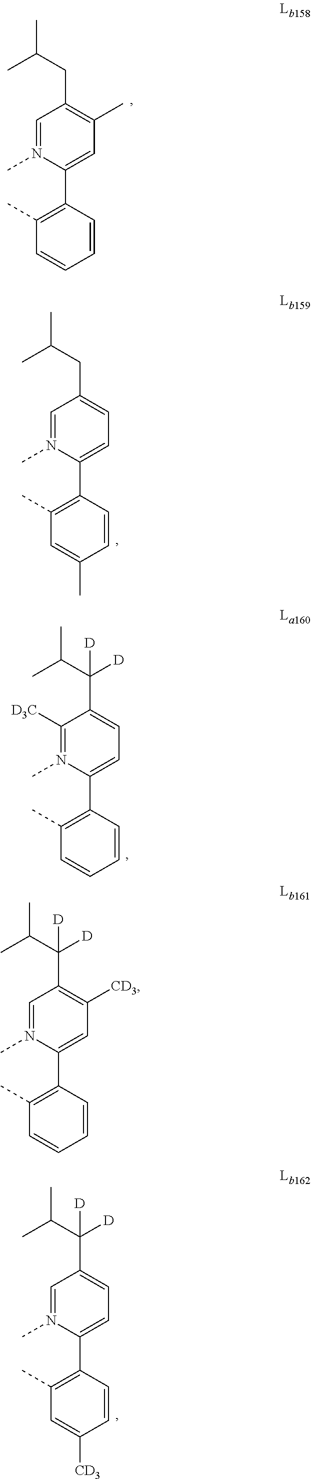 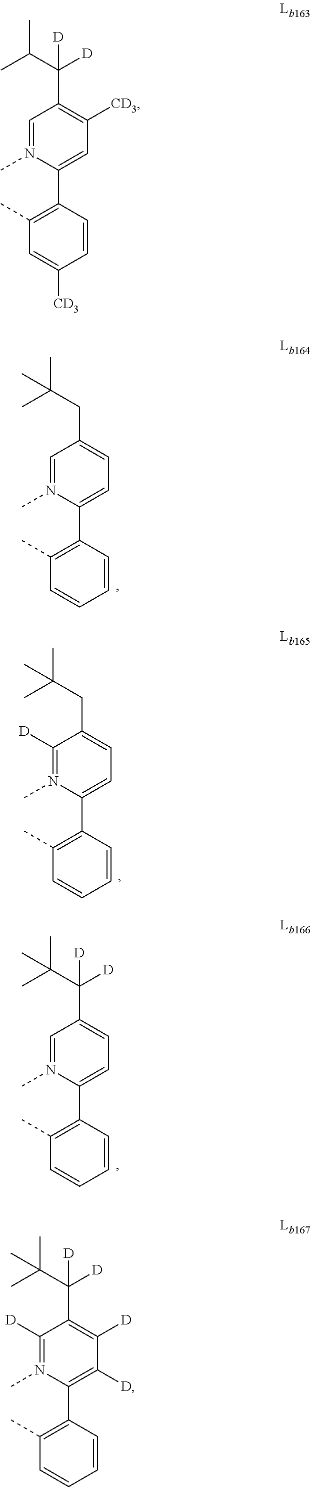 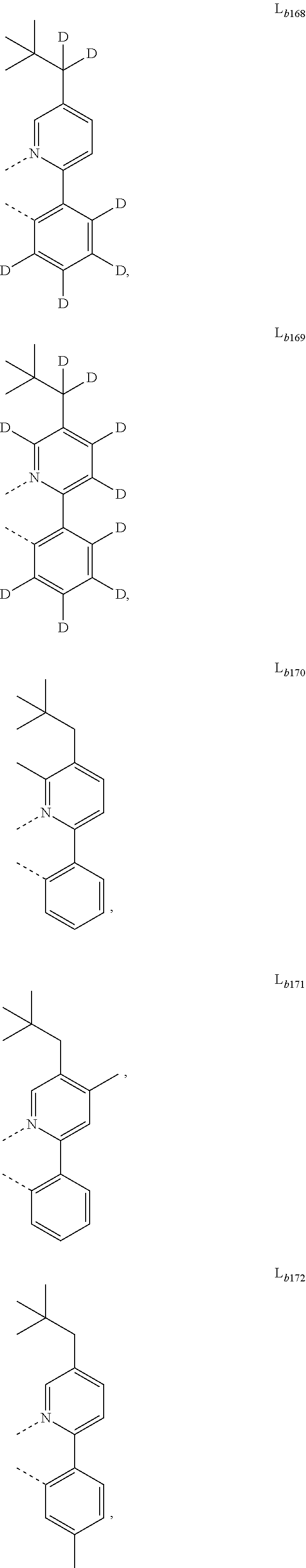 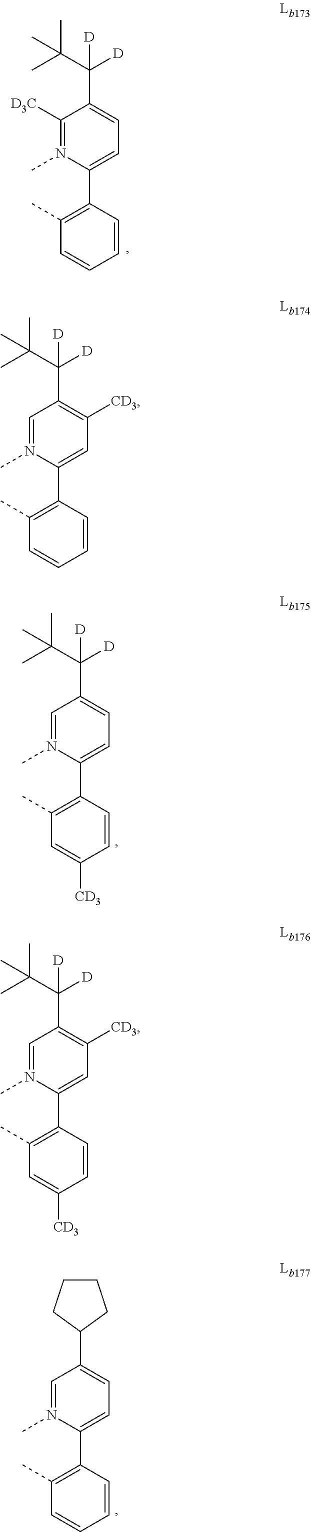 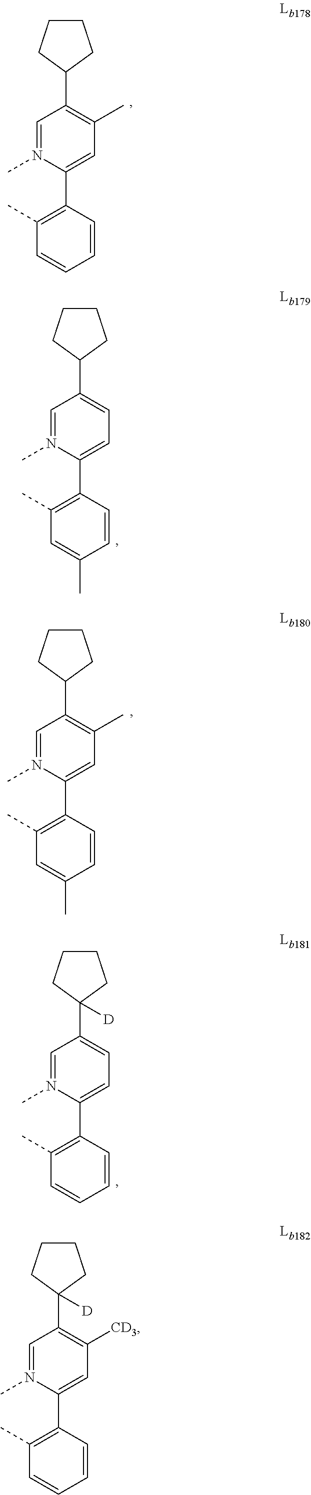 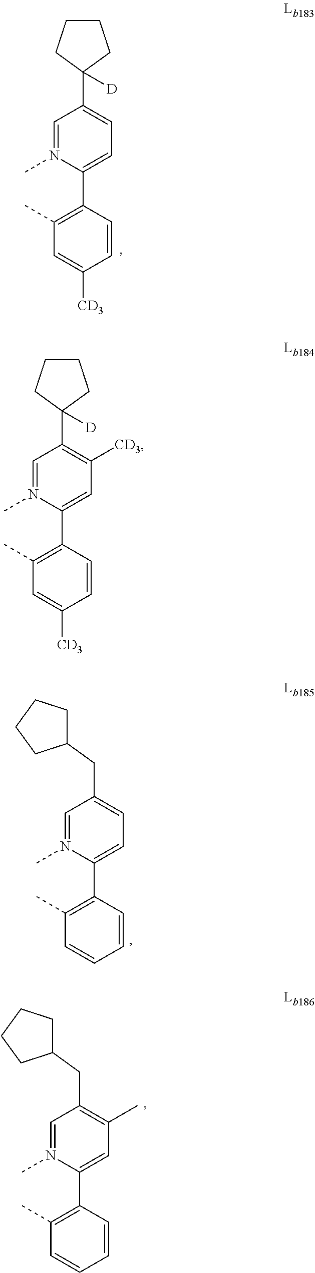 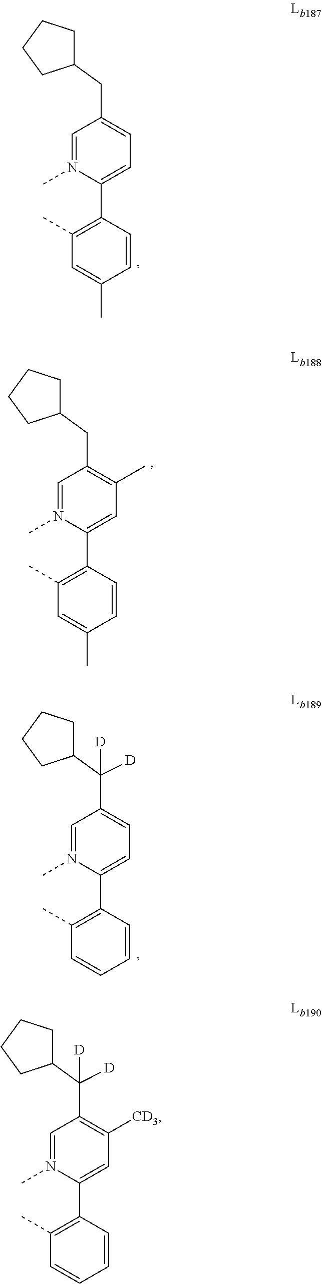 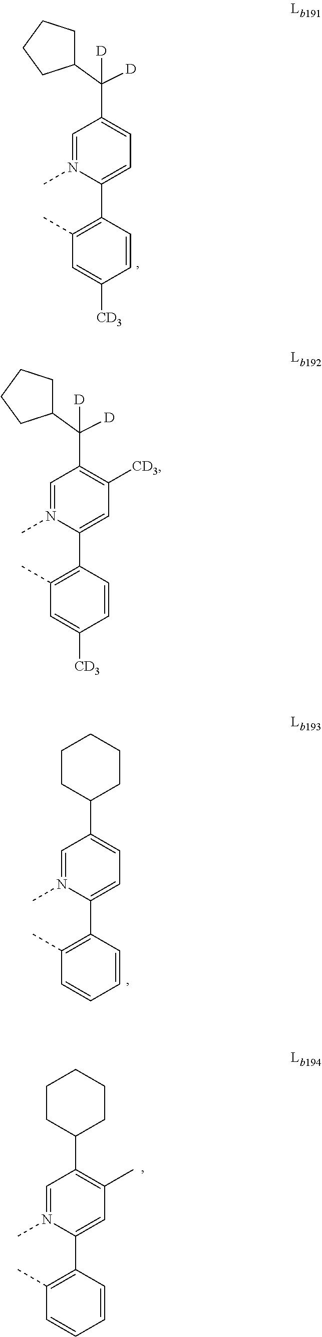 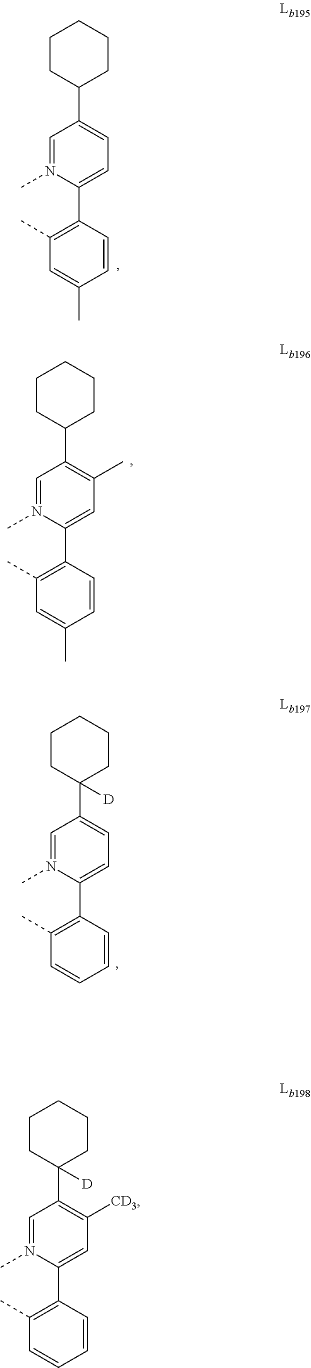 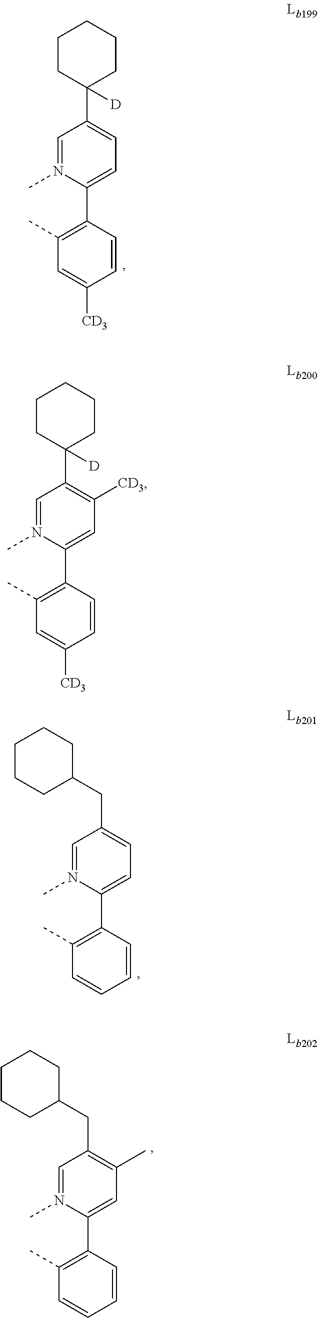 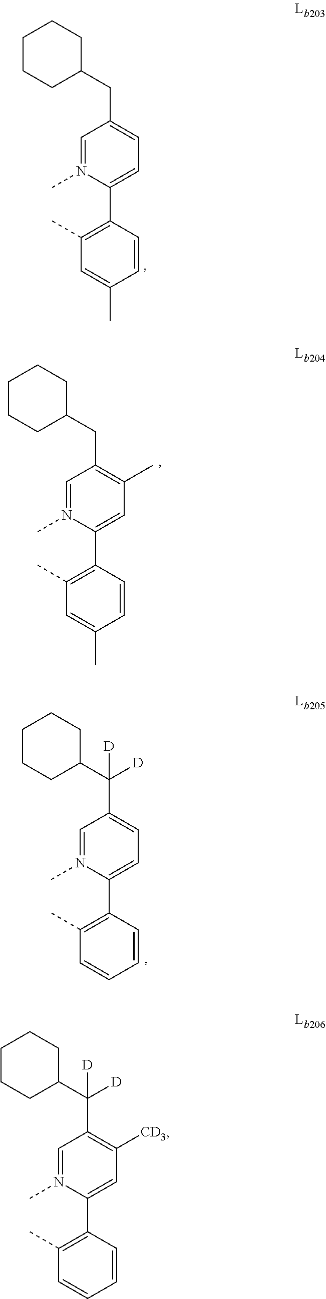 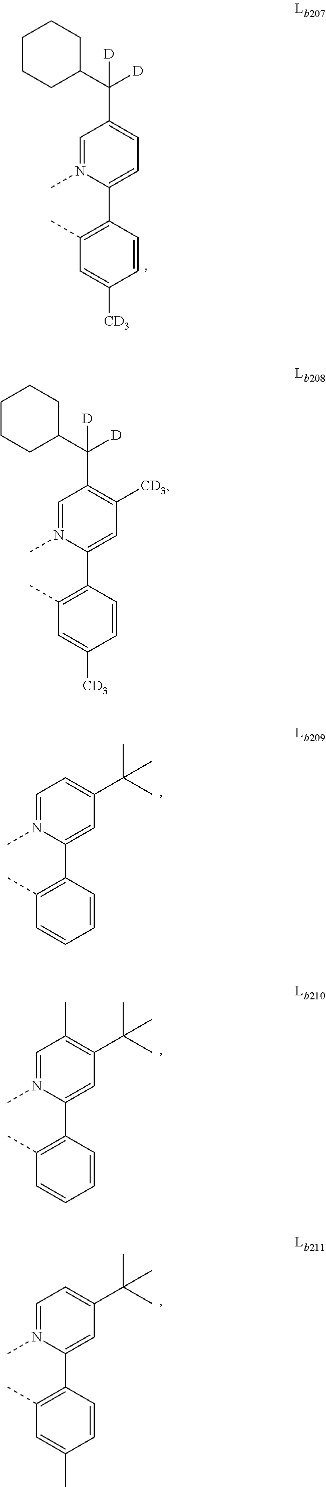 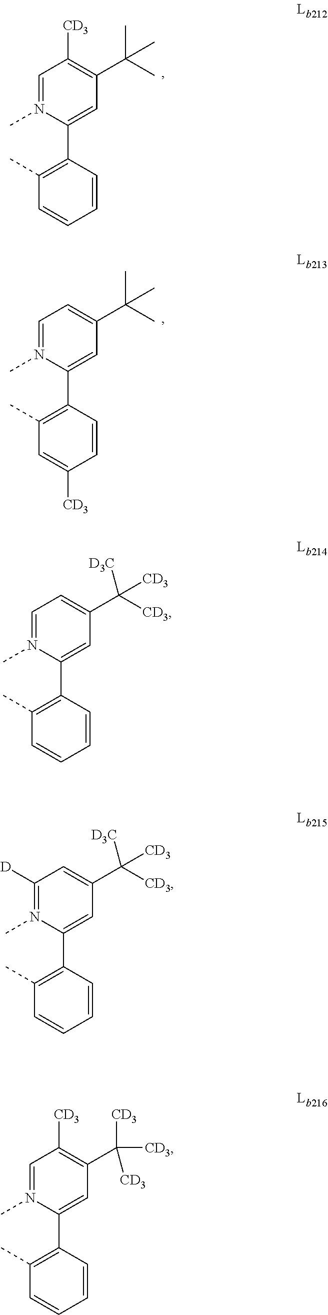 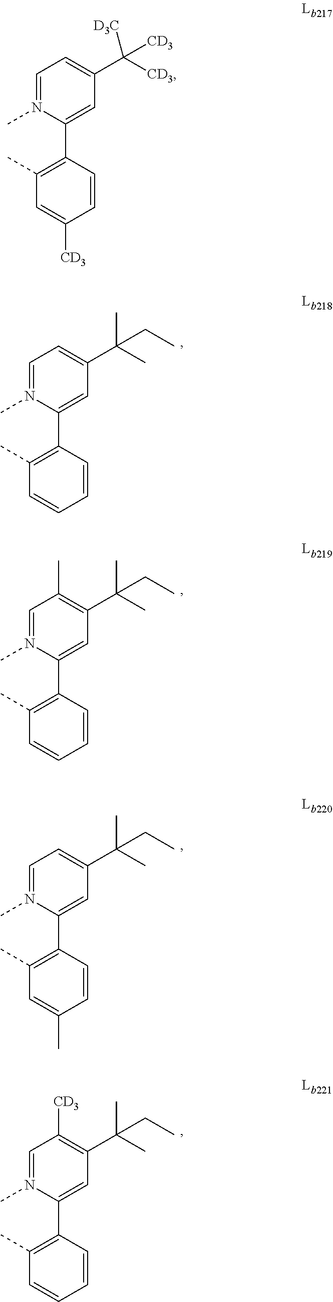 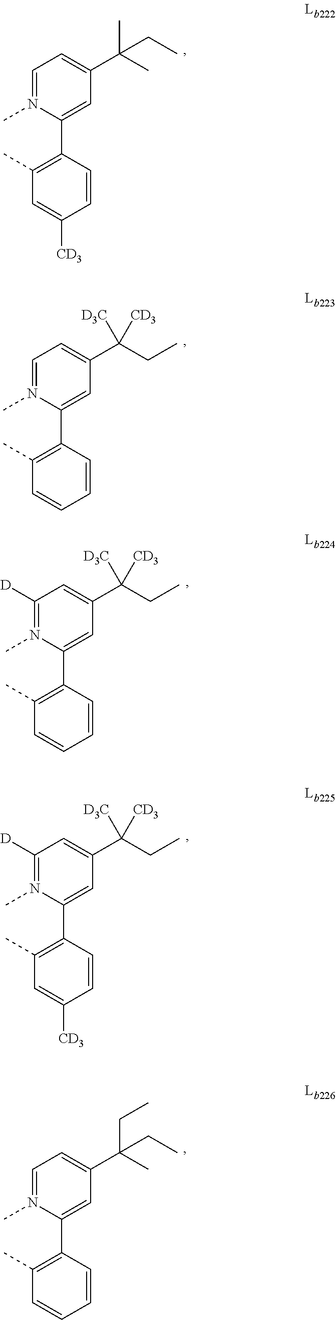 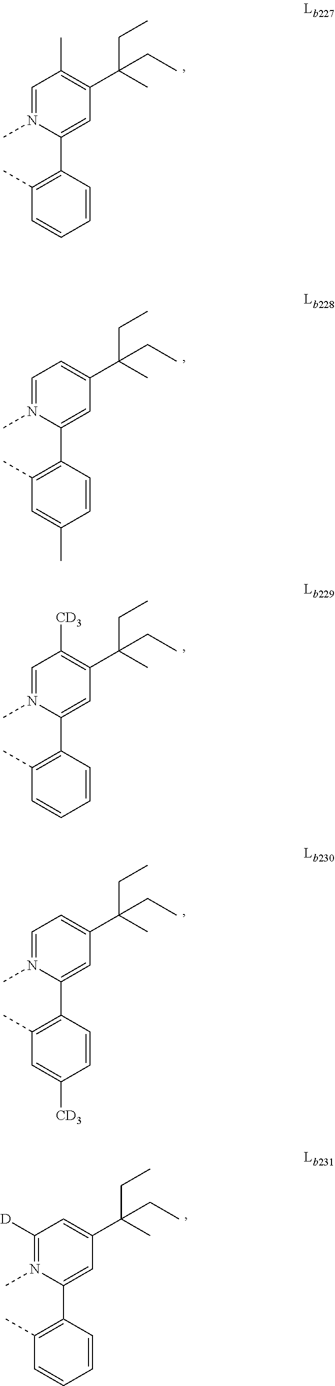 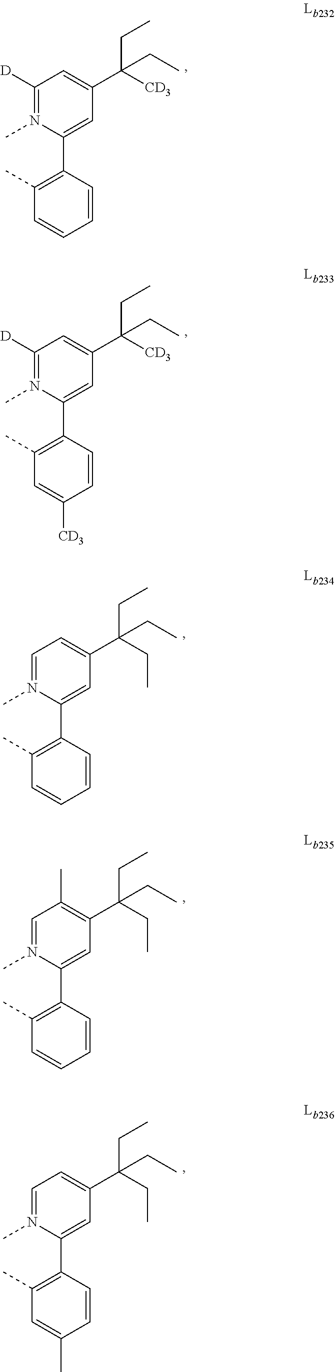 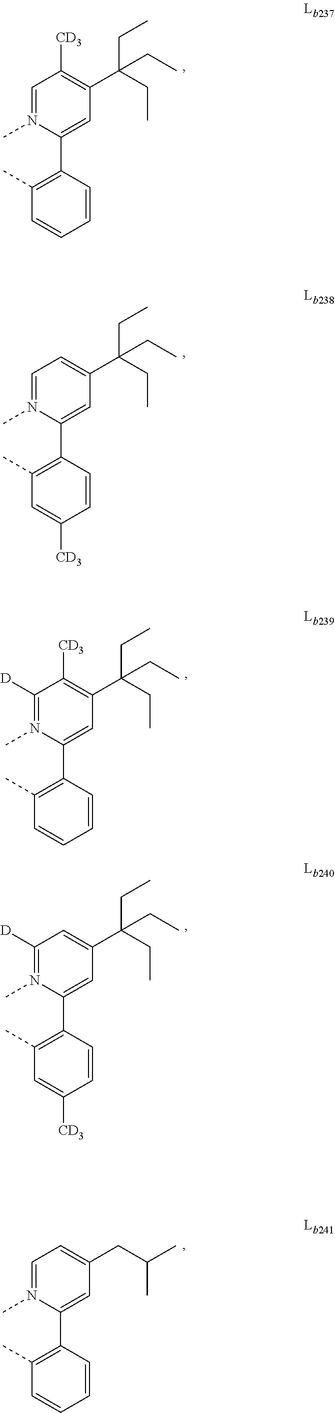 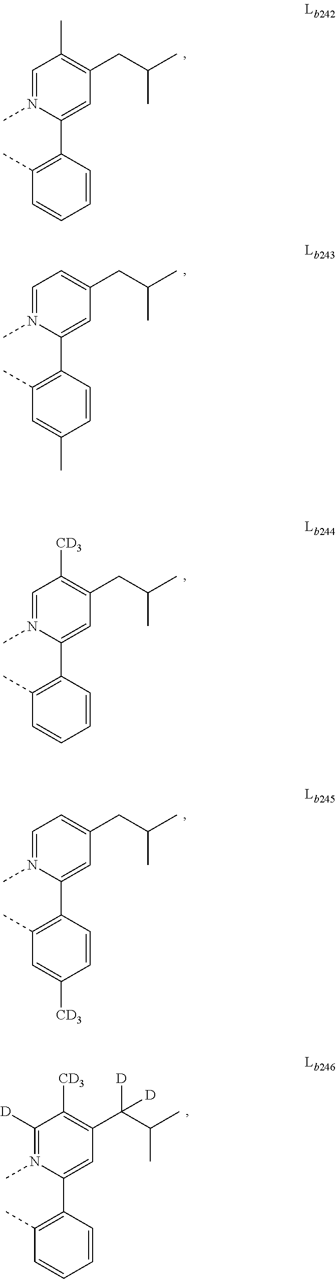 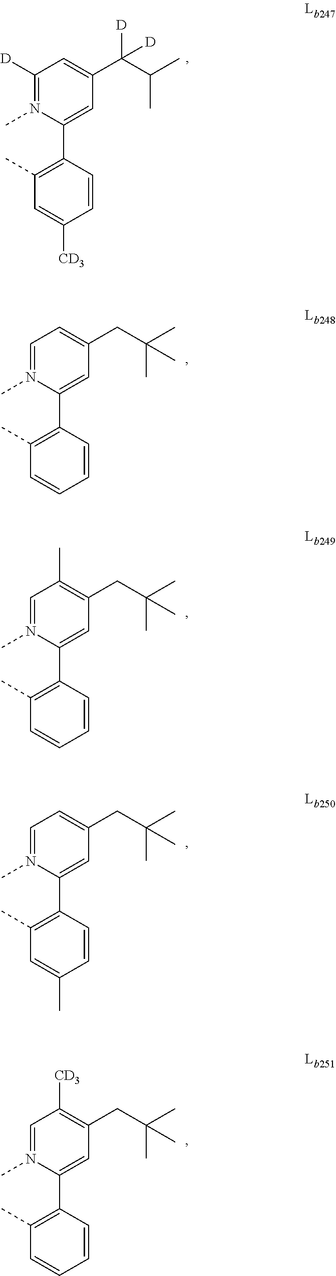 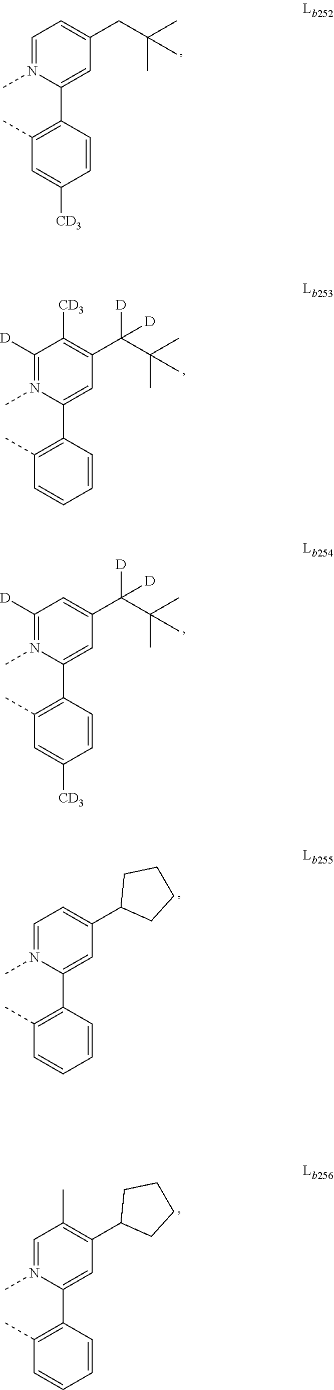 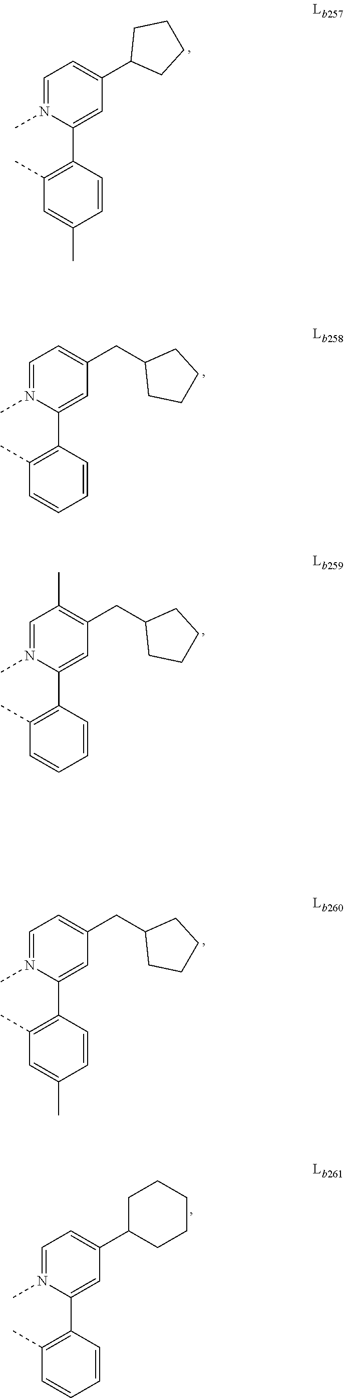 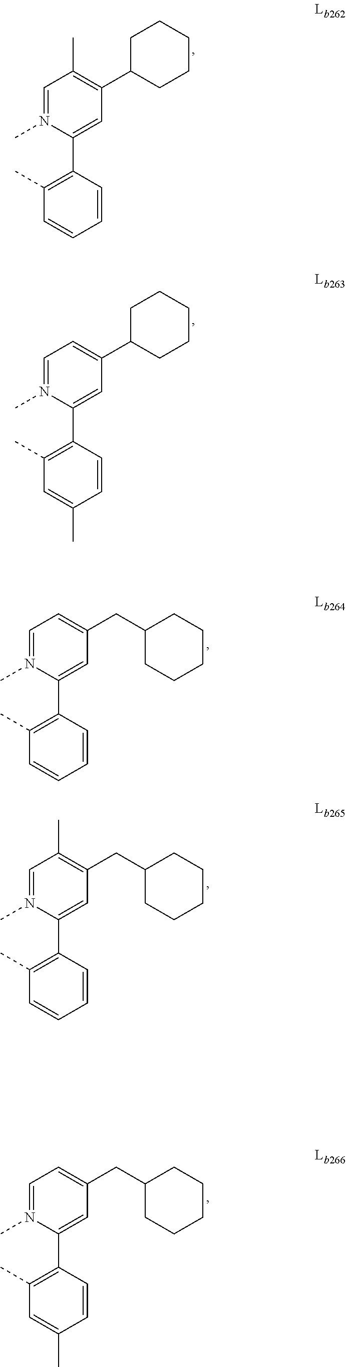 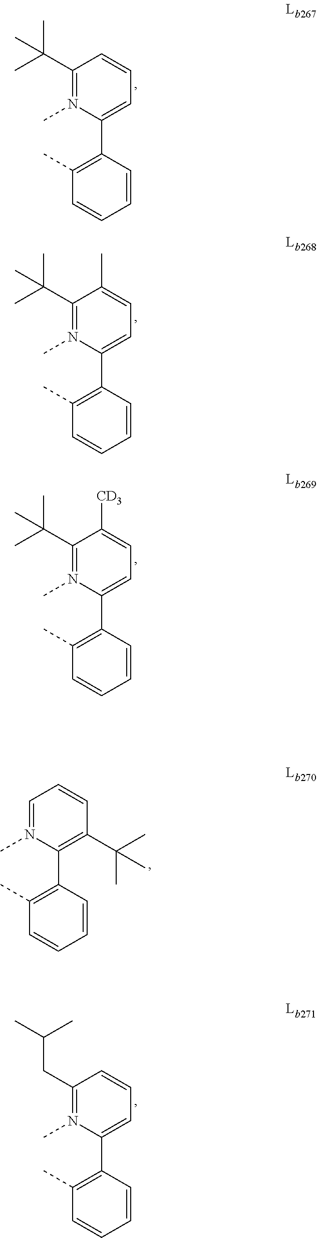 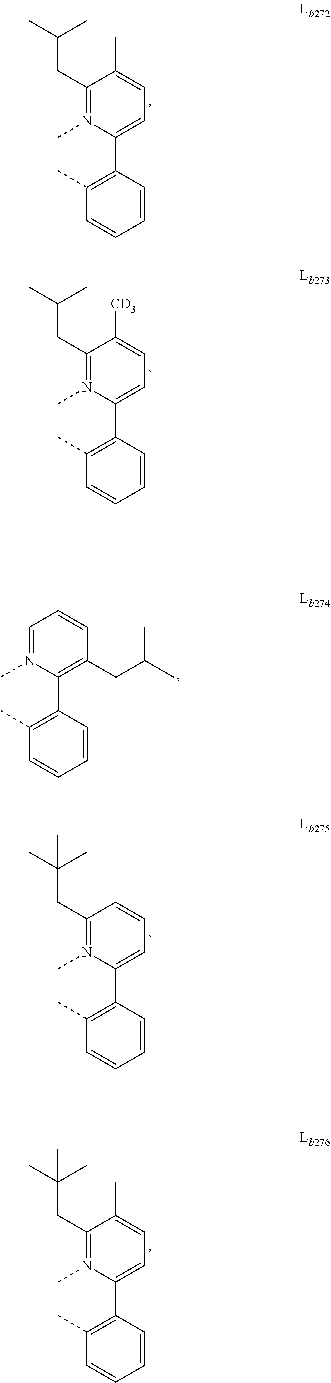 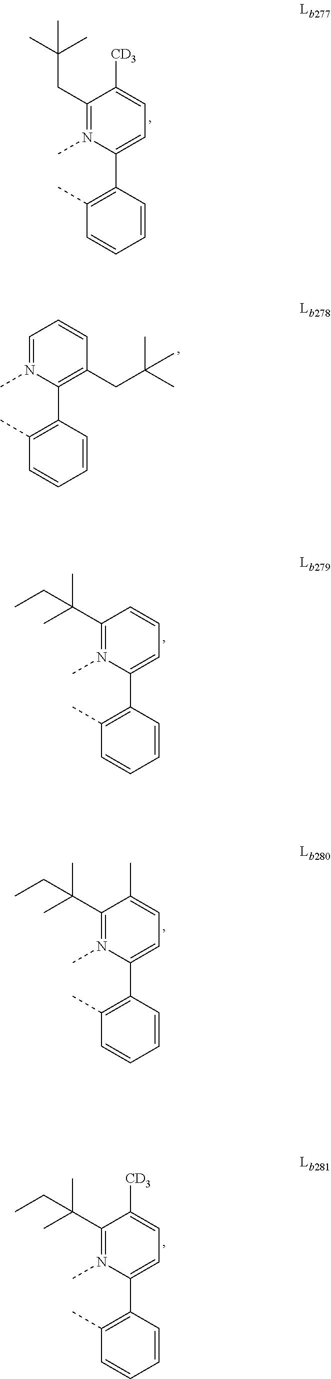 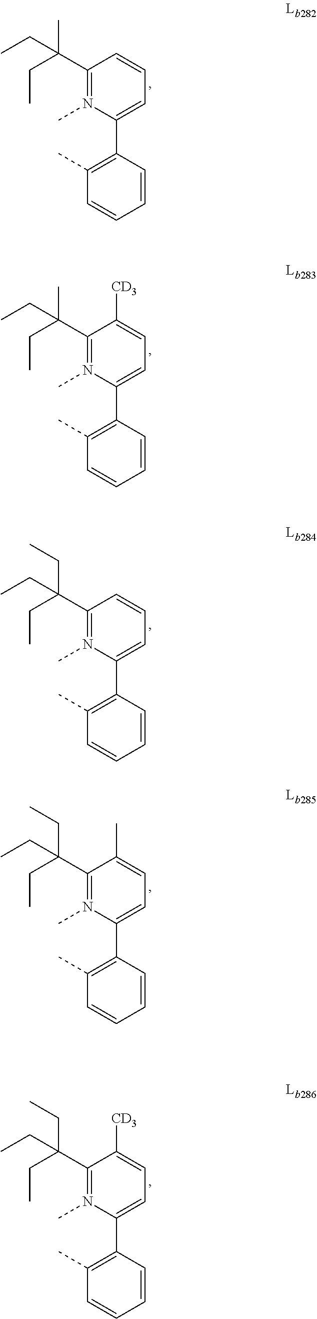 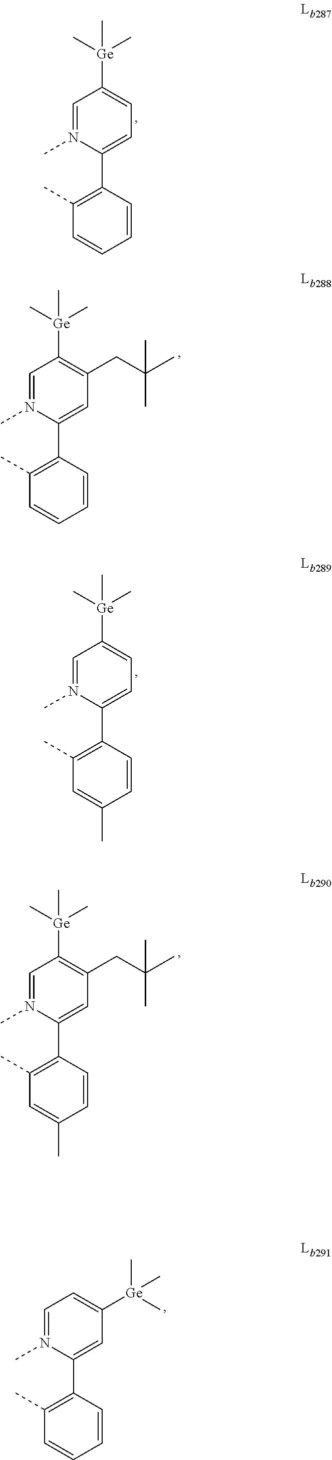 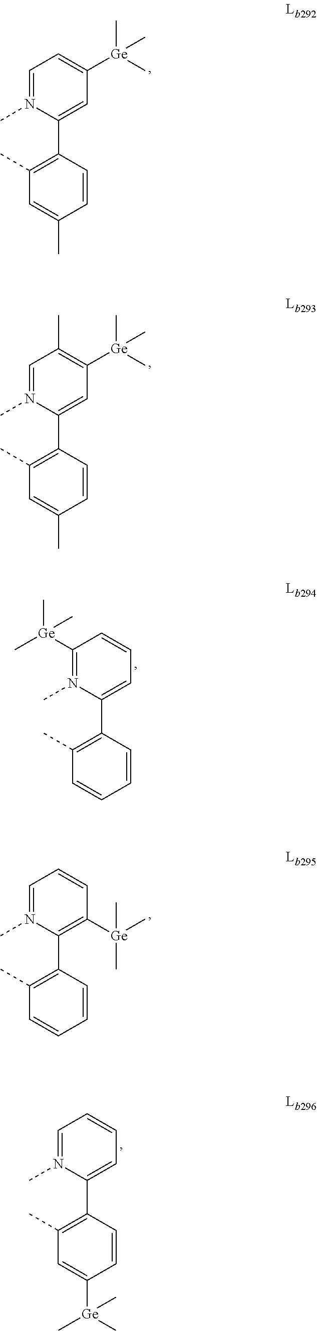 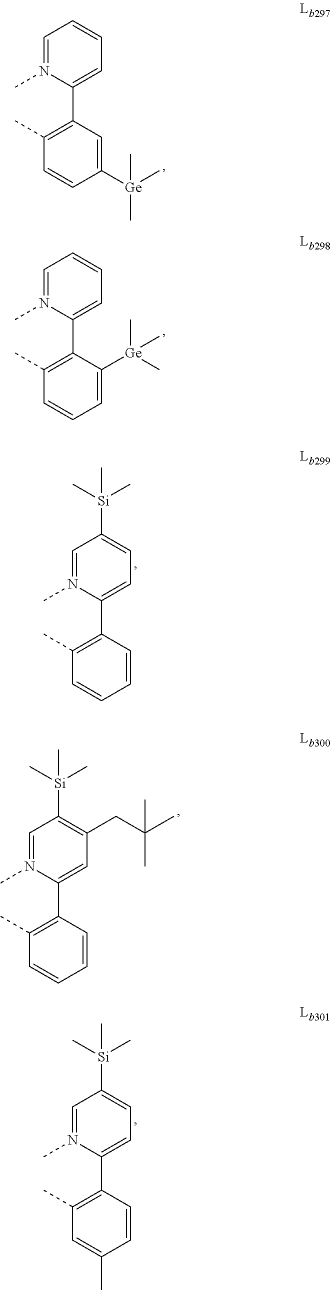 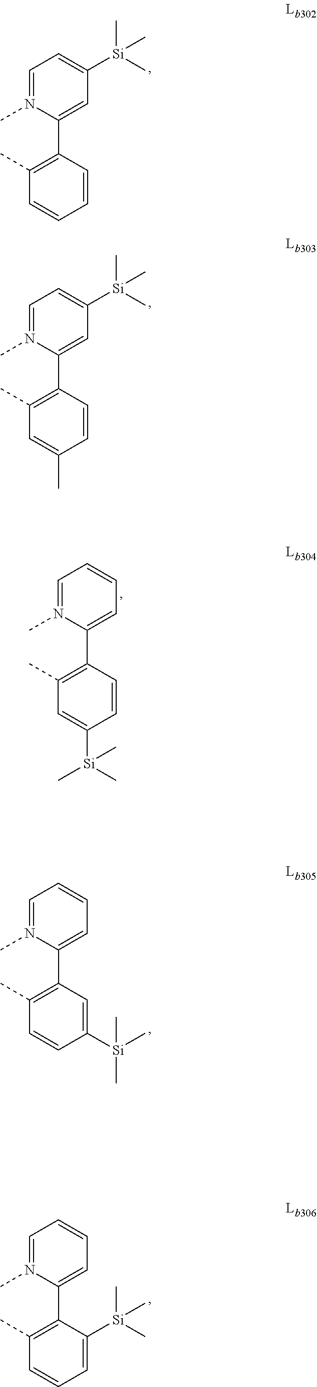 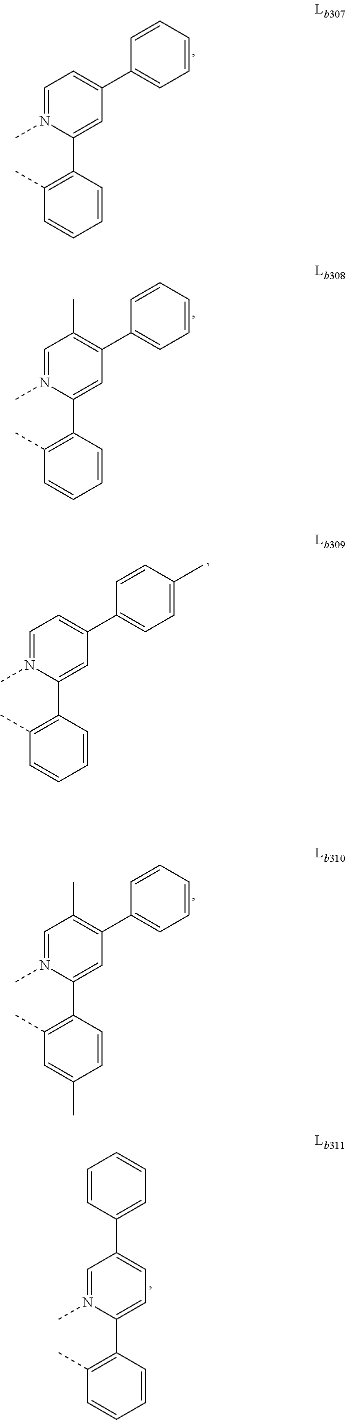 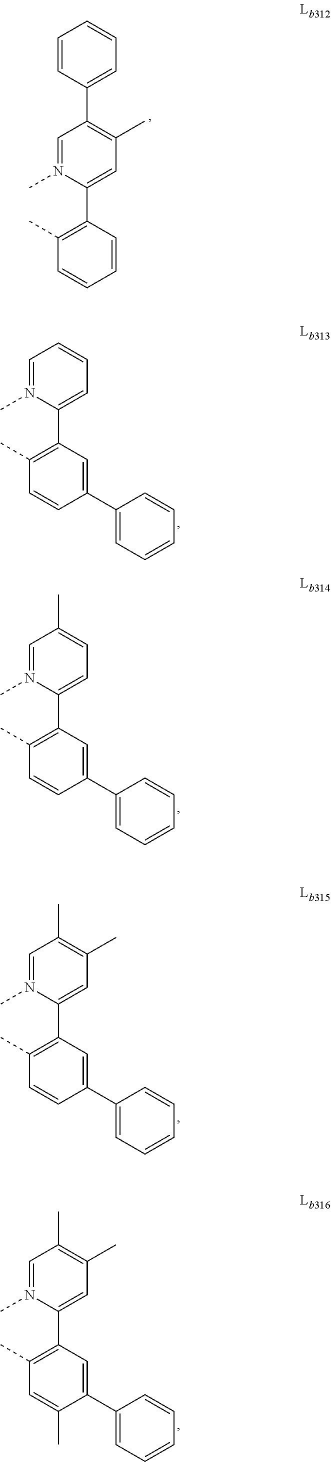 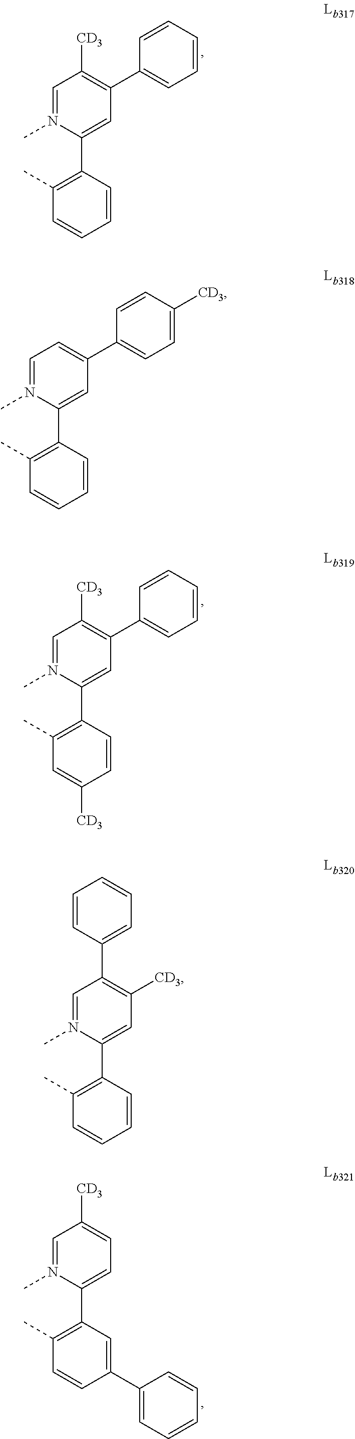 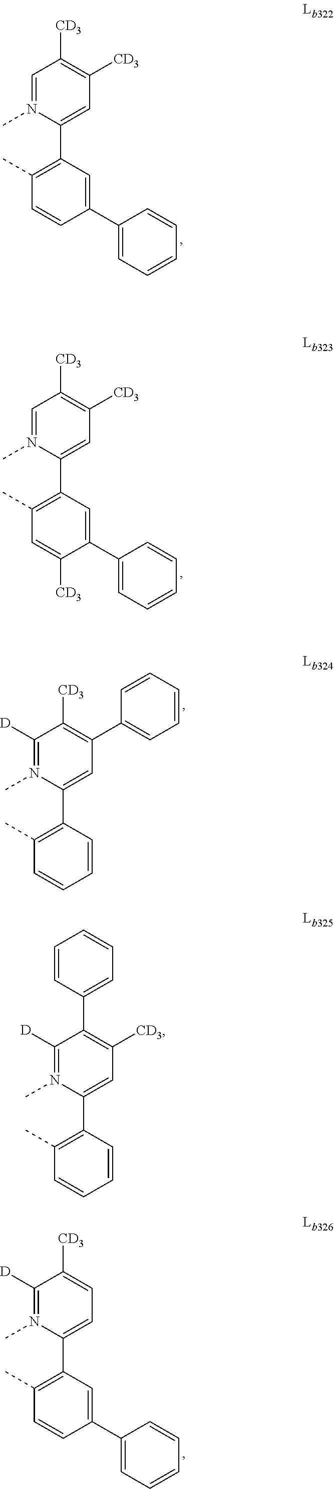 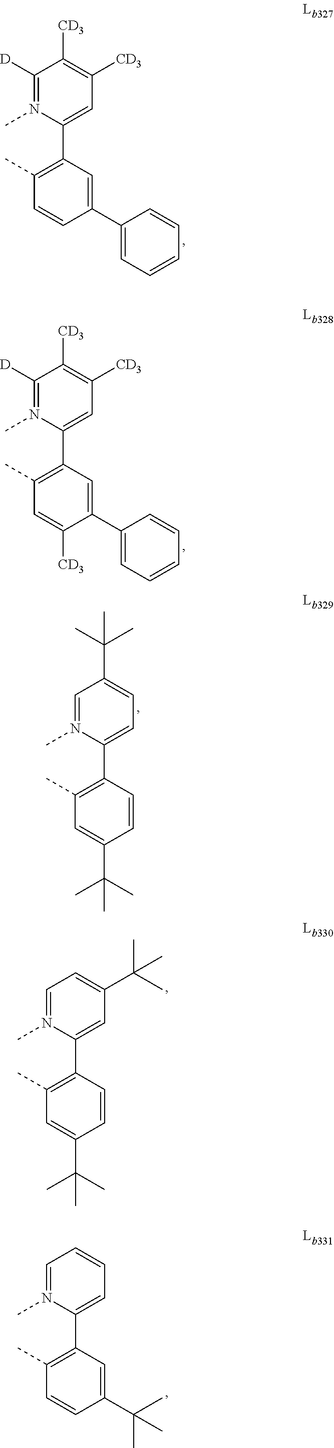 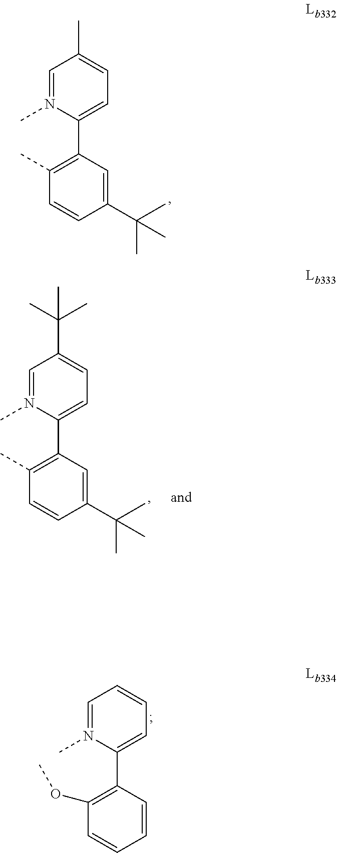
optionally, hydrogen atoms in L_{b1} to L_{b334} can be partially or fully deuterated.

17. The metal complex of claim 16, wherein the ligand L_{c} is, at each occurrence identically or differently, selected from the group consisting of:

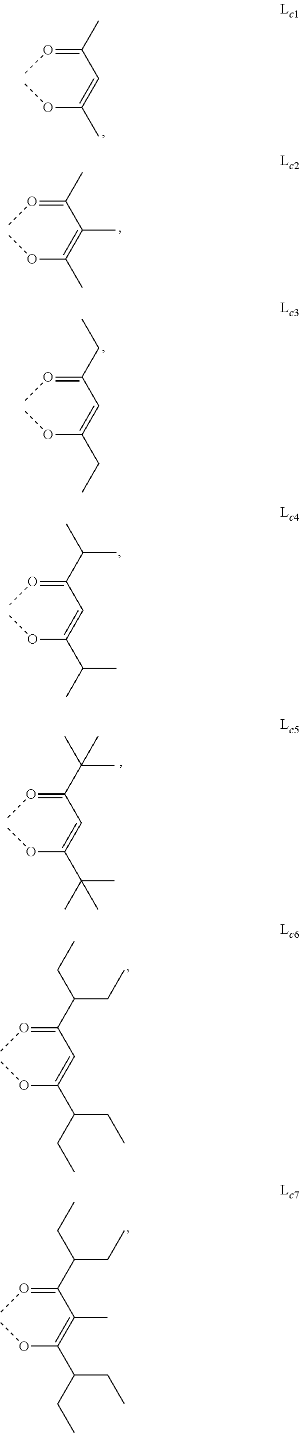

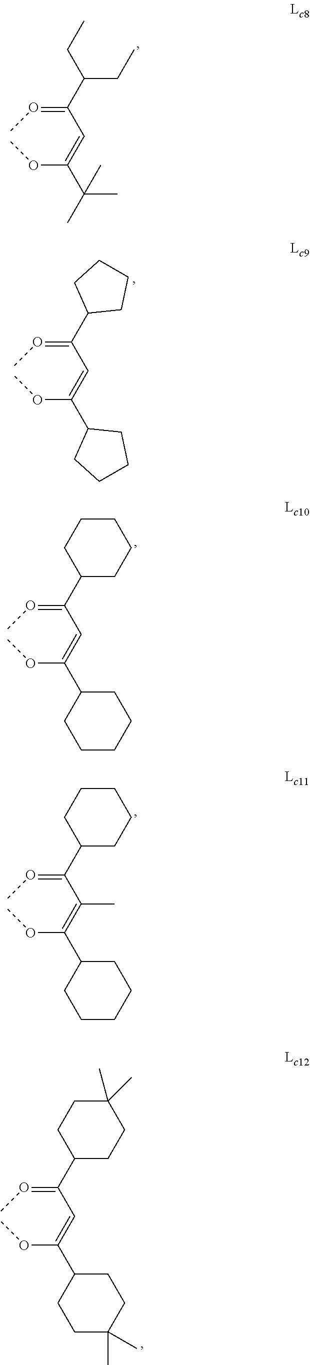

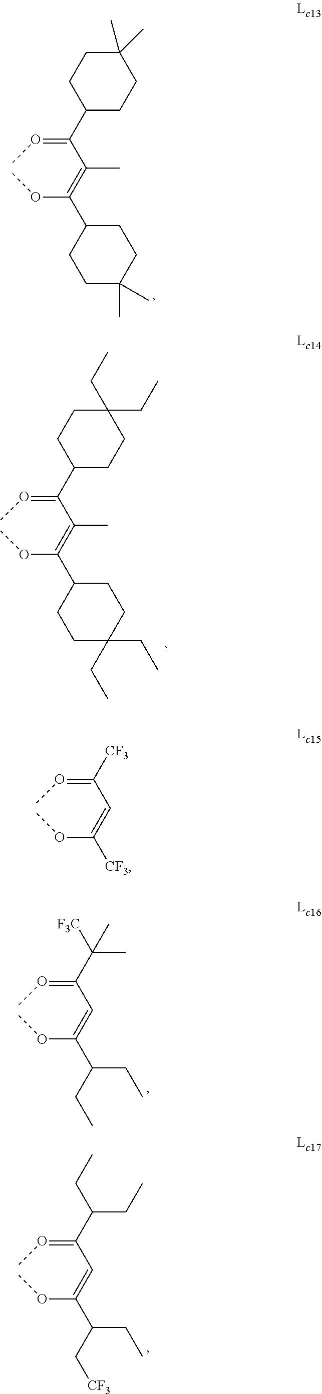

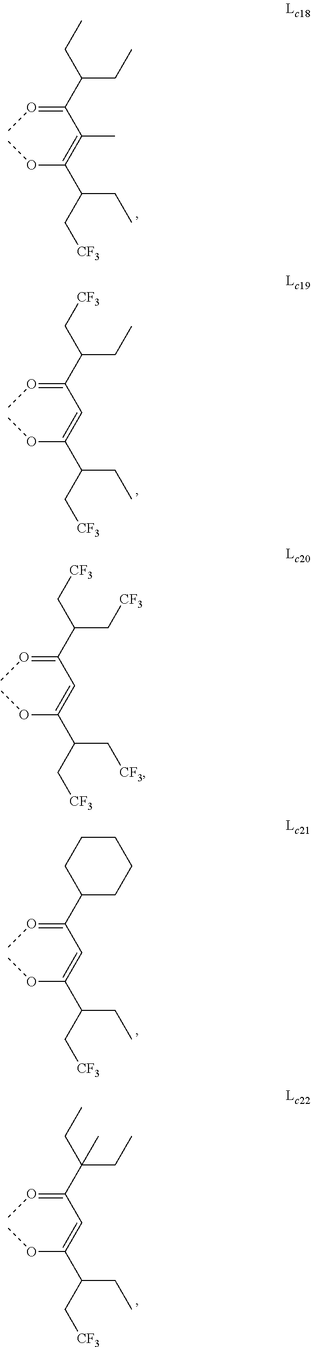

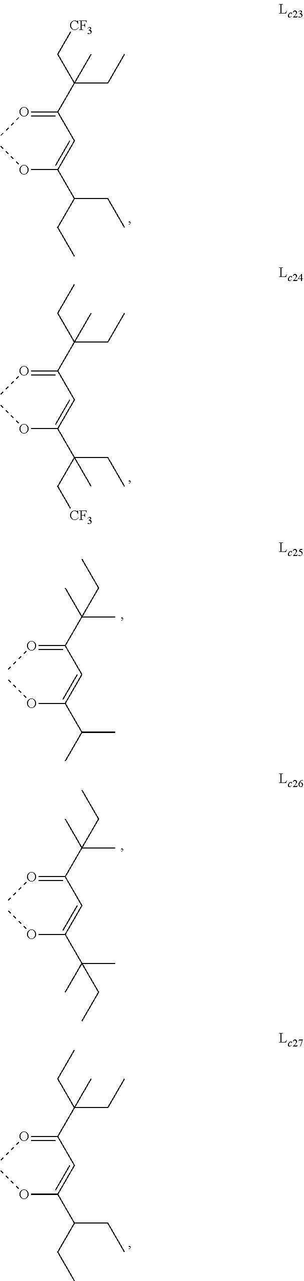

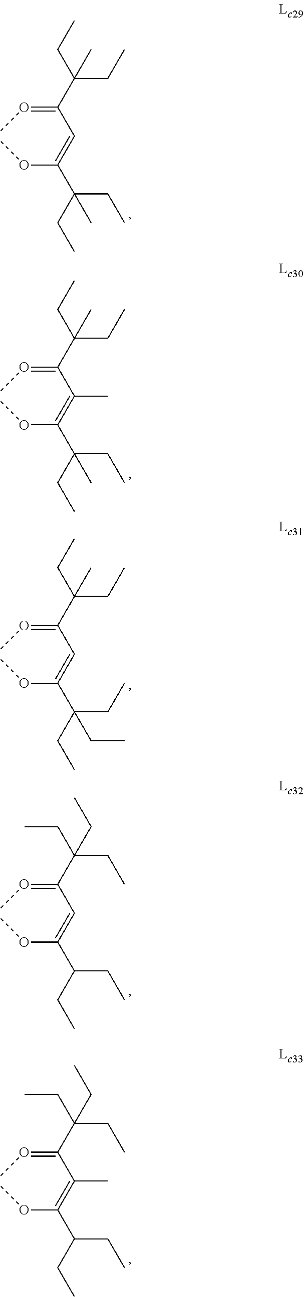

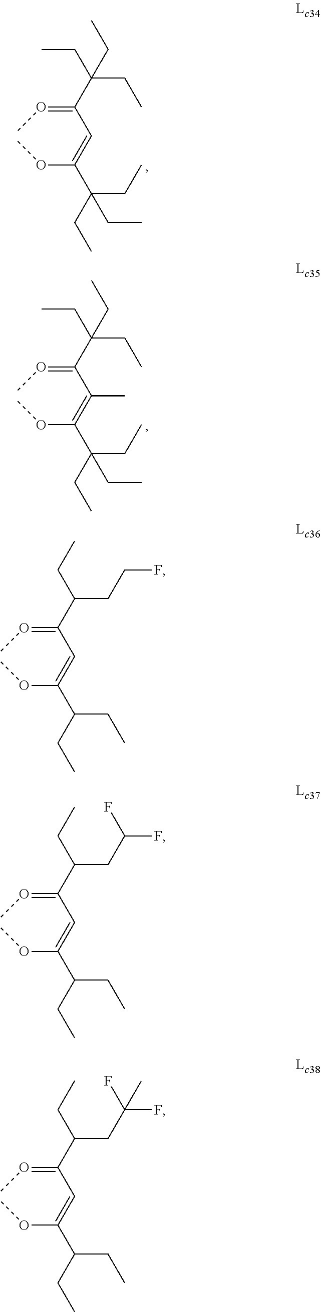

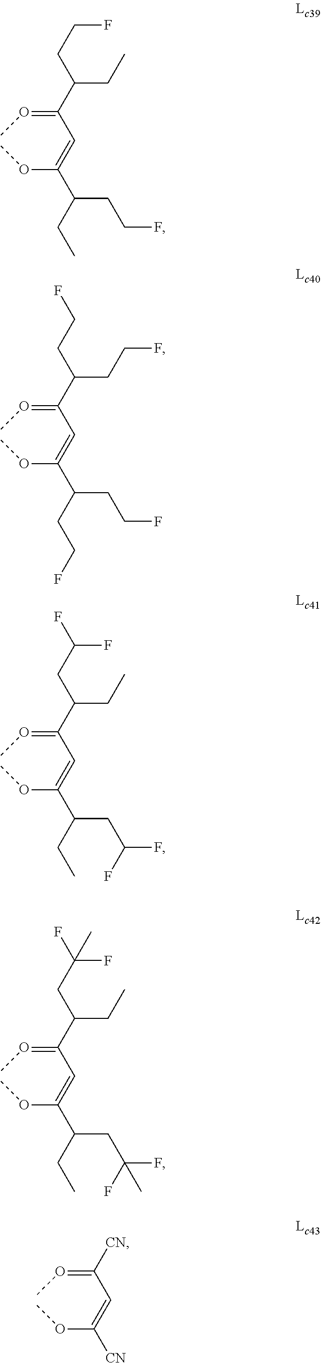

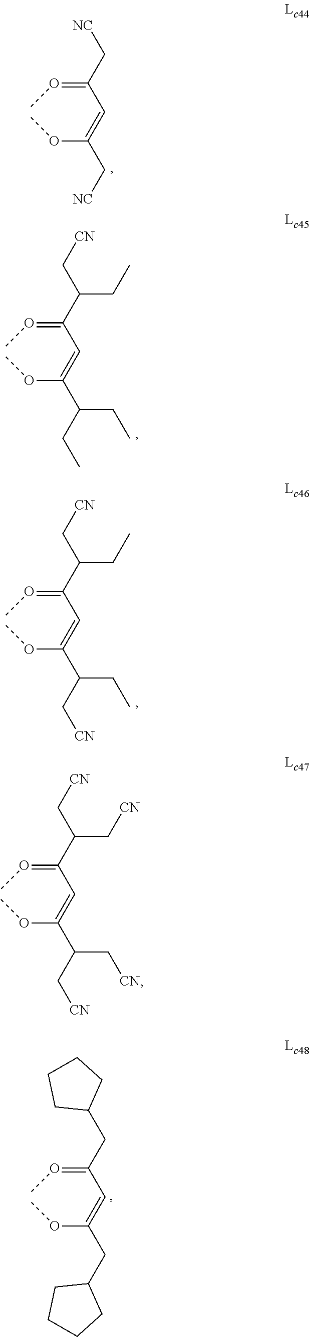

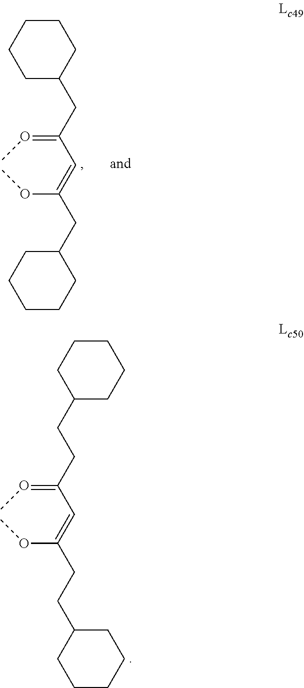

18. The metal complex of claim 16, wherein the metal complex has a structure of IrLₐ(L_{b})₂, wherein the two L_{b} are the same or different; Lₐ is selected from any one of the group consisting of Lₐ₁ to Lₐ₂₅₈, and L_{b} is selected from any one or any two of the group consisting of L_{b1} to L_{b334};
preferably, the metal complex is selected from the group consisting of Metal Complex 1 to Metal Complex 495, wherein Metal Complex 1 to Metal Complex 495 have the structure of IrLₐ(L_{b})₂, the two L_{b} are the same, and Lₐ and L_{b} correspond to structures shown in the following table, respectively:

| Metal | | |
|---|---|---|
| Complex | | |
| No. | Lₐ | L_{b} |
| 1 | Lₐ₁ | L_{b1} |
| 2 | Lₐ₈ | L_{b1} |
| 3 | Lₐ₉ | L_{b1} |
| 4 | Lₐ₁₂ | L_{b1} |
| 5 | Lₐ₁₃ | L_{b1} |
| 6 | Lₐ₁₆ | L_{b1} |
| 7 | Lₐ₁₇ | L_{b1} |
| 8 | Lₐ₁₈ | L_{b1} |
| 9 | Lₐ₁₉ | L_{b1} |
| 10 | Lₐ₂₄ | L_{b1} |
| 11 | Lₐ₂₅ | L_{b1} |
| 12 | Lₐ₂₆ | L_{b1} |
| 13 | Lₐ₂₇ | L_{b1} |
| 14 | Lₐ₂₈ | L_{b1} |
| 15 | Lₐ₃₁ | L_{b1} |
| 16 | Lₐ₃₆ | L_{b1} |
| 17 | Lₐ₄₁ | L_{b1} |
| 18 | Lₐ₄₆ | L_{b1} |
| 19 | Lₐ₄₉ | L_{b1} |
| 20 | Lₐ₅₂ | L_{b1} |
| 21 | Lₐ₅₃ | L_{b1} |
| 22 | Lₐ₅₄ | L_{b1} |
| 23 | Lₐ₅₇ | L_{b1} |
| 24 | Lₐ₅₈ | L_{b1} |
| 25 | Lₐ₆₁ | L_{b1} |
| 26 | Lₐ₆₂ | L_{b1} |
| 27 | Lₐ₆₃ | L_{b1} |
| 28 | Lₐ₆₄ | L_{b1} |
| 29 | Lₐ₆₅ | L_{b1} |
| 30 | Lₐ₆₆ | L_{b1} |
| 31 | Lₐ₆₇ | L_{b1} |
| 32 | Lₐ₇₀ | L_{b1} |
| 33 | Lₐ₇₁ | L_{b1} |
| 34 | Lₐ₇₂ | L_{b1} |
| 35 | Lₐ₇₅ | L_{b1} |
| 36 | Lₐ₇₆ | L_{b1} |
| 37 | Lₐ₈₃ | L_{b1} |
| 38 | Lₐ₈₅ | L_{b1} |
| 39 | Lₐ₈₆ | L_{b1} |
| 40 | Lₐ₉₂ | L_{b1} |
| 41 | Lₐ₉₅ | L_{b1} |
| 42 | Lₐ₉₆ | L_{b1} |
| 43 | Lₐ₁₀₀ | L_{b1} |
| 44 | Lₐ₁₀₂ | L_{b1} |
| 45 | Lₐ₁₀₃ | L_{b1} |
| 46 | Lₐ₁₀₄ | L_{b1} |
| 47 | Lₐ₁₀₅ | L_{b1} |
| 48 | Lₐ₁₀₉ | L_{b1} |
| 49 | Lₐ₁₁₀ | L_{b1} |
| 50 | Lₐ₁₁₁ | L_{b1} |
| 51 | Lₐ₁₁₂ | L_{b1} |
| 52 | Lₐ₁₁₃ | L_{b1} |
| 53 | Lₐ₁₁₇ | L_{b1} |
| 54 | Lₐ₁₁₈ | L_{b1} |
| 55 | Lₐ₁₂₁ | L_{b1} |
| 56 | Lₐ₁₂₂ | L_{b1} |
| 57 | Lₐ₁₂₈ | L_{b1} |
| 58 | Lₐ₁₂₉ | L_{b1} |
| 59 | Lₐ₁₃₀ | L_{b1} |
| 60 | Lₐ₁₃₁ | L_{b1} |
| 61 | Lₐ₁₃₅ | L_{b1} |
| 62 | Lₐ₁₃₆ | L_{b1} |
| 63 | Lₐ₁₃₉ | L_{b1} |
| 64 | Lₐ₁₄₀ | L_{b1} |
| 65 | Lₐ₁₄₄ | L_{b1} |
| 66 | Lₐ₁₄₆ | L_{b1} |
| 67 | Lₐ₁₄₈ | L_{b1} |
| 68 | Lₐ₁₅₀ | L_{b1} |
| 69 | Lₐ₁₆₂ | L_{b1} |
| 70 | Lₐ₁₆₆ | L_{b1} |
| 71 | Lₐ₁₆₇ | L_{b1} |
| 72 | Lₐ₁₆₈ | L_{b1} |
| 73 | Lₐ₁₇₃ | L_{b1} |
| 74 | Lₐ₁₇₄ | L_{b1} |
| 75 | Lₐ₁₇₅ | L_{b1} |
| 76 | Lₐ₁₇₈ | L_{b1} |
| 77 | Lₐ₁₇₉ | L_{b1} |
| 78 | Lₐ₁₈₁ | L_{b1} |
| 79 | Lₐ₁₈₆ | L_{b1} |
| 80 | Lₐ₁₈₇ | L_{b1} |
| 81 | Lₐ₁₈₈ | L_{b1} |
| 82 | Lₐ₁₈₉ | L_{b1} |
| 83 | Lₐ₁₉₀ | L_{b1} |
| 84 | Lₐ₁₉₁ | L_{b1} |
| 85 | Lₐ₁₉₂ | L_{b1} |
| 86 | Lₐ₁₉₃ | L_{b1} |
| 87 | Lₐ₁₉₅ | L_{b1} |
| 88 | Lₐ₂₀₀ | L_{b1} |
| 89 | Lₐ₂₀₃ | L_{b1} |
| 90 | Lₐ₂₀₇ | L_{b1} |
| 91 | Lₐ₂₁₁ | L_{b1} |
| 92 | Lₐ₂₁₂ | L_{b1} |
| 93 | Lₐ₂₂₁ | L_{b1} |
| 94 | Lₐ₂₂₉ | L_{b1} |
| 95 | Lₐ₂₃₀ | L_{b1} |
| 96 | Lₐ₂₃₁ | L_{b1} |
| 97 | Lₐ₂₃₄ | L_{b1} |
| 98 | Lₐ₂₃₅ | L_{b1} |
| 99 | Lₐ₂₃₆ | L_{b1} |
| 100 | Lₐ₁ | L_{b3} |
| 101 | Lₐ₈ | L_{b3} |
| 102 | Lₐ₉ | L_{b3} |
| 103 | Lₐ₁₂ | L_{b3} |
| 104 | Lₐ₁₃ | L_{b3} |
| 105 | Lₐ₁₆ | L_{b3} |
| 106 | Lₐ₁₇ | L_{b3} |
| 107 | Lₐ₁₈ | L_{b3} |
| 108 | Lₐ₁₉ | L_{b3} |
| 109 | Lₐ₂₄ | L_{b3} |
| 110 | Lₐ₂₅ | L_{b3} |
| 111 | Lₐ₂₆ | L_{b3} |
| 112 | Lₐ₂₇ | L_{b3} |
| 113 | Lₐ₂₈ | L_{b3} |
| 114 | Lₐ₃₁ | L_{b3} |
| 115 | Lₐ₃₆ | L_{b3} |
| 116 | Lₐ₄₁ | L_{b3} |
| 117 | Lₐ₄₆ | L_{b3} |
| 118 | Lₐ₄₉ | L_{b3} |
| 119 | Lₐ₅₂ | L_{b3} |
| 120 | Lₐ₅₃ | L_{b3} |
| 121 | Lₐ₅₄ | L_{b3} |
| 122 | Lₐ₅₇ | L_{b3} |
| 123 | Lₐ₅₈ | L_{b3} |
| 124 | Lₐ₆₁ | L_{b3} |
| 125 | Lₐ₆₂ | L_{b3} |
| 126 | Lₐ₆₃ | L_{b3} |
| 127 | Lₐ₆₄ | L_{b3} |
| 128 | Lₐ₆₅ | L_{b3} |
| 129 | Lₐ₆₆ | L_{b3} |
| 130 | Lₐ₆₇ | L_{b3} |
| 131 | Lₐ₇₀ | L_{b3} |
| 132 | Lₐ₇₁ | L_{b3} |
| 133 | Lₐ₇₂ | L_{b3} |
| 134 | Lₐ₇₅ | L_{b3} |
| 135 | Lₐ₇₆ | L_{b3} |
| 136 | Lₐ₈₃ | L_{b3} |
| 137 | Lₐ₈₅ | L_{b3} |
| 138 | Lₐ₈₆ | L_{b3} |
| 139 | Lₐ₉₂ | L_{b3} |
| 140 | Lₐ₉₅ | L_{b3} |
| 141 | Lₐ₉₆ | L_{b3} |
| 142 | Lₐ₁₀₀ | L_{b3} |
| 143 | Lₐ₁₀₂ | L_{b3} |
| 144 | Lₐ₁₀₃ | L_{b3} |
| 145 | Lₐ₁₀₄ | L_{b3} |
| 146 | Lₐ₁₀₅ | L_{b3} |
| 147 | Lₐ₁₀₉ | L_{b3} |
| 148 | Lₐ₁₁₀ | L_{b3} |
| 149 | Lₐ₁₁₁ | L_{b3} |
| 150 | Lₐ₁₁₂ | L_{b3} |
| 151 | Lₐ₁₁₃ | L_{b3} |
| 152 | Lₐ₁₁₇ | L_{b3} |
| 153 | Lₐ₁₁₈ | L_{b3} |
| 154 | Lₐ₁₂₁ | L_{b3} |
| 155 | Lₐ₁₂₂ | L_{b3} |
| 156 | Lₐ₁₂₈ | L_{b3} |
| 157 | Lₐ₁₂₉ | L_{b3} |
| 158 | Lₐ₁₃₀ | L_{b3} |
| 159 | Lₐ₁₃₁ | L_{b3} |
| 160 | Lₐ₁₃₅ | L_{b3} |
| 161 | Lₐ₁₃₆ | L_{b3} |
| 162 | Lₐ₁₃₉ | L_{b3} |
| 163 | Lₐ₁₄₀ | L_{b3} |
| 164 | Lₐ₁₄₄ | L_{b3} |
| 165 | Lₐ₁₄₆ | L_{b3} |
| 166 | Lₐ₁₄₈ | L_{b3} |
| 167 | Lₐ₁₅₀ | L_{b3} |
| 168 | Lₐ₁₆₂ | L_{b3} |
| 169 | Lₐ₁₆₆ | L_{b3} |
| 170 | Lₐ₁₆₇ | L_{b3} |
| 171 | Lₐ₁₆₈ | L_{b3} |
| 172 | Lₐ₁₇₃ | L_{b3} |
| 173 | Lₐ₁₇₄ | L_{b3} |
| 174 | Lₐ₁₇₅ | L_{b3} |
| 175 | Lₐ₁₇₈ | L_{b3} |
| 176 | Lₐ₁₇₉ | L_{b3} |
| 177 | Lₐ₁₈₁ | L_{b3} |
| 178 | Lₐ₁₈₆ | L_{b3} |
| 179 | Lₐ₁₈₇ | L_{b3} |
| 180 | Lₐ₁₈₈ | L_{b3} |
| 181 | Lₐ₁₈₉ | L_{b3} |
| 182 | Lₐ₁₉₀ | L_{b3} |
| 183 | Lₐ₁₉₁ | L_{b3} |
| 184 | Lₐ₁₉₂ | L_{b3} |
| 185 | Lₐ₁₉₃ | L_{b3} |
| 186 | Lₐ₁₉₅ | L_{b3} |
| 187 | Lₐ₂₀₀ | L_{b3} |
| 188 | Lₐ₂₀₃ | L_{b3} |
| 189 | Lₐ₂₀₇ | L_{b3} |
| 190 | Lₐ₂₁₁ | L_{b3} |
| 191 | Lₐ₂₁₂ | L_{b3} |
| 192 | Lₐ₂₂₁ | L_{b3} |
| 193 | Lₐ₂₂₉ | L_{b3} |
| 194 | Lₐ₂₃₀ | L_{b3} |
| 195 | Lₐ₂₃₁ | L_{b3} |
| 196 | Lₐ₂₃₄ | L_{b3} |
| 197 | Lₐ₂₃₅ | L_{b3} |
| 198 | Lₐ₂₃₆ | L_{b3} |
| 199 | Lₐ₁ | L_{b81} |
| 200 | Lₐ₈ | L_{b81} |
| 201 | Lₐ₉ | L_{b81} |
| 202 | Lₐ₁₂ | L_{b81} |
| 203 | Lₐ₁₃ | L_{b81} |
| 204 | Lₐ₁₆ | L_{b81} |
| 205 | Lₐ₁₇ | L_{b81} |
| 206 | Lₐ₁₈ | L_{b81} |
| 207 | Lₐ₁₉ | L_{b81} |
| 208 | Lₐ₂₄ | L_{b81} |
| 209 | Lₐ₂₅ | L_{b81} |
| 210 | Lₐ₂₆ | L_{b81} |
| 211 | Lₐ₂₇ | L_{b81} |
| 212 | Lₐ₂₈ | L_{b81} |
| 213 | Lₐ₃₁ | L_{b81} |
| 214 | Lₐ₃₆ | L_{b81} |
| 215 | Lₐ₄₁ | L_{b81} |
| 216 | Lₐ₄₆ | L_{b81} |
| 217 | Lₐ₄₉ | L_{b81} |
| 218 | Lₐ₅₂ | L_{b81} |
| 219 | Lₐ₅₃ | L_{b81} |
| 220 | Lₐ₅₄ | L_{b81} |
| 221 | Lₐ₅₇ | L_{b81} |
| 222 | Lₐ₅₈ | L_{b81} |
| 223 | Lₐ₆₁ | L_{b81} |
| 224 | Lₐ₆₂ | L_{b81} |
| 225 | Lₐ₆₃ | L_{b81} |
| 226 | Lₐ₆₄ | L_{b81} |
| 227 | Lₐ₆₅ | L_{b81} |
| 228 | Lₐ₆₆ | L_{b81} |
| 229 | Lₐ₆₇ | L_{b81} |
| 230 | Lₐ₇₀ | L_{b81} |
| 231 | Lₐ₇₁ | L_{b81} |
| 232 | Lₐ₇₂ | L_{b81} |
| 233 | Lₐ₇₅ | L_{b81} |
| 234 | Lₐ₇₆ | L_{b81} |
| 235 | Lₐ₈₃ | L_{b81} |
| 236 | Lₐ₈₅ | L_{b81} |
| 237 | Lₐ₈₆ | L_{b81} |
| 238 | Lₐ₉₂ | L_{b81} |
| 239 | Lₐ₉₅ | L_{b81} |
| 240 | Lₐ₉₆ | L_{b81} |
| 241 | Lₐ₁₀₀ | L_{b81} |
| 242 | Lₐ₁₀₂ | L_{b81} |
| 243 | Lₐ₁₀₃ | L_{b81} |
| 244 | Lₐ₁₀₄ | L_{b81} |
| 245 | Lₐ₁₀₅ | L_{b81} |
| 246 | Lₐ₁₀₉ | L_{b81} |
| 247 | Lₐ₁₁₀ | L_{b81} |
| 248 | Lₐ₁₁₁ | L_{b81} |
| 249 | Lₐ₁₁₂ | L_{b81} |
| 250 | Lₐ₁₁₃ | L_{b81} |
| 251 | Lₐ₁₁₇ | L_{b81} |
| 252 | Lₐ₁₁₈ | L_{b81} |
| 253 | Lₐ₁₂₁ | L_{b81} |
| 254 | Lₐ₁₂₂ | L_{b81} |
| 255 | Lₐ₁₂₈ | L_{b81} |
| 256 | Lₐ₁₂₉ | L_{b81} |
| 257 | Lₐ₁₃₀ | L_{b81} |
| 258 | Lₐ₁₃₁ | L_{b81} |
| 259 | Lₐ₁₃₅ | L_{b81} |
| 260 | Lₐ₁₃₆ | L_{b81} |
| 261 | Lₐ₁₃₉ | L_{b81} |
| 262 | Lₐ₁₄₀ | L_{b81} |
| 263 | Lₐ₁₄₄ | L_{b81} |
| 264 | Lₐ₁₄₆ | L_{b81} |
| 265 | Lₐ₁₄₈ | L_{b81} |
| 266 | Lₐ₁₅₀ | L_{b81} |
| 267 | Lₐ₁₆₂ | L_{b81} |
| 268 | Lₐ₁₆₆ | L_{b81} |
| 269 | Lₐ₁₆₇ | L_{b81} |
| 270 | Lₐ₁₆₈ | L_{b81} |
| 271 | Lₐ₁₇₃ | L_{b81} |
| 272 | Lₐ₁₇₄ | L_{b81} |
| 273 | Lₐ₁₇₅ | L_{b81} |
| 274 | Lₐ₁₇₈ | L_{b81} |
| 275 | Lₐ₁₇₉ | L_{b81} |
| 276 | Lₐ₁₈₁ | L_{b81} |
| 277 | Lₐ₁₈₆ | L_{b81} |
| 278 | Lₐ₁₈₇ | L_{b81} |
| 279 | Lₐ₁₈₈ | L_{b81} |
| 280 | Lₐ₁₈₉ | L_{b81} |
| 281 | Lₐ₁₉₀ | L_{b81} |
| 282 | Lₐ₁₉₁ | L_{b81} |
| 283 | Lₐ₁₉₂ | L_{b81} |
| 284 | Lₐ₁₉₃ | L_{b81} |
| 285 | Lₐ₁₉₅ | L_{b81} |
| 286 | Lₐ₂₀₀ | L_{b81} |
| 287 | Lₐ₂₀₃ | L_{b81} |
| 288 | Lₐ₂₀₇ | L_{b81} |
| 289 | Lₐ₂₁₁ | L_{b81} |
| 290 | Lₐ₂₁₂ | L_{b81} |
| 291 | Lₐ₂₂₁ | L_{b81} |
| 292 | Lₐ₂₂₉ | L_{b81} |
| 293 | Lₐ₂₃₀ | L_{b81} |
| 294 | Lₐ₂₃₁ | L_{b81} |
| 295 | Lₐ₂₃₄ | L_{b81} |
| 296 | Lₐ₂₃₅ | L_{b81} |
| 297 | Lₐ₂₃₆ | L_{b81} |
| 298 | Lₐ₁ | L_{b329} |
| 299 | Lₐ₈ | L_{b329} |
| 300 | Lₐ₉ | L_{b329} |
| 301 | Lₐ₁₂ | L_{b329} |
| 302 | Lₐ₁₃ | L_{b329} |
| 303 | Lₐ₁₆ | L_{b329} |
| 304 | Lₐ₁₇ | L_{b329} |
| 305 | Lₐ₁₈ | L_{b329} |
| 306 | Lₐ₁₉ | L_{b329} |
| 307 | Lₐ₂₄ | L_{b329} |
| 308 | Lₐ₂₅ | L_{b329} |
| 309 | Lₐ₂₆ | L_{b329} |
| 310 | Lₐ₂₇ | L_{b329} |
| 311 | Lₐ₂₈ | L_{b329} |
| 312 | Lₐ₃₁ | L_{b329} |
| 313 | Lₐ₃₆ | L_{b329} |
| 314 | Lₐ₄₁ | L_{b329} |
| 315 | Lₐ₄₆ | L_{b329} |
| 316 | Lₐ₄₉ | L_{b329} |
| 317 | Lₐ₅₂ | L_{b329} |
| 318 | Lₐ₅₃ | L_{b329} |
| 319 | Lₐ₅₄ | L_{b329} |
| 320 | Lₐ₅₇ | L_{b329} |
| 321 | Lₐ₅₈ | L_{b329} |
| 322 | Lₐ₆₁ | L_{b329} |
| 323 | Lₐ₆₂ | L_{b329} |
| 324 | Lₐ₆₃ | L_{b329} |
| 325 | Lₐ₆₄ | L_{b329} |
| 326 | Lₐ₆₅ | L_{b329} |
| 327 | Lₐ₆₆ | L_{b329} |
| 328 | Lₐ₆₇ | L_{b329} |
| 329 | Lₐ₇₀ | L_{b329} |
| 330 | Lₐ₇₁ | L_{b329} |
| 331 | Lₐ₇₂ | L_{b329} |
| 332 | Lₐ₇₅ | L_{b329} |
| 333 | Lₐ₇₆ | L_{b329} |
| 334 | Lₐ₈₃ | L_{b329} |
| 335 | Lₐ₈₅ | L_{b329} |
| 336 | Lₐ₈₆ | L_{b329} |
| 337 | Lₐ₉₂ | L_{b329} |
| 338 | Lₐ₉₅ | L_{b329} |
| 339 | Lₐ₉₆ | L_{b329} |
| 340 | Lₐ₁₀₀ | L_{b329} |
| 341 | Lₐ₁₀₂ | L_{b329} |
| 342 | Lₐ₁₀₃ | L_{b329} |
| 343 | Lₐ₁₀₄ | L_{b329} |
| 344 | Lₐ₁₀₅ | L_{b329} |
| 345 | Lₐ₁₀₉ | L_{b329} |
| 346 | Lₐ₁₁₀ | L_{b329} |
| 347 | Lₐ₁₁₁ | L_{b329} |
| 348 | Lₐ₁₁₂ | L_{b329} |
| 349 | Lₐ₁₁₃ | L_{b329} |
| 350 | Lₐ₁₁₇ | L_{b329} |
| 351 | Lₐ₁₁₈ | L_{b329} |
| 352 | Lₐ₁₂₁ | L_{b329} |
| 353 | Lₐ₁₂₂ | L_{b329} |
| 354 | Lₐ₁₂₈ | L_{b329} |
| 355 | Lₐ₁₂₉ | L_{b329} |
| 356 | Lₐ₁₃₀ | L_{b329} |
| 357 | Lₐ₁₃₁ | L_{b329} |
| 358 | Lₐ₁₃₅ | L_{b329} |
| 359 | Lₐ₁₃₆ | L_{b329} |
| 360 | Lₐ₁₃₉ | L_{b329} |
| 362 | Lₐ₁₄₀ | L_{b329} |
| 362 | Lₐ₁₄₄ | L_{b329} |
| 363 | Lₐ₁₄₆ | L_{b329} |
| 364 | Lₐ₁₄₈ | L_{b329} |
| 365 | Lₐ₁₅₀ | L_{b329} |
| 366 | Lₐ₁₆₂ | L_{b329} |
| 367 | Lₐ₁₆₆ | L_{b329} |
| 368 | Lₐ₁₆₇ | L_{b329} |
| 369 | Lₐ₁₆₈ | L_{b329} |
| 370 | Lₐ₁₇₃ | L_{b329} |
| 371 | Lₐ₁₇₄ | L_{b329} |
| 372 | Lₐ₁₇₅ | L_{b329} |
| 373 | Lₐ₁₇₈ | L_{b329} |
| 374 | Lₐ₁₇₉ | L_{b329} |
| 375 | Lₐ₁₈₁ | L_{b329} |
| 376 | Lₐ₁₈₆ | L_{b329} |
| 377 | Lₐ₁₈₇ | L_{b329} |
| 378 | Lₐ₁₈₈ | L_{b329} |
| 379 | Lₐ₁₈₉ | L_{b329} |
| 380 | Lₐ₁₉₀ | L_{b329} |
| 381 | Lₐ₁₉₁ | L_{b329} |
| 382 | Lₐ₁₉₂ | L_{b329} |
| 383 | Lₐ₁₉₃ | L_{b329} |
| 384 | Lₐ₁₉₅ | L_{b329} |
| 385 | Lₐ₂₀₀ | L_{b329} |
| 386 | Lₐ₂₀₃ | L_{b329} |
| 387 | Lₐ₂₀₇ | L_{b329} |
| 388 | Lₐ₂₁₁ | L_{b329} |
| 389 | Lₐ₂₁₂ | L_{b329} |
| 390 | Lₐ₂₂₁ | L_{b329} |
| 391 | Lₐ₂₂₉ | L_{b329} |
| 392 | Lₐ₂₃₀ | L_{b329} |
| 393 | Lₐ₂₃₁ | L_{b329} |
| 394 | Lₐ₂₃₄ | L_{b329} |
| 395 | Lₐ₂₃₅ | L_{b329} |
| 396 | Lₐ₂₃₆ | L_{b329} |
| 397 | Lₐ₁ | L_{b333} |
| 398 | Lₐ₈ | L_{b333} |
| 399 | Lₐ₉ | L_{b333} |
| 400 | Lₐ₁₂ | L_{b333} |
| 401 | Lₐ₁₃ | L_{b333} |
| 402 | Lₐ₁₆ | L_{b333} |
| 403 | Lₐ₁₇ | L_{b333} |
| 404 | Lₐ₁₈ | L_{b333} |
| 405 | Lₐ₁₉ | L_{b333} |
| 406 | Lₐ₂₄ | L_{b333} |
| 407 | Lₐ₂₅ | L_{b333} |
| 408 | Lₐ₂₆ | L_{b333} |
| 409 | Lₐ₂₇ | L_{b333} |
| 410 | Lₐ₂₈ | L_{b333} |
| 411 | Lₐ₃₁ | L_{b333} |
| 412 | Lₐ₃₆ | L_{b333} |
| 413 | Lₐ₄₁ | L_{b333} |
| 414 | Lₐ₄₆ | L_{b333} |
| 415 | Lₐ₄₉ | L_{b333} |
| 416 | Lₐ₅₂ | L_{b333} |
| 417 | Lₐ₅₃ | L_{b333} |
| 418 | Lₐ₅₄ | L_{b333} |
| 419 | Lₐ₅₇ | L_{b333} |
| 420 | Lₐ₅₈ | L_{b333} |
| 421 | Lₐ₆₁ | L_{b333} |
| 422 | Lₐ₆₂ | L_{b333} |
| 423 | Lₐ₆₃ | L_{b333} |
| 424 | Lₐ₆₄ | L_{b333} |
| 425 | Lₐ₆₅ | L_{b333} |
| 426 | Lₐ₆₆ | L_{b333} |
| 427 | Lₐ₆₇ | L_{b333} |
| 428 | Lₐ₇₀ | L_{b333} |
| 429 | Lₐ₇₁ | L_{b333} |
| 430 | Lₐ₇₂ | L_{b333} |
| 431 | Lₐ₇₅ | L_{b333} |
| 432 | Lₐ₇₆ | L_{b333} |
| 433 | Lₐ₈₃ | L_{b333} |
| 434 | Lₐ₈₅ | L_{b333} |
| 435 | Lₐ₈₆ | L_{b333} |
| 436 | Lₐ₉₂ | L_{b333} |
| 437 | Lₐ₉₅ | L_{b333} |
| 438 | Lₐ₉₆ | L_{b333} |
| 439 | Lₐ₁₀₀ | L_{b333} |
| 440 | Lₐ₁₀₂ | L_{b333} |
| 441 | Lₐ₁₀₃ | L_{b333} |
| 442 | Lₐ₁₀₄ | L_{b333} |
| 443 | Lₐ₁₀₅ | L_{b333} |
| 444 | Lₐ₁₀₉ | L_{b333} |
| 445 | Lₐ₁₁₀ | L_{b333} |
| 446 | Lₐ₁₁₁ | L_{b333} |
| 447 | Lₐ₁₁₂ | L_{b333} |
| 448 | Lₐ₁₁₃ | L_{b333} |
| 449 | Lₐ₁₁₇ | L_{b333} |
| 450 | Lₐ₁₁₈ | L_{b333} |
| 451 | Lₐ₁₂₁ | L_{b333} |
| 452 | Lₐ₁₂₂ | L_{b333} |
| 453 | Lₐ₁₂₈ | L_{b333} |
| 454 | Lₐ₁₂₉ | L_{b333} |
| 455 | Lₐ₁₃₀ | L_{b333} |
| 456 | Lₐ₁₃₁ | L_{b333} |
| 457 | Lₐ₁₃₅ | L_{b333} |
| 458 | Lₐ₁₃₆ | L_{b333} |
| 459 | Lₐ₁₃₉ | L_{b333} |
| 460 | Lₐ₁₄₀ | L_{b333} |
| 461 | Lₐ₁₄₄ | L_{b333} |
| 462 | Lₐ₁₄₆ | L_{b333} |
| 463 | Lₐ₁₄₈ | L_{b333} |
| 464 | Lₐ₁₅₀ | L_{b333} |
| 465 | Lₐ₁₆₂ | L_{b333} |
| 466 | Lₐ₁₆₆ | L_{b333} |
| 467 | Lₐ₁₆₇ | L_{b333} |
| 468 | Lₐ₁₆₈ | L_{b333} |
| 469 | Lₐ₁₇₃ | L_{b333} |
| 470 | Lₐ₁₇₄ | L_{b333} |
| 471 | Lₐ₁₇₅ | L_{b333} |
| 472 | Lₐ₁₇₈ | L_{b333} |
| 473 | Lₐ₁₇₉ | L_{b333} |
| 474 | Lₐ₁₈₁ | L_{b333} |
| 475 | Lₐ₁₈₆ | L_{b333} |
| 476 | Lₐ₁₈₇ | L_{b333} |
| 477 | Lₐ₁₈₈ | L_{b333} |
| 478 | Lₐ₁₈₉ | L_{b333} |
| 479 | Lₐ₁₉₀ | L_{b333} |
| 480 | Lₐ₁₉₁ | L_{b333} |
| 481 | Lₐ₁₉₂ | L_{b333} |
| 482 | Lₐ₁₉₃ | L_{b333} |
| 483 | Lₐ₁₉₅ | L_{b333} |
| 484 | Lₐ₂₀₀ | L_{b333} |
| 485 | Lₐ₂₀₃ | L_{b333} |
| 486 | Lₐ₂₀₇ | L_{b333} |
| 487 | Lₐ₂₁₁ | L_{b333} |
| 488 | Lₐ₂₁₂ | L_{b333} |
| 489 | Lₐ₂₂₁ | L_{b333} |
| 490 | Lₐ₂₂₉ | L_{b333} |
| 491 | Lₐ₂₃₀ | L_{b333} |
| 492 | Lₐ₂₃₁ | L_{b333} |
| 493 | Lₐ₂₃₄ | L_{b333} |
| 494 | Lₐ₂₃₅ | L_{b333} |
| 495 | Lₐ₂₃₆ | L_{b333}. |

19. An organic electroluminescent device, comprising:
an anode,
a cathode, and
an organic layer disposed between the anode and the cathode, wherein at least one layer of the organic layer comprises the metal complex of claim 1.

20. The organic electroluminescent device of claim 19, wherein the organic layer comprising the metal complex is an emissive layer.

21. The organic electroluminescent device of claim 20, wherein the emissive layer further comprises a first host compound;
preferably, the emissive layer further comprises a second host compound; and
more preferably, at least one of the first host compound and the second host compound comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

22. The organic electroluminescent device of claim 21, wherein the metal complex is doped in the first host compound and the second host compound, and the weight of the metal complex accounts for 1% to 30% of the total weight of the emissive layer; and
preferably, the weight of the metal complex accounts for 3% to 13% of the total weight of the emissive layer.

23. A compound composition, comprising the metal complex of claim 1.
